(19) United States
(12) Patent Application Publication
(10) Pub. No.: US 2024/0389452 A1
(43) Pub. Date: Nov. 21, 2024

(54) ORGANIC LIGHT EMITTING DEVICE

(71) Applicant: LG CHEM, LTD., Seoul (KR)

(72) Inventors: Min Woo Jung, Daejeon (KR); Dong Hoon Lee, Daejeon (KR); Miyeon Han, Daejeon (KR); Seulchan Park, Daejeon (KR); Hoon Jun Kim, Daejeon (KR); Hye Min Cho, Daejeon (KR); Hojung Lee, Daejeon (KR)

(21) Appl. No.: 18/693,922

(22) PCT Filed: Jan. 26, 2023
(86) PCT No.: PCT/KR2023/001223

§ 371 Date: Mar. 20, 2024

(30) Foreign Application Priority Data
Jan. 26, 2022 (KR) 10-2022-0011717

(51) Int. Cl. H10K 85/60; C07B 59/00

(52) U.S. Cl. CPC H10K 85/654; C07B 59/004; H10K 85/615; H10K 85/631; H10K 85/6572; H10K 85/6574; H10K 85/6576; C07B 2200/05

(57) ABSTRACT

An organic light emitting device comprising: an anode; a cathode; and a light emitting layer between the anode and cathode, the light emitting layer comprising a compound of Chemical Formula 1, and a compound of Chemical Formula 2:

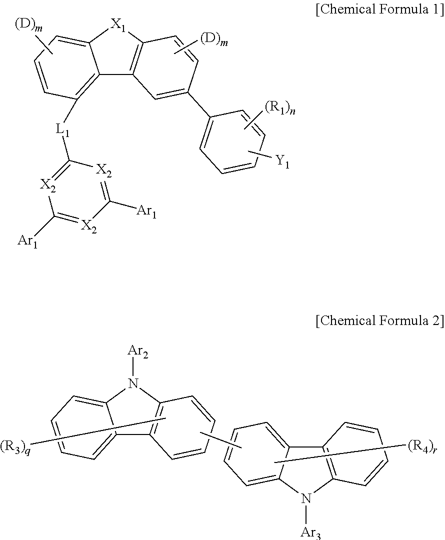

wherein: X₁ is O or S; at least one of X₂ is N; each Ar₁, and Ar₂ and Ar₃ are independently a substituted or unsubstituted C₆₋₆₀ aryl or C₂₋₆₀ heteroaryl containing any one or more of N, O, and S; at least one of the Ar₂ and Ar₃ is substituted with at least one deuterium, or at least one of the R₃ and R₄ is deuterium; and the other substituents are defined in the specification. When light emitting layer includes a compound of Chemical Formulae 1 and 2, the organic light emitting device exhibits improved driving voltage, efficiency and lifetime.

### CROSS-REFERENCE TO RELATED APPLICATION(S)

This application is a National Stage Application of International Application No. PCT/KR2023/001223 filed on Jan. 26, 2023, which claims the benefit of and priority to Korean Patent Application No. 10-2022-0011717 filed on Jan. 26, 2022 with the Korean Intellectual Property Office, the contents of which are incorporated herein by reference in their entirety.

### TECHNICAL FIELD

The present disclosure relates to an organic light emitting device having improved driving voltage, efficiency and lifetime

### BACKGROUND

In general, an organic light emitting phenomenon refers to a phenomenon where electric energy is converted into light energy by using an organic material. The organic light emitting device using the organic light emitting phenomenon has characteristics such as a wide viewing angle, an excellent contrast, a fast response time. an excellent luminance, driving voltage and response speed, and thus many studies have proceeded.

The organic light emitting device generally has a structure which comprises an anode, a cathode, and an organic material layer interposed between the anode and the cathode The organic material layer frequently has a multilayered structure that comprises different materials in order to enhance efficiency and stability of the organic light emitting device, and for example, the organic material layer can be formed of a hole injection layer, a hole transport layer, a light emitting layer, an electron transport layer, an electron injection layer and the like. In the structure of the organic light emitting device, if a voltage is applied between two electrodes, the holes are injected from an anode into the organic material layer and the electrons are injected from the cathode into the organic material layer, and when the injected holes and electrons meet each other, an exciton is formed, and light is emitted when the exciton falls to a ground state again.

In the organic light emitting device as described above, there is a continuing need for the development of an organic light emitting device having improved driving voltage, efficiency and lifetime.

### PRIOR ART LITERATURE

### Patent Literature

(Patent Literature 0001) Korean Unexamined Patent Publication No. 10-2000-0051826

### DETAILED DESCRIPTION OF THE INVENTION

### Technical Problem

It is an object of the present disclosure to provide an organic light emitting device having improved driving voltage, efficiency and lifetime.

### Technical Solution

The present disclosure provides the following organic light emitting device:

An organic light emitting device comprising:
an anode;
a cathode; and
a light emitting layer interposed between the anode and the cathode,

wherein the light emitting layer includes a compound of the following Chemical Formula 1, and a compound of the following Chemical Formula 2:

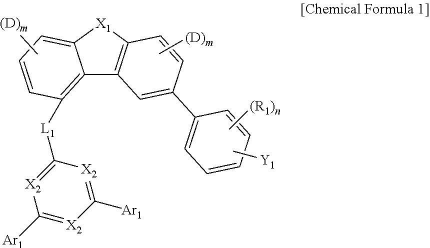

wherein, in Chemical Formula 1:
X₁ is O or S;
L₁ is a single bond, a substituted or unsubstituted C₆₋₆₀ arylene, or a substituted or unsubstituted C₂₋₆₀ heteroarylene containing any one or more heteroatoms selected from the group consisting of N, O, and S;
each X₂ is independently N or CH, provided that at least one of X₂ is N;
each Ar₁ is independently a substituted or unsubstituted C₆₋₆₀ aryl, or a substituted or unsubstituted C₂₋₆₀ heteroaryl containing any one or more heteroatoms selected from the group consisting of N, O, and S;
each R₁ is independently hydrogen, deuterium, or a substituted or unsubstituted C₆₋₆₀ aryl;
each m is independently an integer of 0 to 3;
n is an integer of 0 to 4; and
Y₁ is any one selected from the group consisting of:

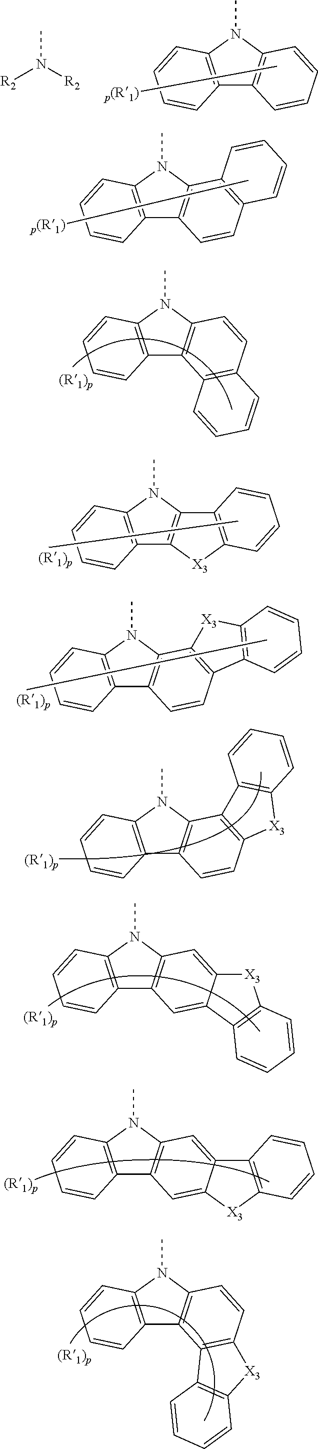

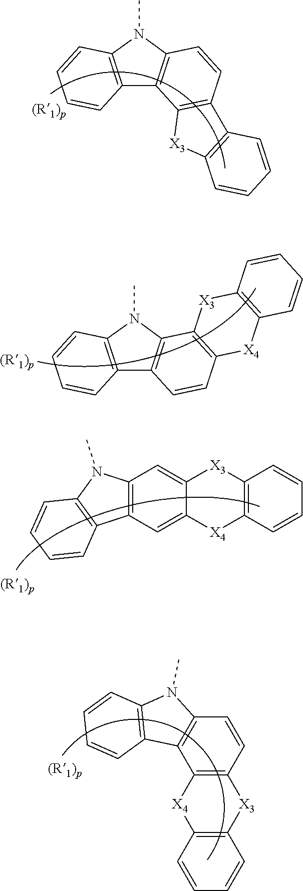

wherein, in the above group:
each R₂ is independently hydrogen, deuterium, or phenyl:
X₃ and X₄ are each independently O, N-(phenyl), S, or C(CH₃)₂;
each R′₁ is independently hydrogen, deuterium, or phenyl which is unsubstituted or substituted with at least one deuterium; and
p is an integer of 0 to 10;

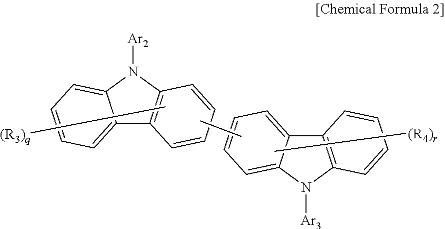

wherein, in Chemical Formula 2:
Ar₂ and Ar₃ are each independently a substituted or unsubstituted C₆₋₆₀ aryl, or a substituted or unsubstituted C₂₋₆₀ heteroaryl containing any one or more heteroatoms selected from the group consisting of N, O and S;
R₃ and R₄ are each independently hydrogen, deuterium, a substituted or unsubstituted C₆₋₆₀ aryl, or a substituted or unsubstituted C₂₋₆₀ heteroaryl containing any one or more heteroatoms selected from the group consisting of N, O and S;
at least one of the Ar₂ and Ar₃ is substituted with at least one deuterium, or at least one of the R₃ and R₄ is deuterium;
q is an integer of 1 to 7; and
r is an integer of 1 to 7.

### Advantageous Effects

The organic light emitting device described above is excellent in driving voltage, efficiency and lifetime.

### BRIEF DESCRIPTION OF THE DRAWINGS

FIG. 1 shows an example of an organic light emitting device comprising a substrate 1, an anode 2, a light emitting layer 3, and a cathode 4.

FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron transport layer 9, an electron injection layer 10, and a cathode 4.

### BRIEF DESCRIPTION

Hereinafter, embodiments of the present disclosure will be described in more detail to facilitate understanding of the invention.

As used herein, the notation [symbol] or [symbol] means a bond linked to another substituent group, and “D” means deuterium.

As used herein, the term “substituted or unsubstituted” means being unsubstituted or substituted with one or more substituent groups selected from the group consisting of deuterium, a halogen group, a cyano group, a nitro group, a hydroxy group, a carbonyl group, an ester group, an imide group, an amino group, a phosphine oxide group, an alkoxy group, an aryloxy group, an alkylthioxy group, an arylthioxy group, an alkylsulfoxy group, an arylsulfoxy group, a silyl group, a boron group, an alkyl group, a cycloalkyl group, an alkenyl group, an aryl group, an aralkyl group, an aralkenyl group, an alkylaryl group, an alkylamine group, an aralkylamine group, a heteroarylamine group, an arylamine group, an arylphosphine group, and a heterocyclic group containing at least one of N, O and S atoms, or being unsubstituted or substituted with a substituent group in which two or more substituent groups of the above-exemplified substituent groups are linked together. For example, “a substituent group in which two or more substituents are linked” can be a biphenylyl group. Namely, a biphenylyl group can be an aryl group, or it can be interpreted as a substituent group in which two phenyl groups are linked together. In one example, the term “substituted or unsubstituted” can be understood as meaning “being unsubstituted or substituted with one or more substituents selected from the group consisting of deuterium, halogen, cyano, a C₁₋₁₀ alkyl, a C₁₋₁₀ alkoxy and a C₆₋₂₀ aryl”, or “being unsubstituted or substituted with one or more substituents selected from the group consisting of deuterium, halogen, cyano, methyl, ethyl, phenyl and naphthyl”. Also, the term “substituted with one or more substituents” as used herein can be understood as meaning “being substituted with mono to the maximum number of substitutable hydrogens”. Alternatively, the term “substituted with one or more substituents” as used herein can be understood as meaning “being substituted with 1 to 5 substituents”, or “being substituted with one or two substituents”.

In the present disclosure, the carbon number of a carbonyl group is not particularly limited, but is preferably 1 to 40. Specifically, the carbonyl group can be a substituent group having the following structural formulas, but is not limited thereto:

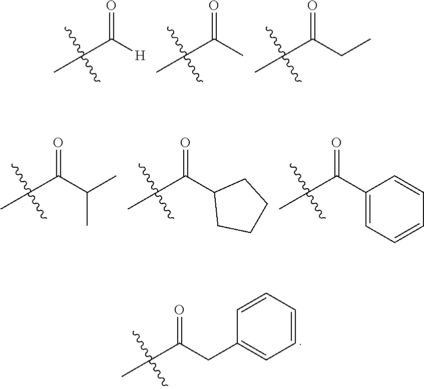

In the present disclosure, an ester group can have a structure in which oxygen of the ester group can be substituted by a straight-chain, branched-chain, or cyclic alkyl group having 1 to 25 carbon atoms, or an aryl group having 6 to 25 carbon atoms. Specifically, the ester group can be a substituent group having the following structural formulas, but is not limited thereto:

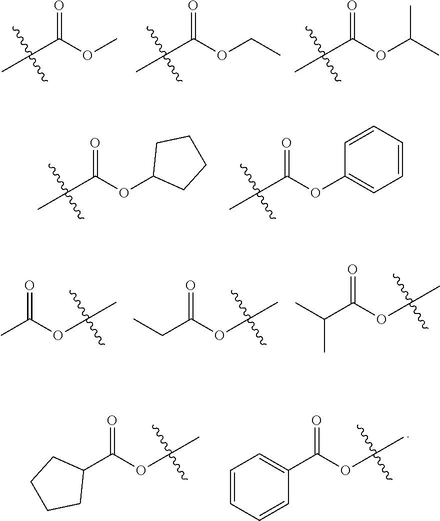

In the present disclosure, the carbon number of an imide group is not particularly limited, but is preferably 1 to 25. Specifically, the imide group can be a substituent group having the following structural formulas, but is not limited thereto:

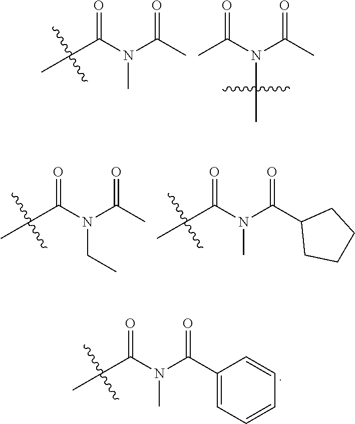

In the present disclosure, a silyl group specifically includes a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group and the like, but is not limited thereto.

In the present disclosure, a boron group specifically includes a trimethylboron group, a triethylboron group, a t-butyldimethylboron group, a triphenylboron group, and a phenylboron group, but is not limited thereto.

In the present disclosure, examples of a halogen group include fluorine, chlorine, bromine, or iodine.

In the present disclosure, the alkyl group can be straight-chain or branched-chain, and the carbon number thereof is not particularly limited, but is preferably 1 to 40. According to one embodiment, the carbon number of the alkyl group is 1 to 20. According to another embodiment, the carbon number of the alkyl group is 1 to 10.According to another embodiment, the carbon number of the alkyl group is 1 to 6.Specific examples of the alkyl group include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 4-methylhexyl, 5-methylhexyl, and the like, but are not limited thereto.

In the present disclosure, the alkenyl group can be straight-chain or branched-chain, and the carbon number thereof is not particularly limited, but is preferably 2 to 40. According to one embodiment, the carbon number of the alkenyl group is 2 to 20. According to another embodiment, the carbon number of the alkenyl group is 2 to 10. According to still another embodiment, the carbon number of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl) vinyl-1-yl, 2,2-bis (diphenyl-1-yl) vinyl-1-yl, a stilbenyl group, a styrenyl group, and the like, but are not limited thereto.

In the present disclosure, a cycloalkyl group is not particularly limited, but the carbon number thereof is preferably 3 to 60. According to one embodiment, the carbon number of the cycloalkyl group is 3 to 30. According to another embodiment, the carbon number of the cycloalkyl group is 3 to 20. According to still another embodiment, the carbon number of the cycloalkyl group is 3 to 6. Specific examples thereof include cyclopropyl, cyclobutyl, cyclopentyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, cyclooctyl, and the like, but are not limited thereto.

In the present disclosure, an aryl group is not particularly limited, but the carbon number thereof is preferably 6 to 60, and it can be a monocyclic aryl group or a polycyclic aryl group. According to one embodiment, the carbon number of the aryl group is 6 to 30. According to one embodiment, the carbon number of the aryl group is 6 to 20. The aryl group can be a phenyl group, a biphenyl group, a terphenyl group or the like as the monocyclic aryl group, but is not limited thereto. The polycyclic aryl group includes a naphthyl group, an anthracenyl group, a phenanthrenyl group, a pyrenyl group, a perylenyl group, a chrysenyl group, or the like, but is not limited thereto.

In the present disclosure, the fluorenyl group can be substituted, and two substituent groups can be linked with each other to form a spiro structure. In the case where the fluorenyl group is substituted,

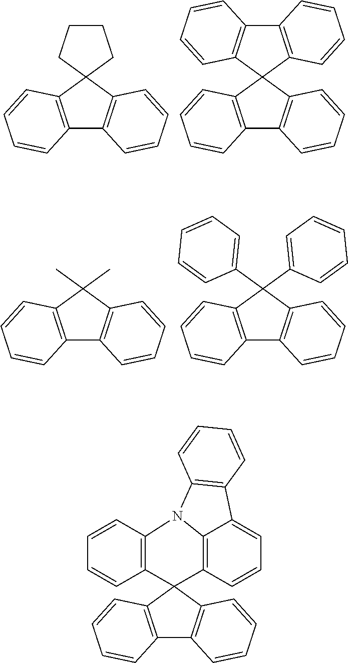

and the like can be formed. However, the structure is not limited thereto.

In the present disclosure, a heterocyclic group is a heterocyclic group containing one or more of O, N, Si and S as a heteroatom, and the carbon number thereof is not particularly limited, but is preferably 2 to 60. Examples of the heterocyclic group include a thiophene group, a furan group, a pyrrole group, an imidazole group, a thiazole group, an oxazol group, an oxadiazol group, a triazol group, a pyridyl group, a bipyridyl group, a pyrimidyl group, a triazine group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, a benzoxazole group, a benzoimidazole group, a benzothiazol group, a benzocarbazole group, a benzothiophene group, a dibenzothiophene group, a benzofuranyl group, a phenanthroline group, an isoxazolyl group, a thiadiazolyl group, a phenothiazinyl group, a dibenzofuranyl group, and the like, but are not limited thereto.

In the present disclosure, the aryl group in the aralkyl group, the aralkenyl group, the alkylaryl group and the arylamine group is the same as the aforementioned examples of the aryl group. In the present disclosure, the alkyl group in the aralkyl group, the alkylaryl group and the alkylamine group is the same as the aforementioned examples of the alkyl group. In the present disclosure, the heteroaryl in the heteroarylamine can be applied to the aforementioned description of the heterocyclic group. In the present disclosure, the alkenyl group in the aralkenyl group is the same as the aforementioned examples of the alkenyl group. In the present disclosure, the aforementioned description of the aryl group can be applied except that the arylene is a divalent group. In the present disclosure, the aforementioned description of the heterocyclic group can be applied except that the heteroarylene is a divalent group. In the present disclosure, the aforementioned description of the aryl group or cycloalkyl group can be applied except that the hydrocarbon ring is not a monovalent group but formed by combining two substituent groups. In the present disclosure, the aforementioned description of the heterocyclic group can be applied, except that the heterocycle is not a monovalent group but formed by combining two substituent groups.

In the present disclosure, the term “deuterated or substituted with deuterium” means that at least one of the substitutable hydrogens in a compound, a divalent linking group, or a monovalent substituent has been substituted with deuterium.

Also, the term “unsubstituted or substituted with deuterium” or “substituted or unsubstituted with deuterium” means that “mono to the maximum number of unsubstituted or substitutable hydrogens have been substituted with deuterium.” In one example, the term “phenanthryl unsubstituted or substituted with deuterium” can be understood as meaning “phenanthryl unsubstituted or substituted with 1 to 9 deuterium atoms”, considering that the maximum number of hydrogens that can be substituted with deuterium in the phenanthryl structure is 9.

In addition, the “deuterium substitution rate” or “degree of deuteration” of a compound means that the ratio of the number of substituted deuterium atoms to the total number of hydrogen atoms (the sum of the number of hydrogen atoms substitutable with deuterium and the number of substituted deuterium atoms in a compound) that can be present in the compound is calculated as a percentage. Therefore, when the “deuterium substitution rate” or “degree of deuteration” of a compound is “K %”, it means that K % of the hydrogen atoms substitutable with deuterium in the compound are substituted with deuterium.

At this time, the “deuterium substitution rate” or “degree of deuteration” can be measured according to a commonly known method using MALDI-TOF MS (Matrix-Assisted Laser Desorption/Ionization Time-of-Flight Mass Spectrometer), a nuclear magnetic resonance spectroscopy (¹H NMR), TLC/MS (Thin-Layer Chromatography/Mass Spectrometry), GC/MS (Gas Chromatography/Mass Spectrometry), or the like. More specifically, when using MALDI-TOF MS, the “deuterium substitution rate” or “degree of deuteration” is obtained by determining the number of substituted deuterium atoms in the compound through MALDI-TOF MS analysis, and then calculating the ratio of the number of substituted deuterium atoms to the total number of hydrogen atoms that can be present in the compound as a percentage.

Hereinafter, the present disclosure will be described in detail for each configuration.

### Anode and Cathode

An anode and a cathode used in the present disclosure mean electrodes used in an organic light emitting device.

As the anode material, generally, a material having a large work function is preferably used so that holes can be smoothly injected into the organic material layer. Specific examples of the anode material include metals such as vanadium, chrome, copper, zinc, and gold, or an alloy thereof: metal oxides such as zinc oxides, indium oxides, indium tin oxides (ITO), and indium zinc oxides (IZO); a combination of metals and oxides, such as ZnO:Al or SnO₂:Sb; conductive polymers such as poly (3-methylthiophene), poly [3,4-(ethylene-1,2-dioxy) thiophene] (PEDOT), polypyrrole, and polyaniline, and the like, but are not limited thereto.

As the cathode material, generally, a material having a small work function is preferably used so that electrons can be easily injected into the organic material layer. Specific examples of the cathode material include metals such as magnesium, calcium, sodium, potassium, titanium, indium, yttrium, lithium, gadolinium, aluminum, silver, tin, and lead, or an alloy thereof: a multilayered structure material such as LiF/Al or LiO₂/Al, and the like, but are not limited thereto.

### Light Emitting Layer

The light emitting layer used in the present disclosure is a layer that can emit light in the visible light region by combining holes and electrons transported from the anode and the cathode. Generally, the light emitting layer includes a host material and a dopant material, and in the present disclosure, the compound of Chemical Formula 1 and the compound of Chemical Formula 2 are included together as a host.

In Chemical Formula 1, preferably, L₁ is a single bond.

Preferably, every X₂ is N.

Preferably, each Ar₁ is independently phenyl which is unsubstituted or substituted with at least one deuterium, or biphenylyl which is unsubstituted or substituted with at least one deuterium.

Preferably, each R₁ is independently hydrogen, deuterium, or phenyl which is unsubstituted or substituted with at least one deuterium.

Further, the compound of Chemical Formula 1 may not contain deuterium, or may contain at least one deuterium.

When the compound of Chemical Formula 1 contains deuterium, the deuterium substitution rate of the compound may be 1% to 100%. Specifically, the deuterium substitution rate of the compound may be 5% or more, 10% or more, 20% or more, 30% or more, 40% or more, or 50% or more, and 100% or less, 90% or less, 80% or less, 70% or less, or 60% or less.

In one example, the compound of Chemical Formula 1 may not contain deuterium, or may contain 1 to 50 deuterium atoms. More specifically, the compound may contain no deuterium, or may contain 1 or more, 2 or more, 3 or more, 4 or more, 5 or more, 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium atoms.

Representative examples of the compound of Chemical Formula 1 are as follows:

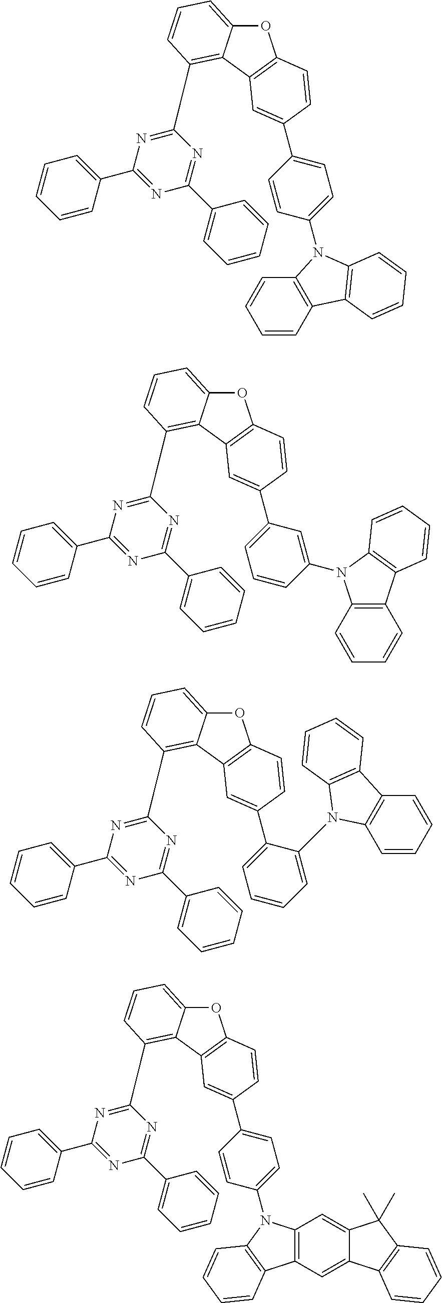 [SMILES: c1ccc(-c2nc(-c3ccccc3)nc(-c3cccc4oc5ccc(-c6ccc(-n7c8ccccc8c8ccccc87)cc6)cc5c34)n2)cc1 ; c1ccc(-c2nc(-c3ccccc3)nc(-c3cccc4oc5ccc(-c6cccc(-n7c8ccccc8c8ccccc87)c6)cc5c34)n2)cc1 ; c1ccc(-c2nc(-c3ccccc3)nc(-c3cccc4oc5ccc(-c6ccccc6-n6c7ccccc7c7ccccc76)cc5c34)n2)cc1 ; CC1(C)c2ccccc2-c2cc3c4ccccc4n(-c4ccc(-c5ccc6oc7cccc(-c8nc(-c9ccccc9)nc(-c9ccccc9)n8)c7c6c5)cc4)c3cc21]

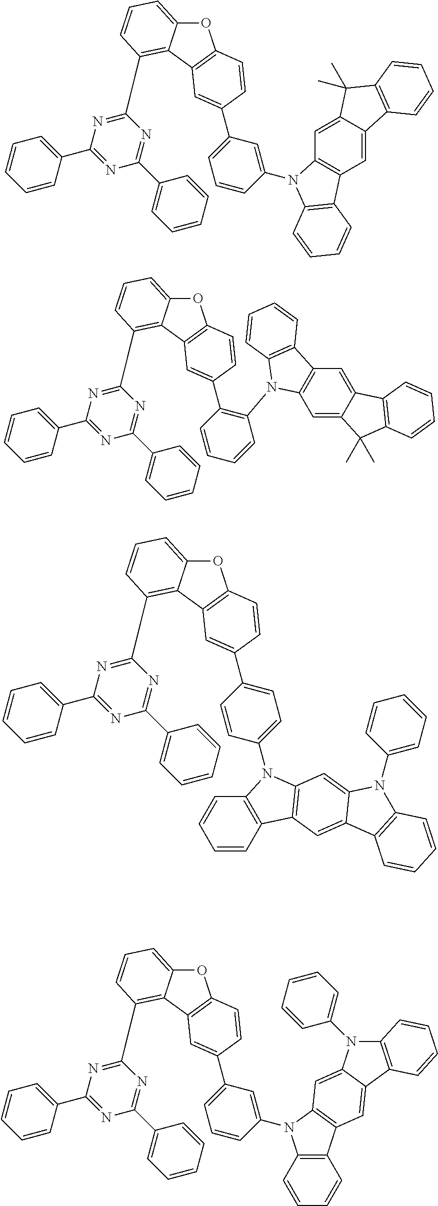

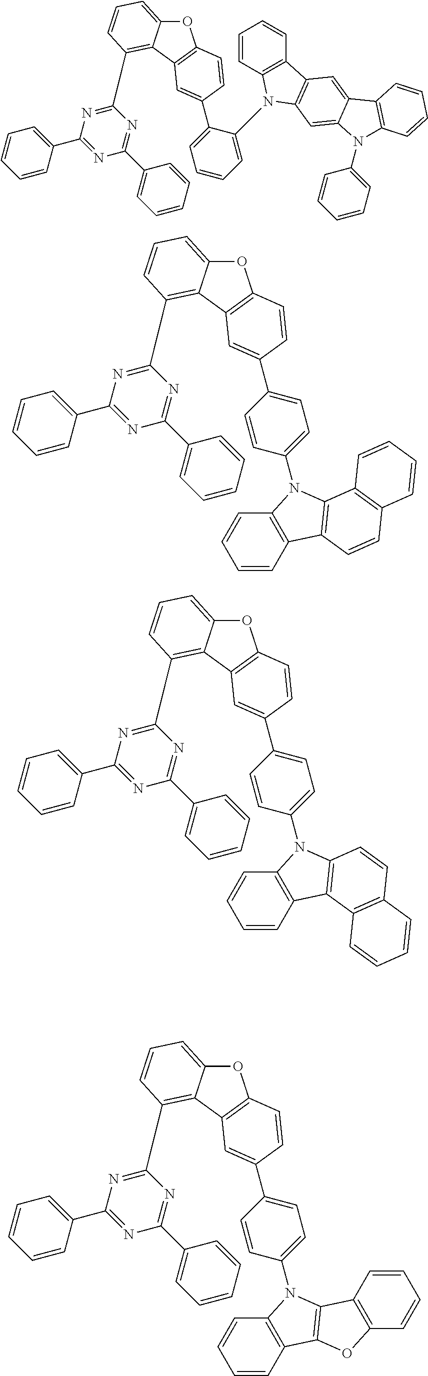

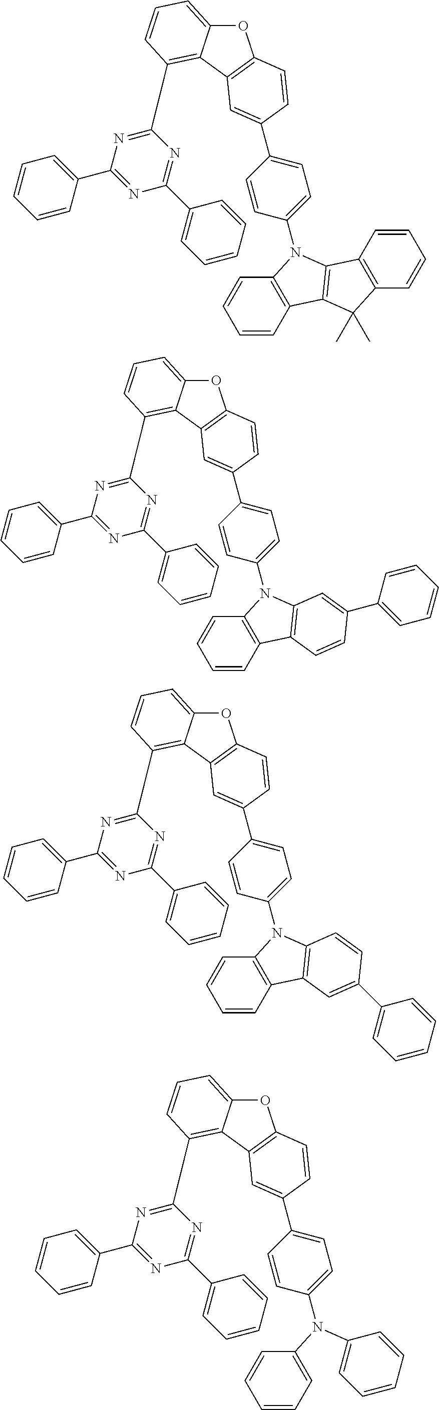

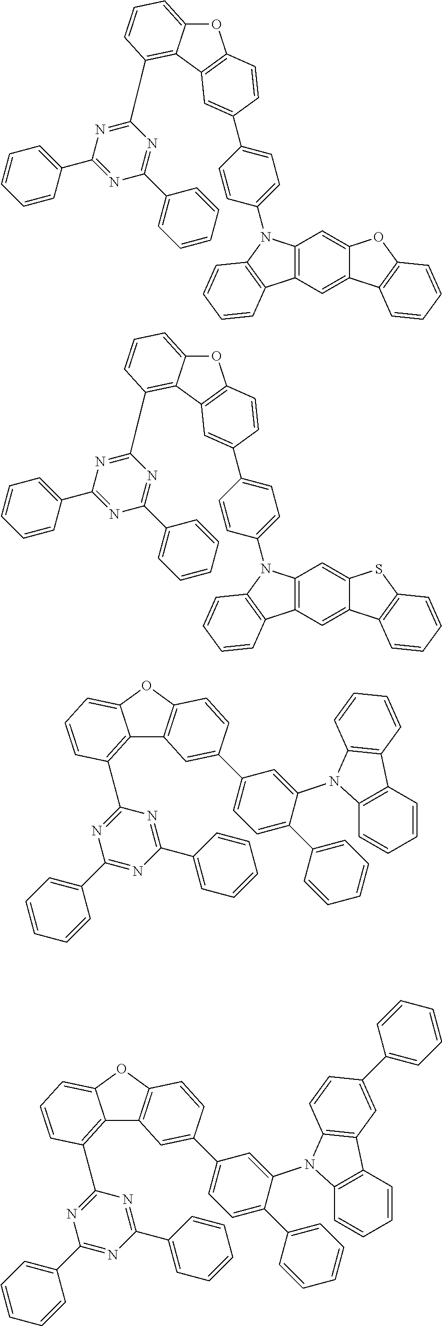

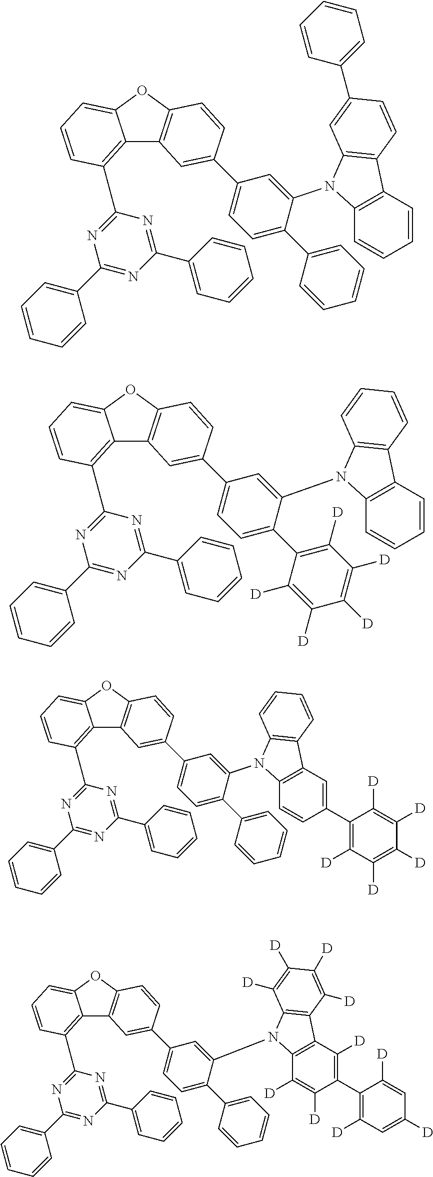

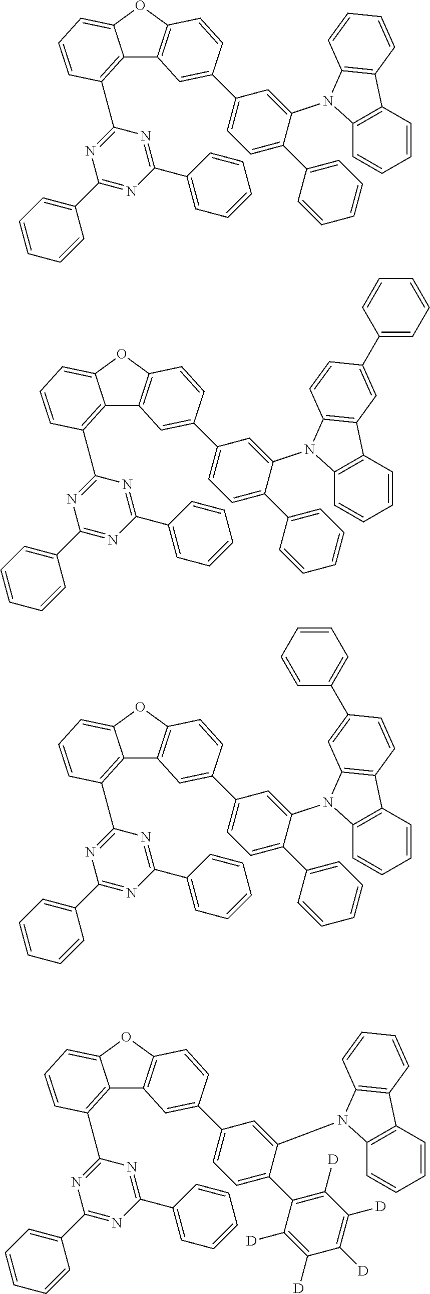 [SMILES: c1ccc(-c2nc(-c3ccccc3)nc(-c3cccc4oc5ccc(-c6ccc(-c7ccccc7)c(-n7c8ccccc8c8ccccc87)c6)cc5c34)n2)cc1 ; c1ccc(-c2ccc3c(c2)c2ccccc2n3-c2cc(-c3ccc4oc5cccc(-c6nc(-c7ccccc7)nc(-c7ccccc7)n6)c5c4c3)ccc2-c2ccccc2)cc1 ; c1ccc(-c2ccc3c4ccccc4n(-c4cc(-c5ccc6oc7cccc(-c8nc(-c9ccccc9)nc(-c9ccccc9)n8)c7c6c5)ccc4-c4ccccc4)c3c2)cc1 ; [2H]c1c([2H])c([2H])c(-c2ccc(-c3ccc4oc5cccc(-c6nc(-c7ccccc7)nc(-c7ccccc7)n6)c5c4c3)cc2-n2c3ccccc3c3ccccc32)c([2H])c1[2H]]

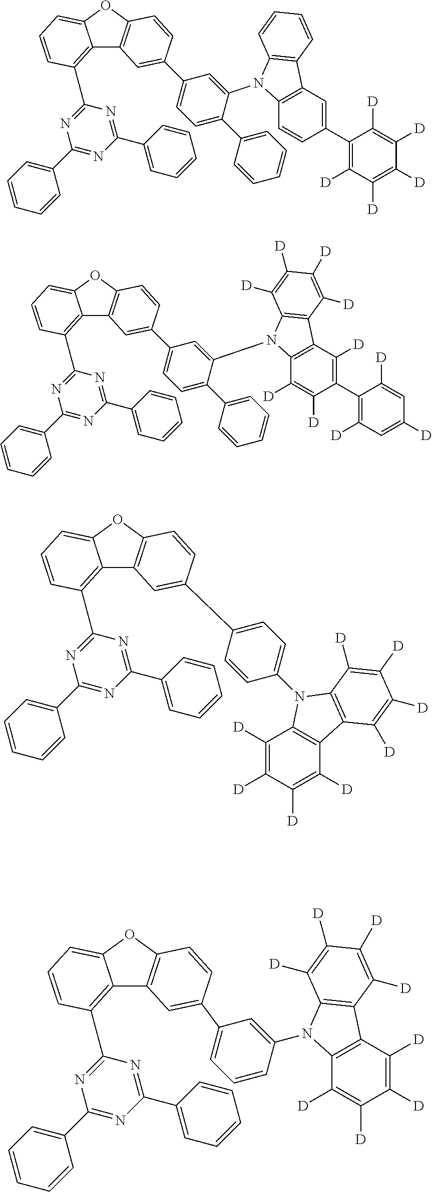

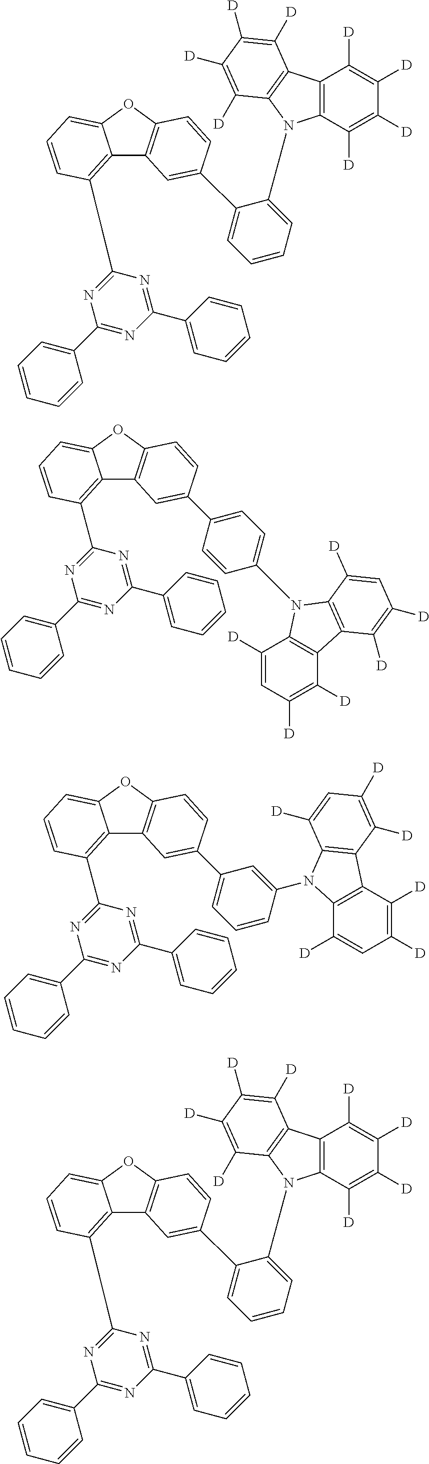

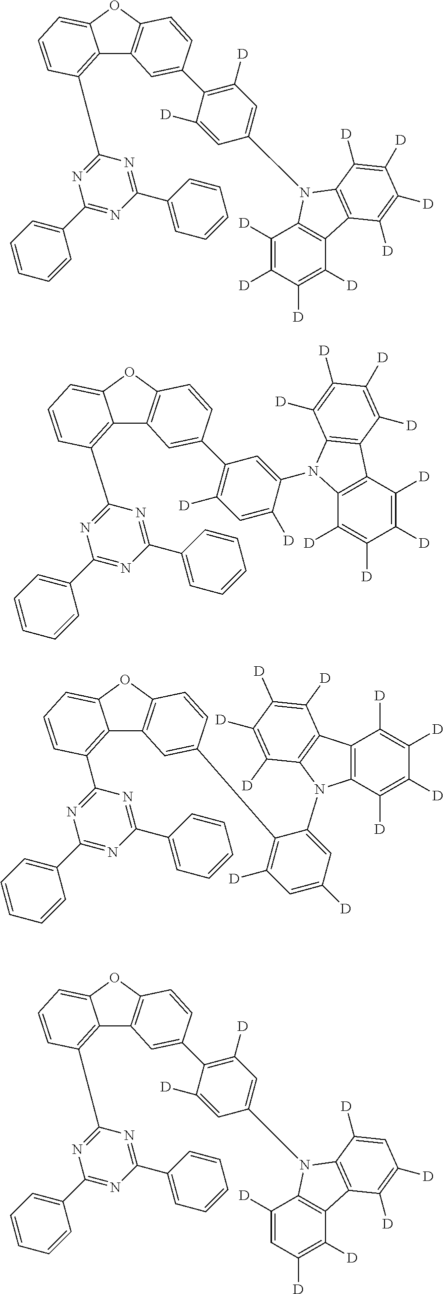

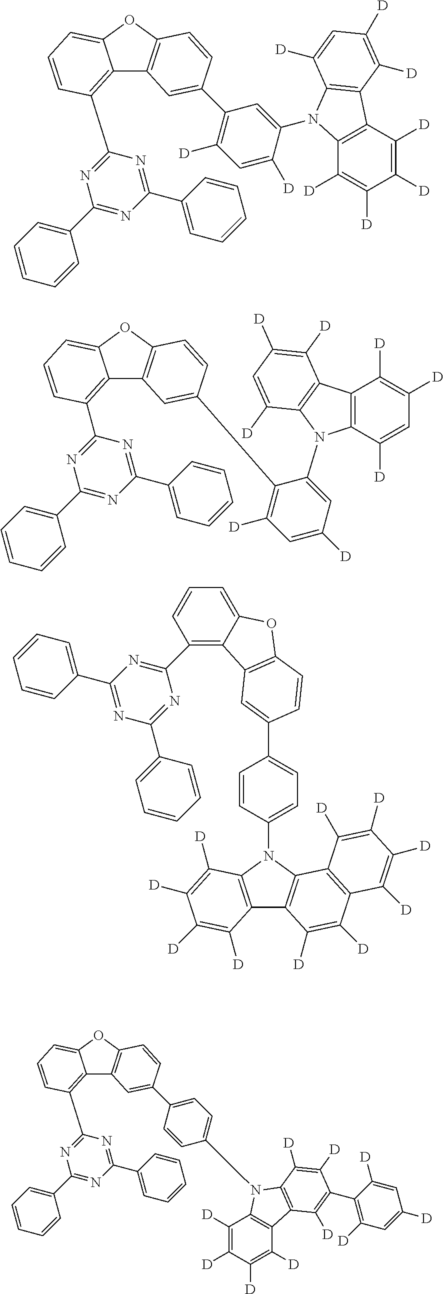

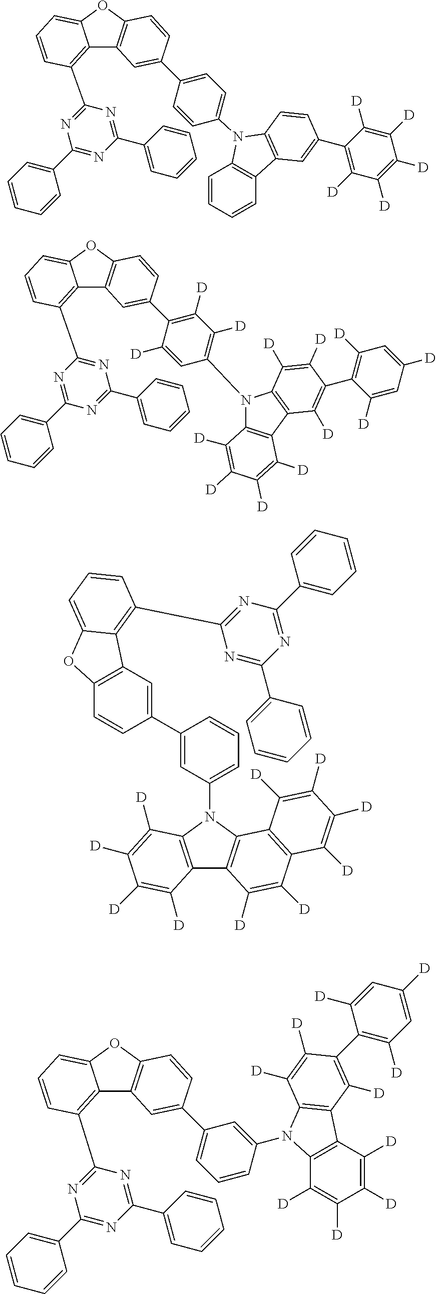

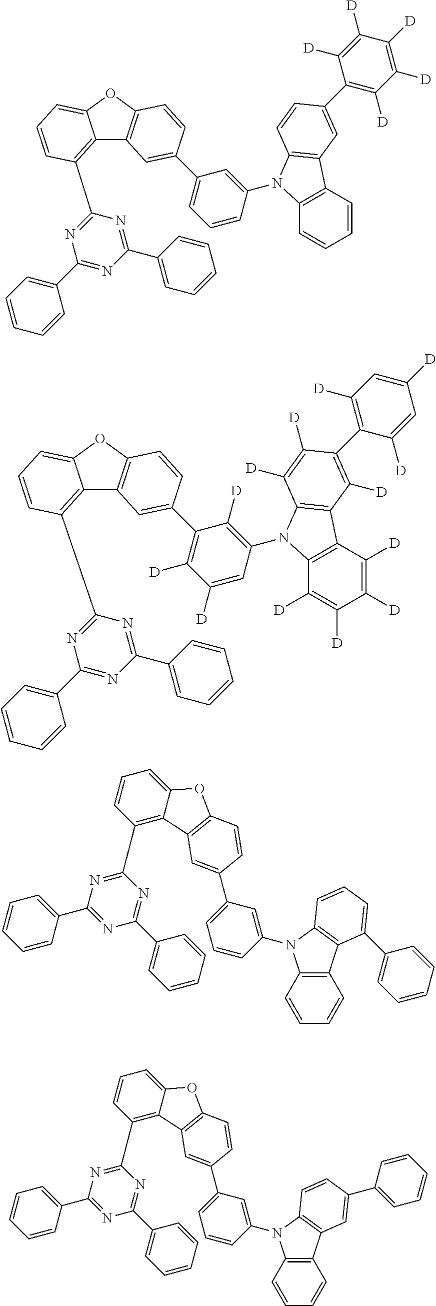 [SMILES: [2H]c1c([2H])c([2H])c(-c2ccc3c(c2)c2ccccc2n3-c2cccc(-c3ccc4oc5cccc(-c6nc(-c7ccccc7)nc(-c7ccccc7)n6)c5c4c3)c2)c([2H])c1[2H] ; [2H]c1cc([2H])c(-c2c([2H])c([2H])c3c(c2[2H])c2c([2H])c([2H])c([2H])c([2H])c2n3-c2cc([2H])c([2H])c(-c3ccc4oc5cccc(-c6nc(-c7ccccc7)nc(-c7ccccc7)n6)c5c4c3)c2[2H])c([2H])c1 ; c1ccc(-c2nc(-c3ccccc3)nc(-c3cccc4oc5ccc(-c6cccc(-n7c8ccccc8c8c(-c9ccccc9)cccc87)c6)cc5c34)n2)cc1 ; c1ccc(-c2ccc3c(c2)c2ccccc2n3-c2cccc(-c3ccc4oc5cccc(-c6nc(-c7ccccc7)nc(-c7ccccc7)n6)c5c4c3)c2)cc1]

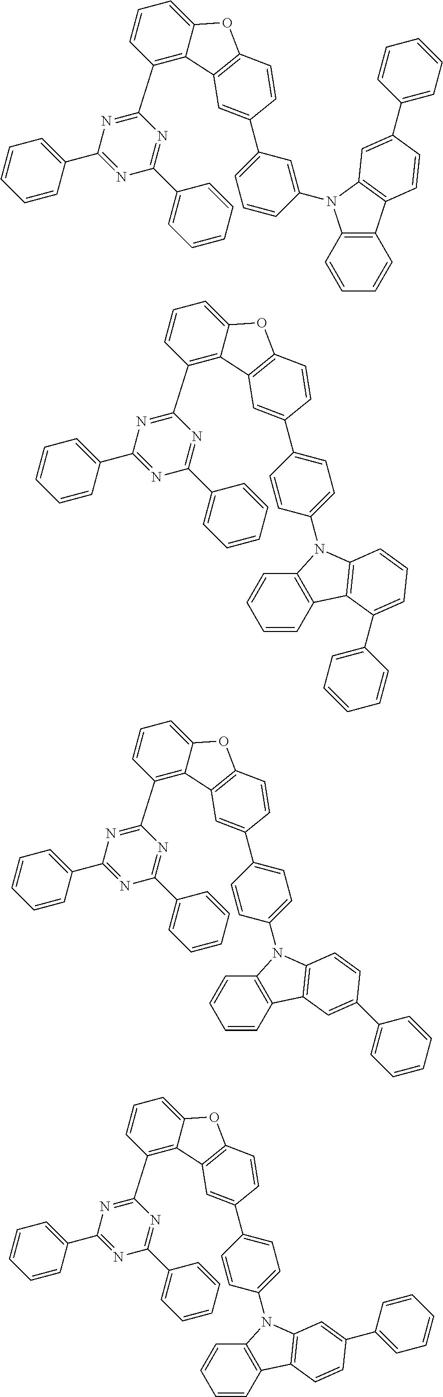 [SMILES: c1ccc(-c2ccc3c4ccccc4n(-c4cccc(-c5ccc6oc7cccc(-c8nc(-c9ccccc9)nc(-c9ccccc9)n8)c7c6c5)c4)c3c2)cc1 ; c1ccc(-c2nc(-c3ccccc3)nc(-c3cccc4oc5ccc(-c6ccc(-n7c8ccccc8c8c(-c9ccccc9)cccc87)cc6)cc5c34)n2)cc1 ; c1ccc(-c2ccc3c(c2)c2ccccc2n3-c2ccc(-c3ccc4oc5cccc(-c6nc(-c7ccccc7)nc(-c7ccccc7)n6)c5c4c3)cc2)cc1 ; c1ccc(-c2ccc3c4ccccc4n(-c4ccc(-c5ccc6oc7cccc(-c8nc(-c9ccccc9)nc(-c9ccccc9)n8)c7c6c5)cc4)c3c2)cc1]

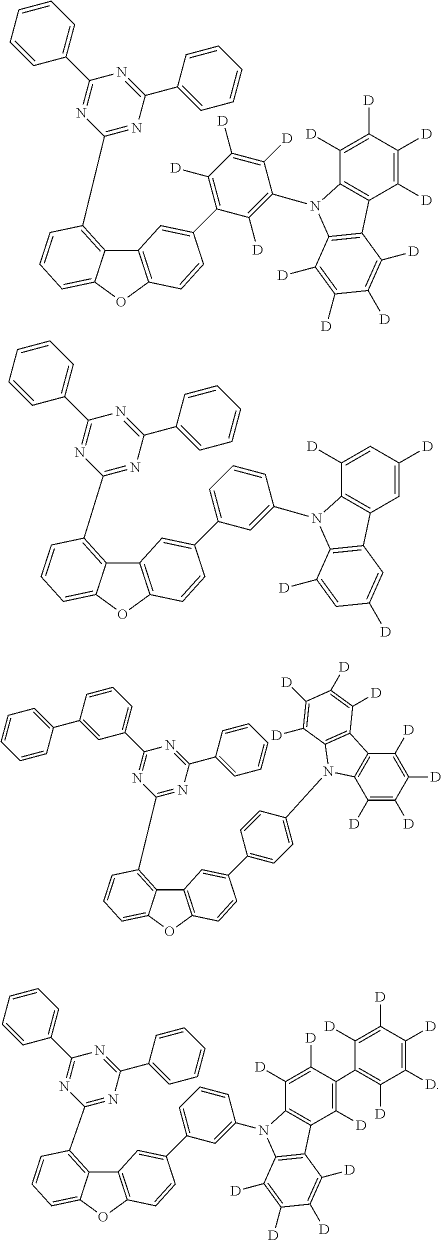

In Chemical Formula 2, preferably, Ar₂ and Ar₃ are each independently phenyl, biphenylyl, terphenylyl, naphthyl, dimethylfluorenyl, dibenzofuranyl, or dibenzothiophenyl; wherein Ar₂ and Ar₃ are unsubstituted or substituted with at least one deuterium.

More preferably, Ar₂ is phenyl, biphenylyl, terphenylyl, dimethylfluorenyl, dibenzofuranyl, or dibenzothiophenyl; and Ar₃ is phenyl, biphenylyl, or naphthyl; wherein Ar₂ and Ar₃ are unsubstituted or substituted with at least one deuterium.

Preferably, R₃ and R₄ are each independently hydrogen, deuterium, or phenyl which is unsubstituted or substituted with at least one deuterium.

Further, the deuterium substitution rate of the compound of Chemical Formula 2 may be 1% to 100%. Specifically, the deuterium substitution rate of the compound may be 5% or more, 10% or more, 20% or more, 30% or more, 40% or more, or 50% or more, and 100% or less, 90% or less, 80% or less, 70% or less, or 60% or less.

In one example, the compound of Chemical Formula 2 may contain 1 or more, 2 or more, 3 or more, 4 or more, 5 or more, 6 or more, 7 or more, 8 or more, or 9 or more, and 50 or less, 40 or less, 30 or less, 28 or less, 26 or less, 24 or less, 22 or less, 20 or less, 18 or less, 16 or less, 14 or less, 13 or less, 12 or less, 11 or less, or 10 or less deuterium atoms.

Representative examples of the compound of Chemical Formula 2 are as follows:

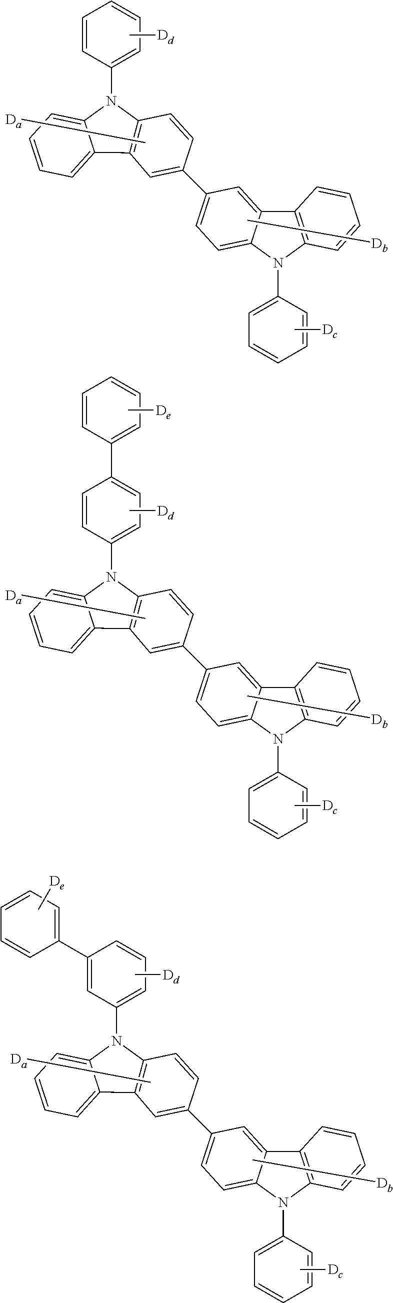

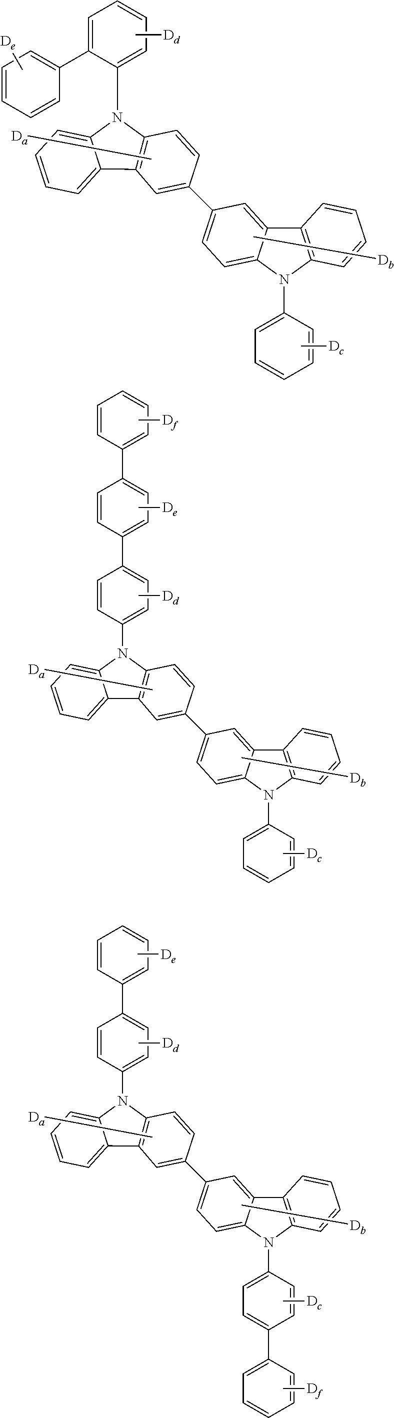

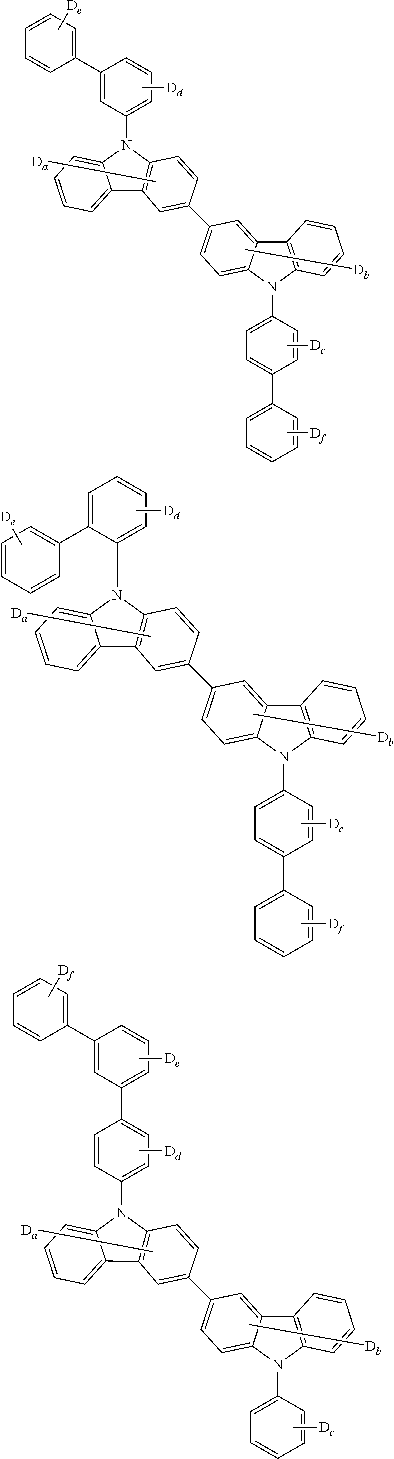

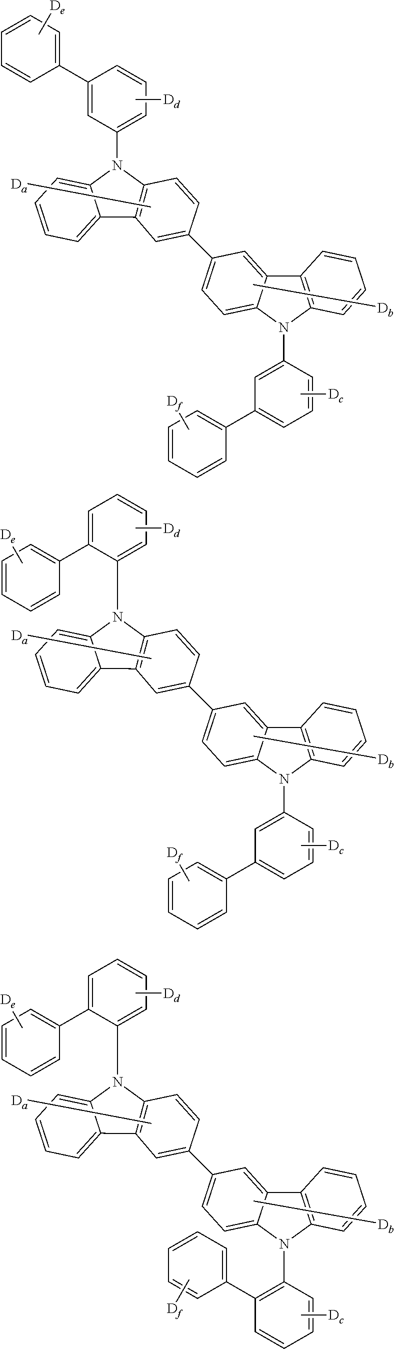

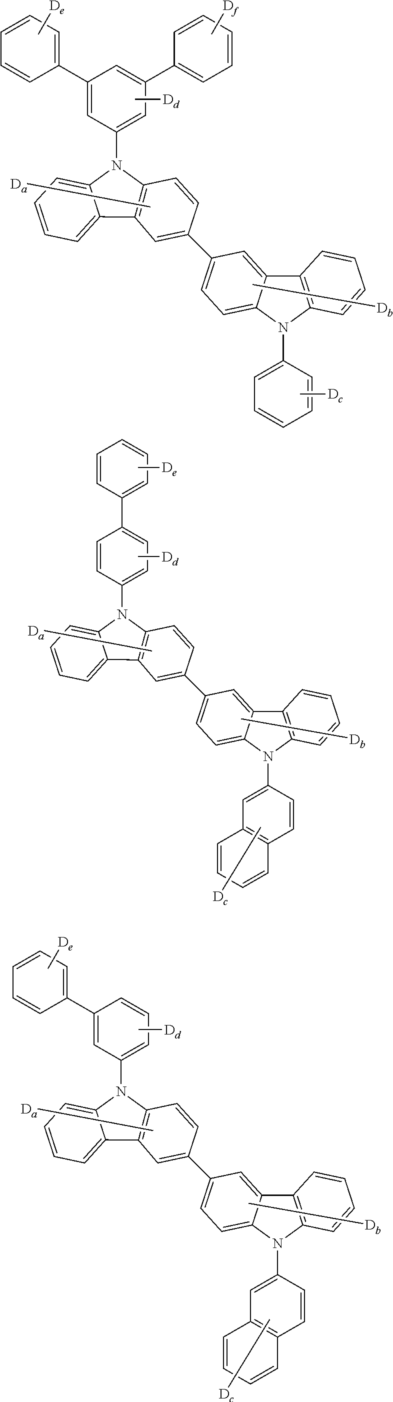

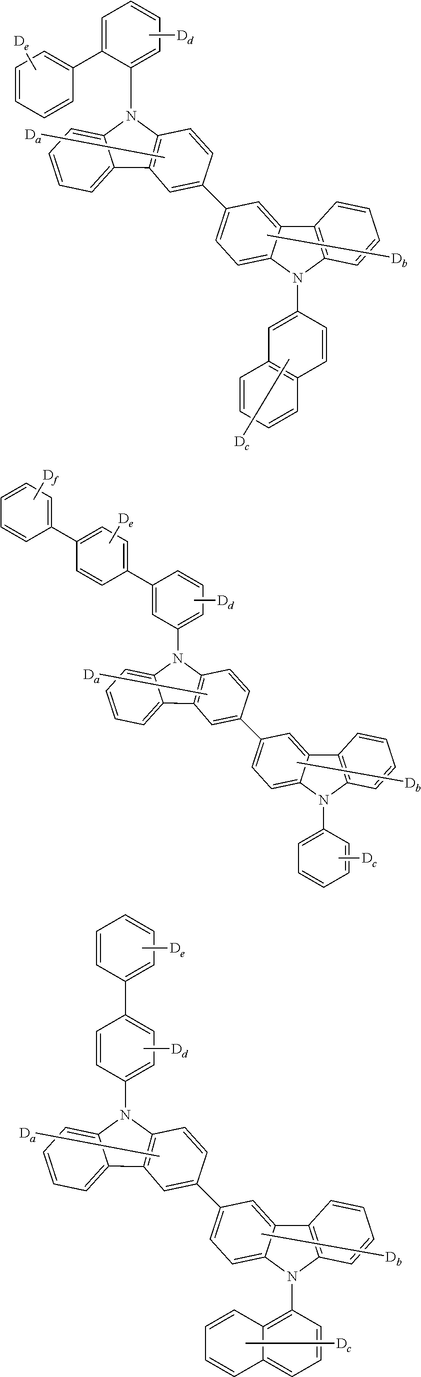

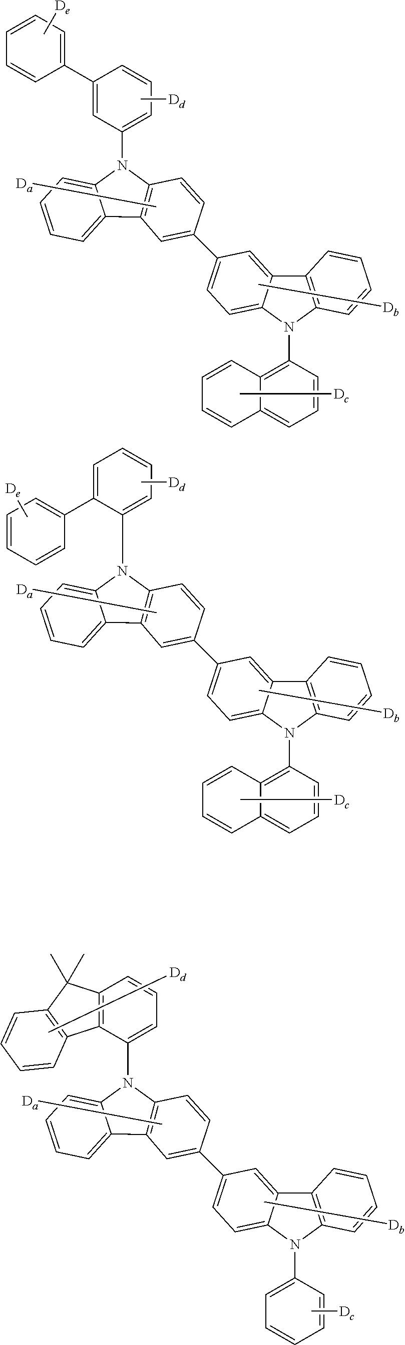

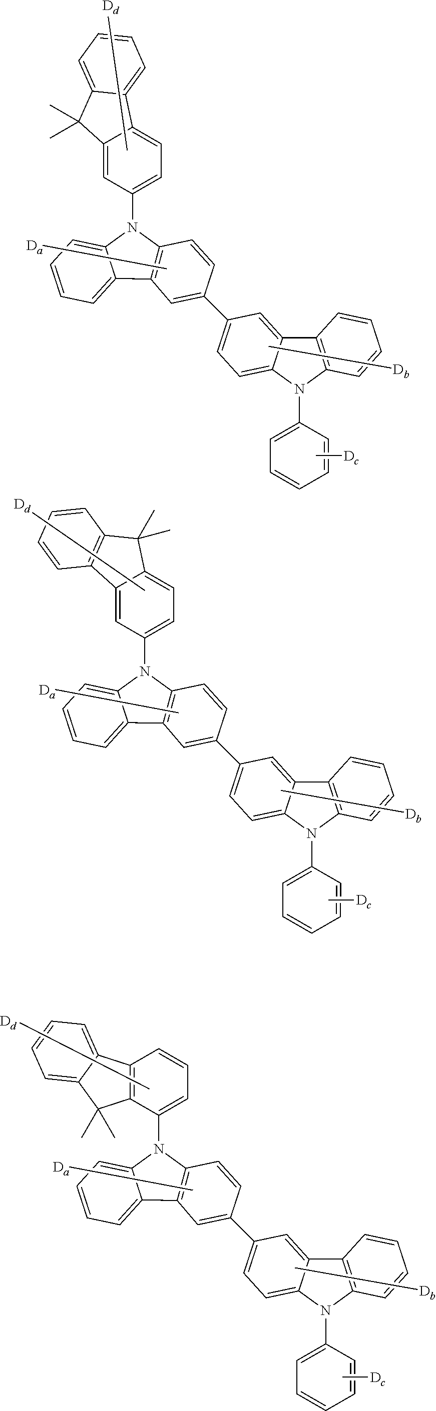

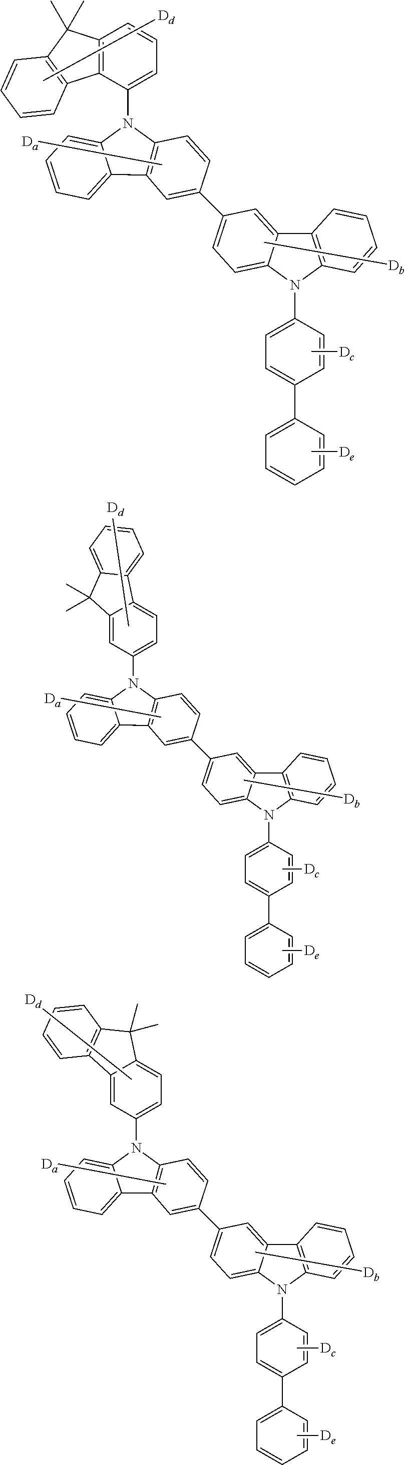

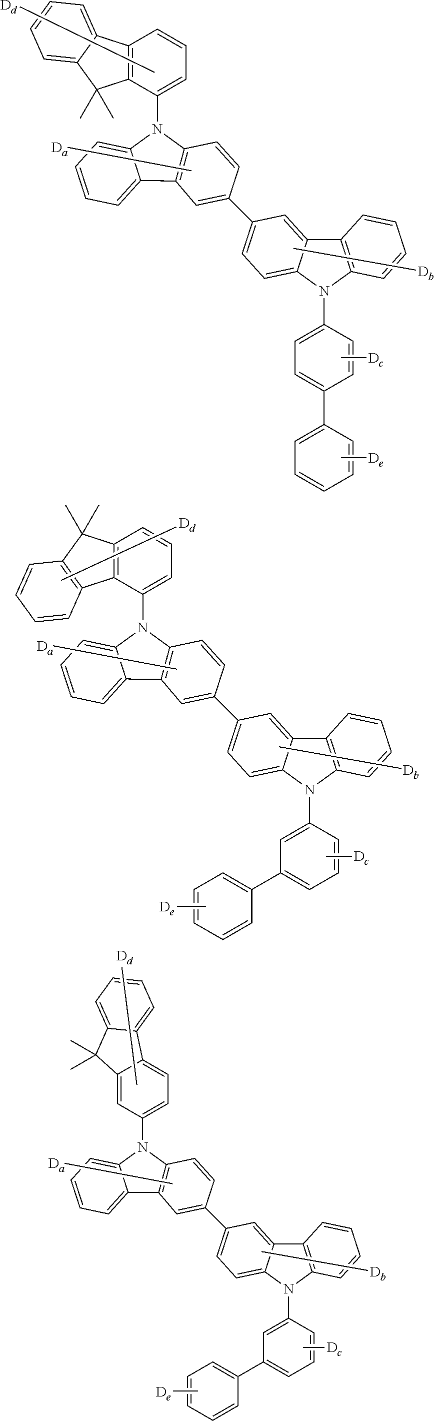

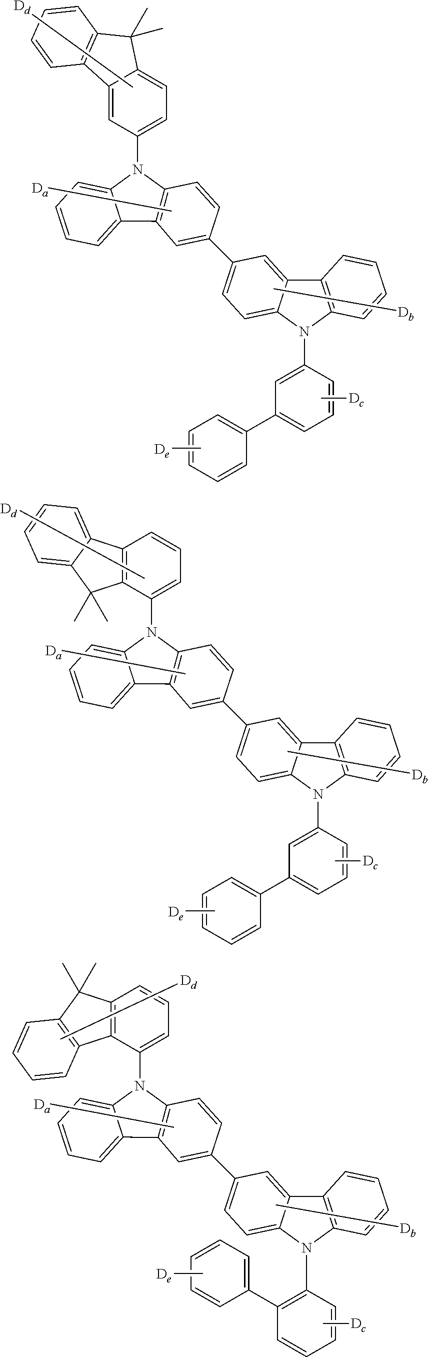

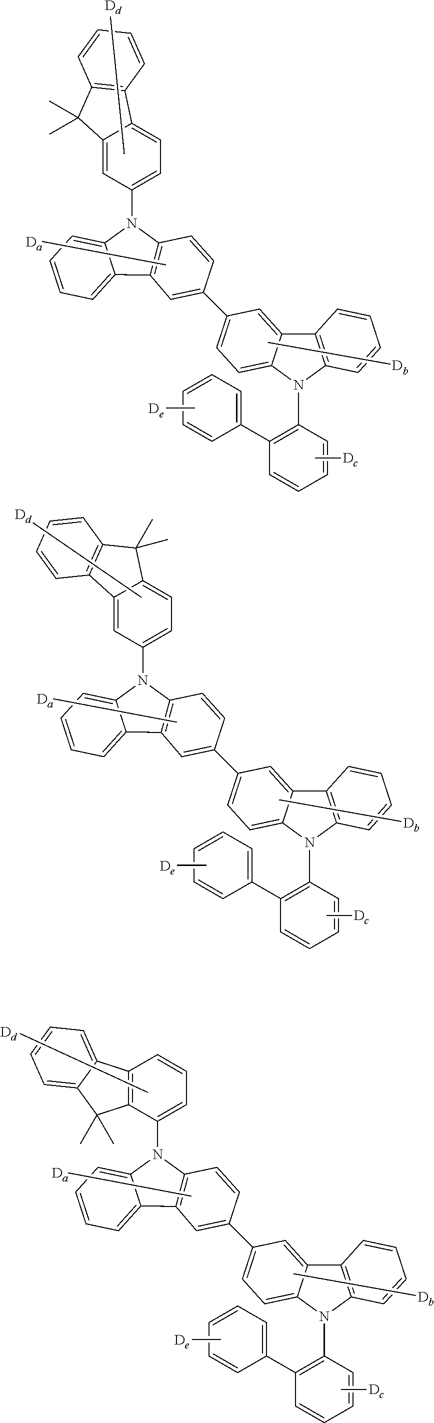

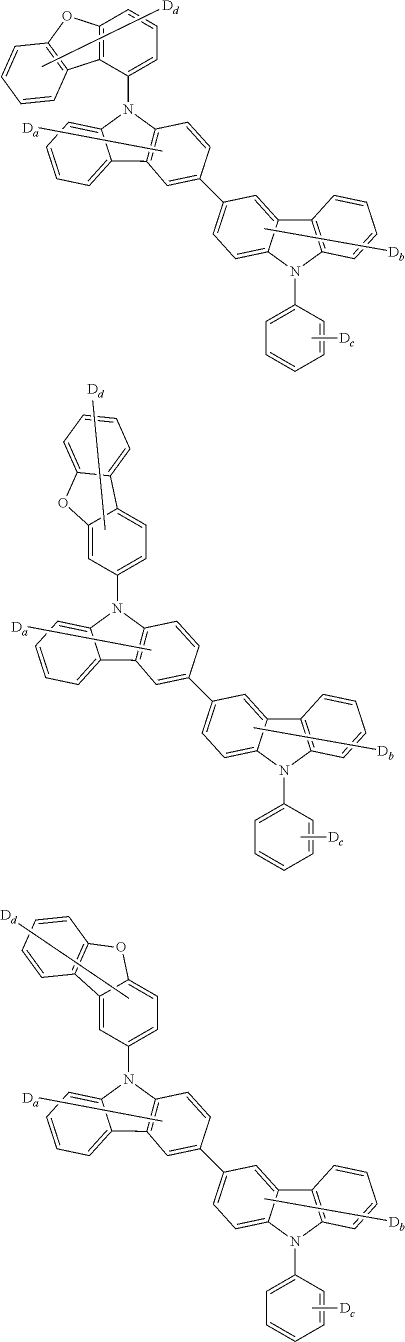

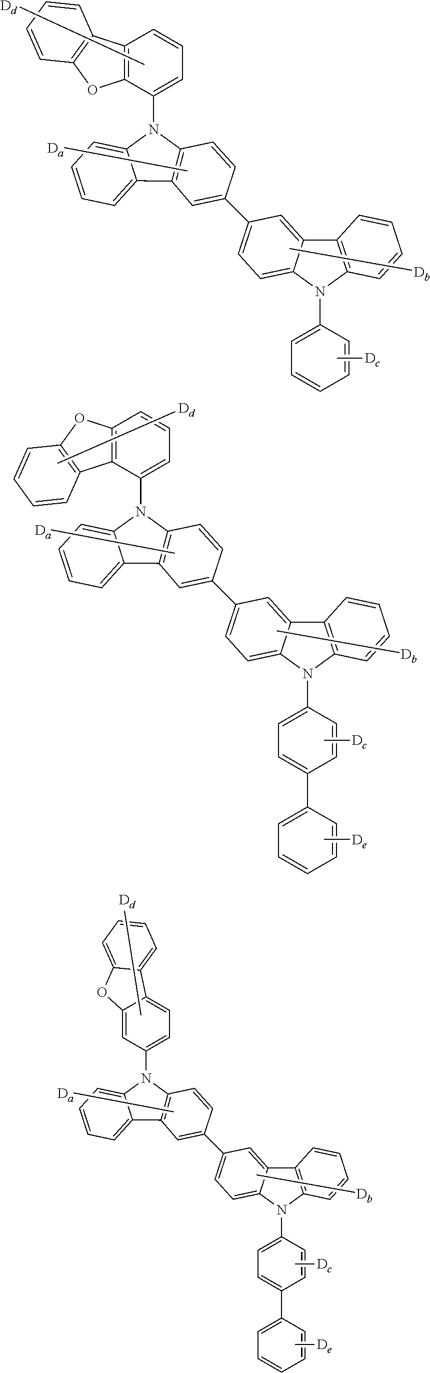

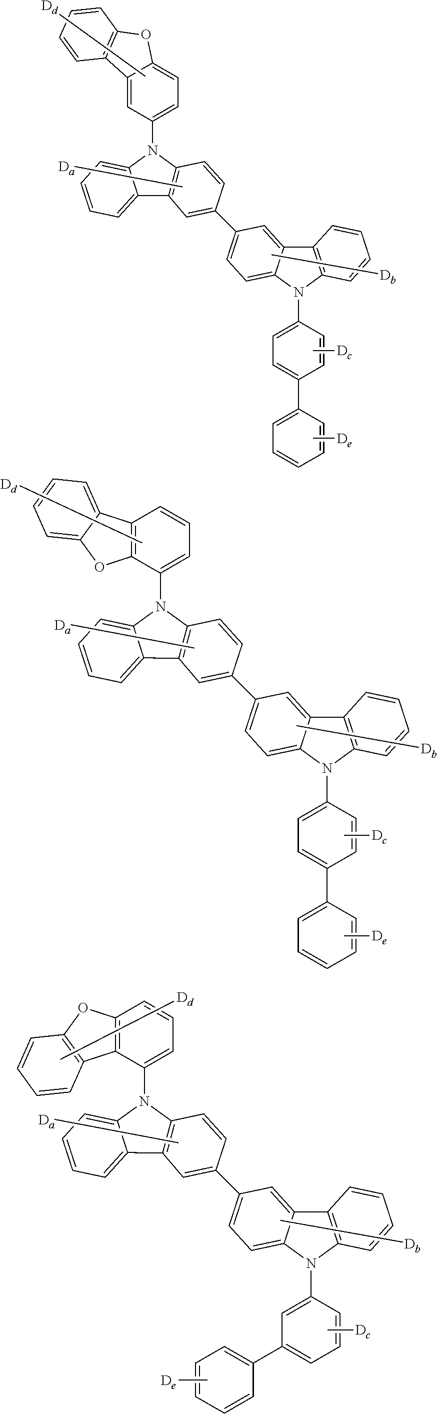

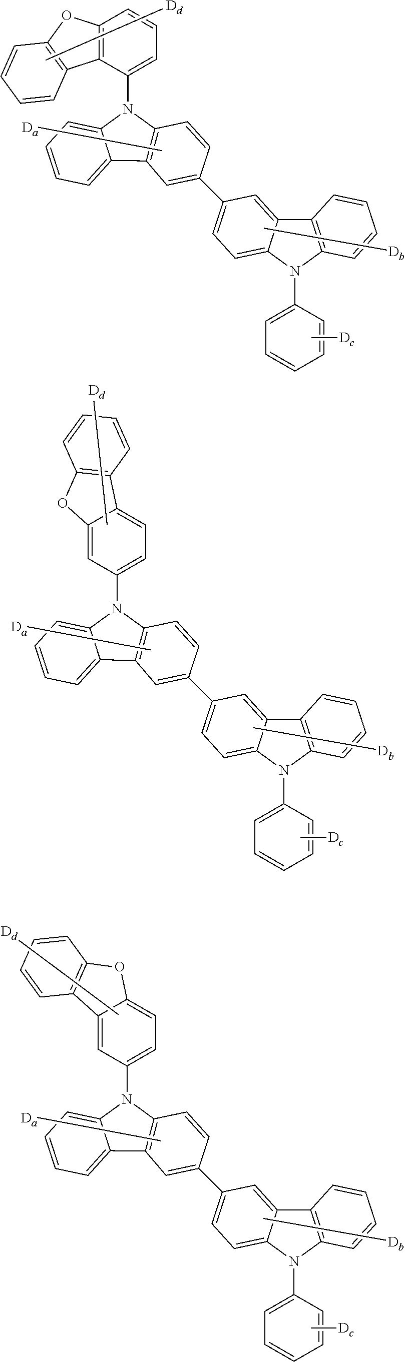

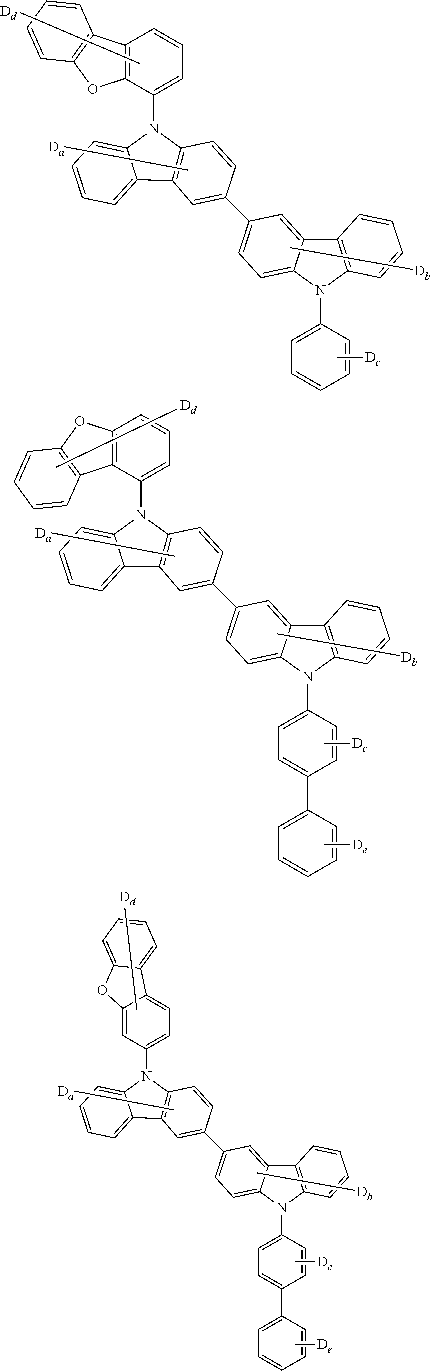

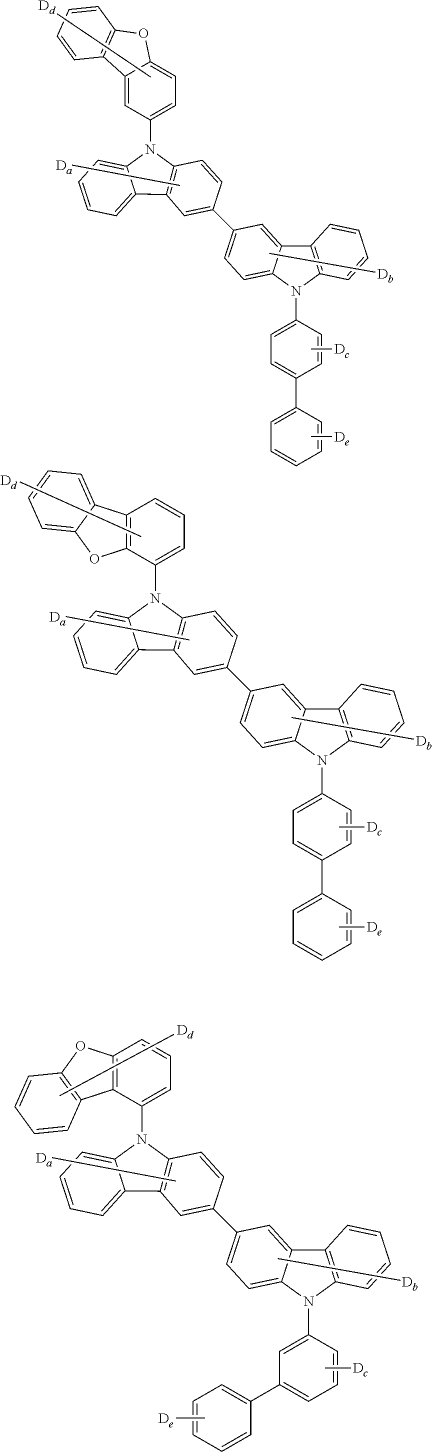

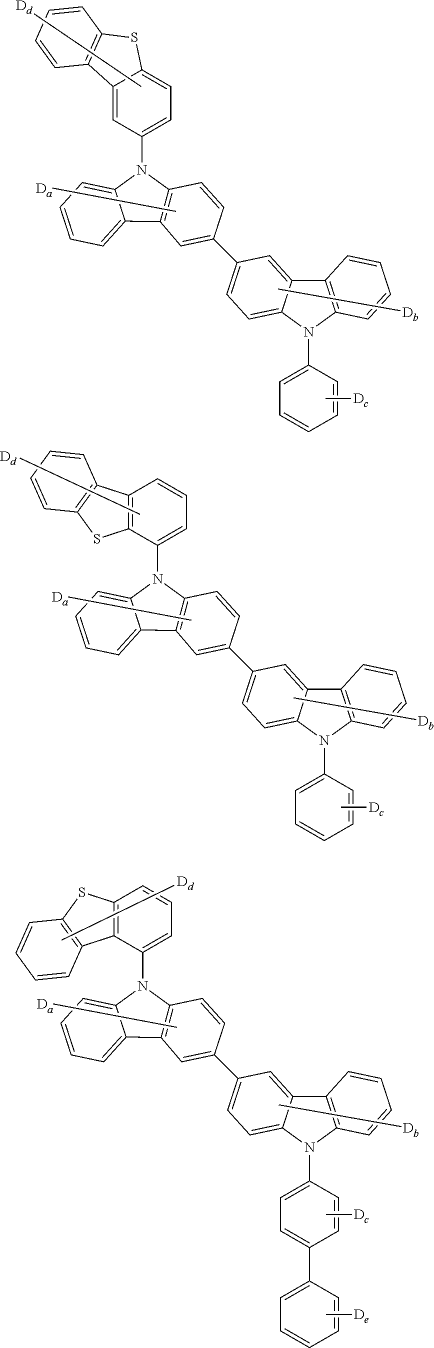

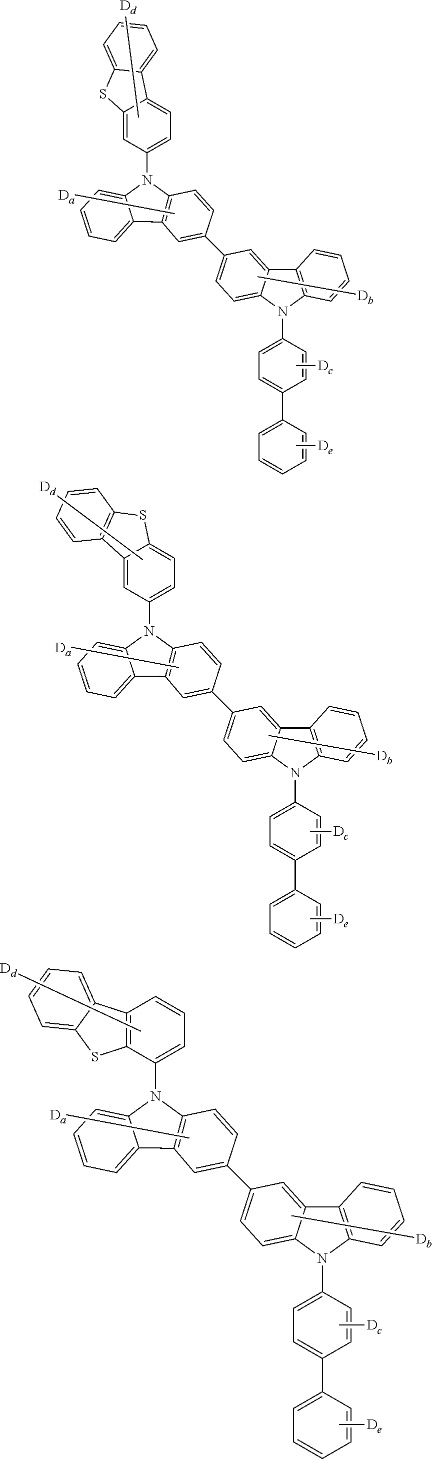

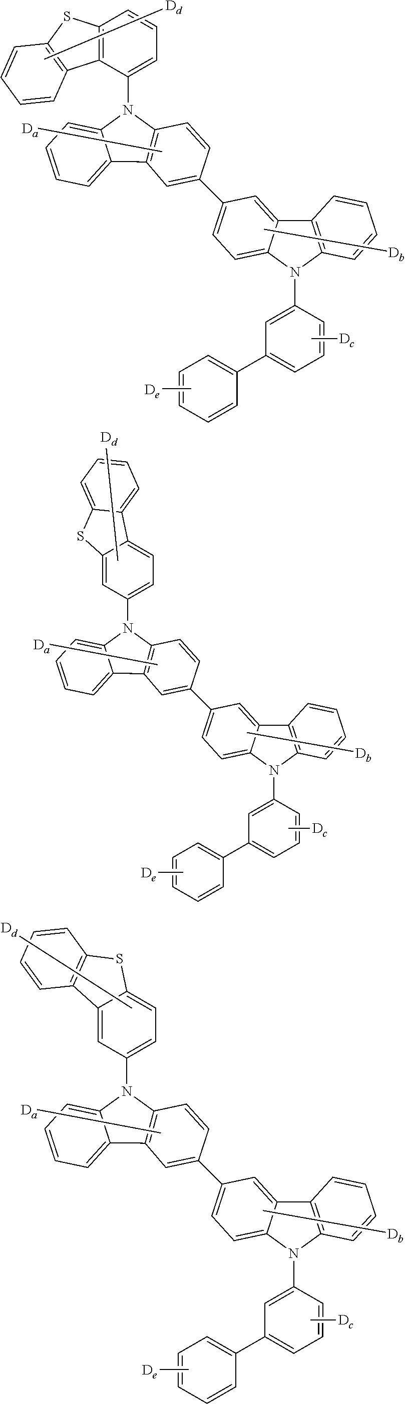

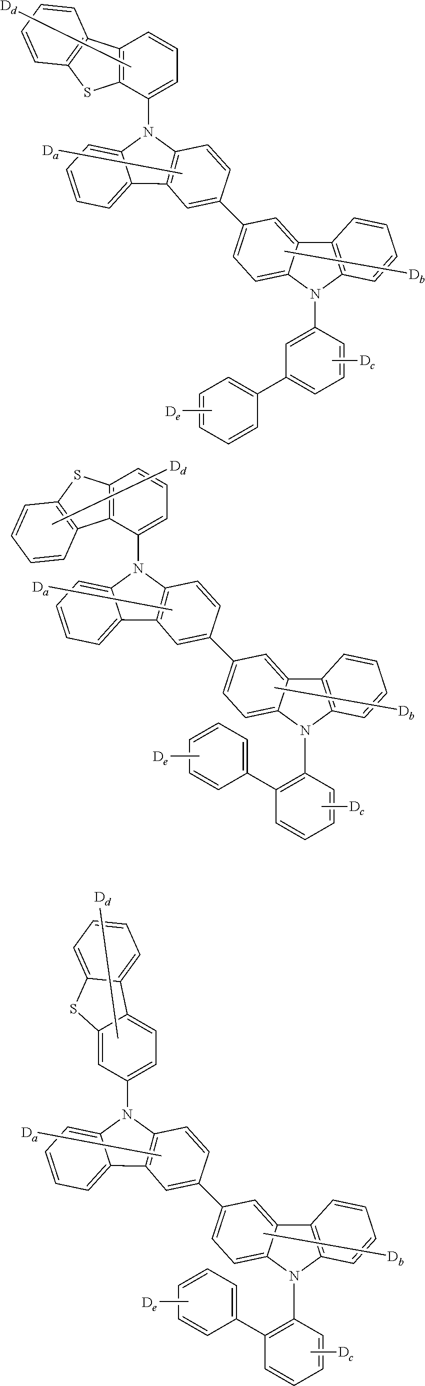

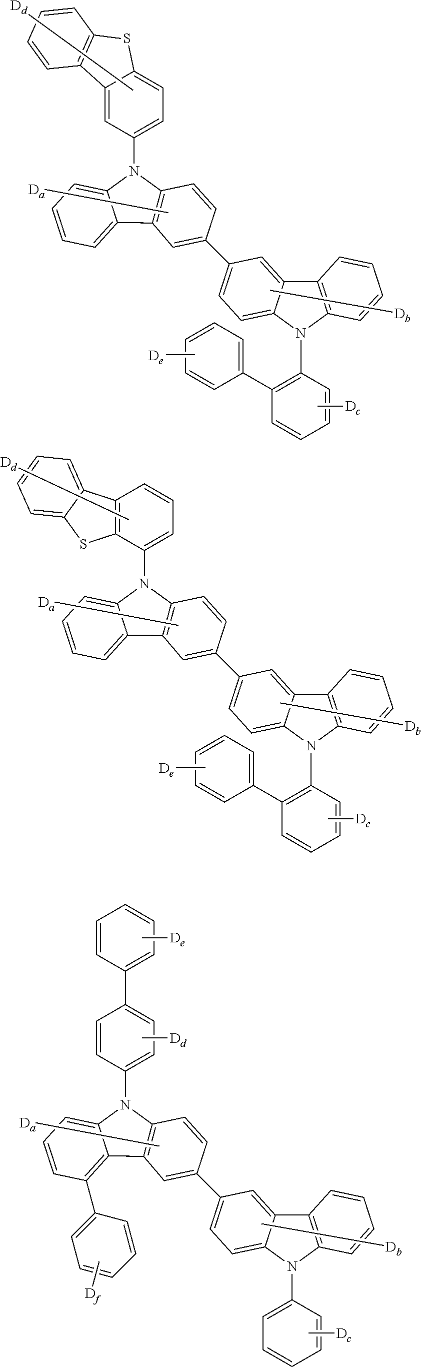

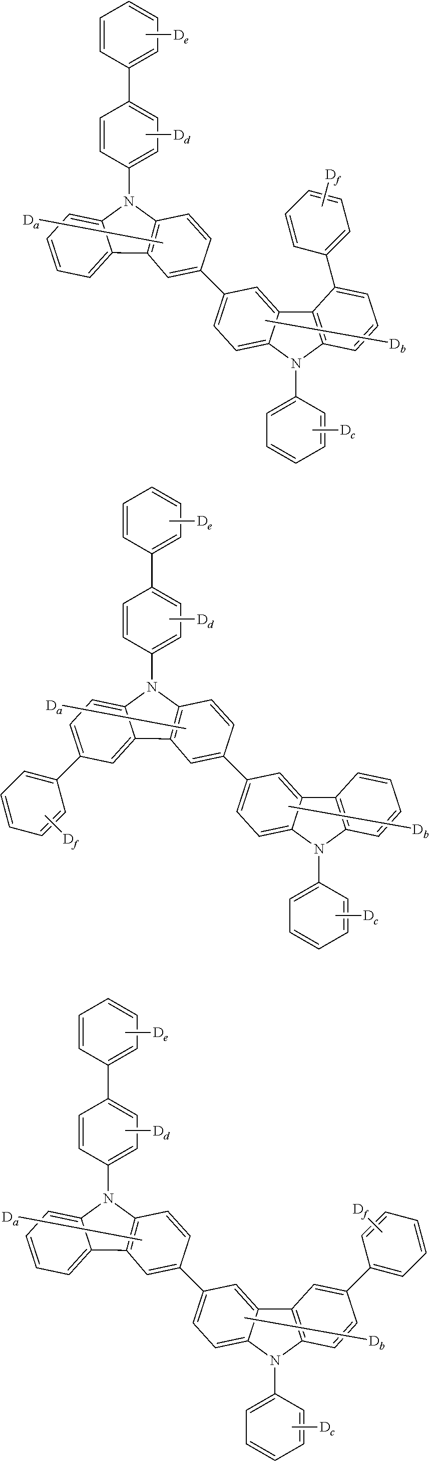

wherein, in the above group,
a is an integer of 0 to 7,
b is an integer of 0 to 7,
c is an integer of 0 to 7,
d is an integer of 0 to 7,
e is an integer of 0 to 5, and
f is an integer of 0 to 5,
provided that the sum of a to f is 1 or more.

In the above group, each compound is substituted with at least one deuterium.

Meanwhile, the dopant material is not particularly limited as long as it is a material used for the organic light emitting device. As an example, an aromatic amine derivative, a styrylamine compound, a boron complex, a fluoranthene compound, a metal complex, and the like can be mentioned. Specific examples of the aromatic amine derivatives include substituted or unsubstituted fused aromatic ring derivatives having a substituted or unsubstituted arylamino group, examples of which include pyrene, anthracene, chrysene, and periflanthene having the arylamino group, and the like. The styrylamine compound is a compound where at least one arylvinyl group is substituted in a substituted or unsubstituted arylamine, in which one or two or more substituent groups selected from the group consisting of an aryl group, a silyl group, an alkyl group, a cycloalkyl group, and an arylamino group are substituted or unsubstituted. Specific examples thereof include styrylamine, styryldiamine, styryltriamine, styryltetramine, and the like, but are not limited thereto. Further, examples of the metal complex include an iridium complex, a platinum complex, and the like, but are not limited thereto.

### Hole Transport Layer

The organic light emitting device according to the present disclosure can include a hole transport layer interposed between the light emitting layer and the anode.

The hole transport layer is a layer that receives holes from a hole injection layer and transports the holes to the light emitting layer. The hole transport material is suitably a material having large mobility to the holes, which can receive injection of holes from the anode or the hole injection layer and transfer the holes to the light emitting layer.

Specific examples of the hole transport material include an arylamine-based organic material, a conductive polymer, a block copolymer in which a conjugate portion and a non-conjugate portion are present together, and the like, but are not limited thereto.

### Hole Injection Layer

The organic light emitting device according to the present disclosure can further include a hole injection layer interposed between the anode and the hole transport layer, if necessary.

The hole injection layer is a layer injecting holes from an electrode, and the hole injection material is preferably a compound which has a capability of transporting the holes, has a hole injection effect in the anode and an excellent hole injection effect to the light emitting layer or the light emitting material, prevents movement of an exciton generated in the light emitting layer to the electron injection layer or the electron injection material, and is excellent in the ability to form a thin film. Further, it is preferable that a HOMO (highest occupied molecular orbital) of the hole injection material is between the work function of the anode material and a HOMO of a peripheral organic material layer.

Specific examples of the hole injection material include metal porphyrin, oligothiophene, an arylamine-based organic material, a hexanitrilehexaazatriphenylene-based organic material, a quinacridone-based organic material, a perylene-based organic material, anthraquinone, polyaniline and polythiophene-based conductive polymer, and the like, but are not limited thereto.

### Electron Blocking Layer

The electron blocking layer refers to a layer which is formed on the hole transport layer, preferably provided in contact with the light emitting layer, and serves to adjust the hole mobility, prevent excessive movement of electrons, and increase the probability of hole-electron coupling, thereby improving the efficiency of the organic light emitting device.

The electron blocking layer includes an electron blocking material, and as such an electron blocking material, a material having a stable structure that prevents electrons from flowing out of the light emitting layer is suitable.

Specific examples of such electron blocking material can include an arylamine-based organic material or the like, but is not limited thereto.

### Hole Blocking Layer

The hole blocking layer refers to a layer which is formed on the light emitting layer, and specifically, is provided in contact with the light emitting layer, and thus severs to prevent excessive movement of holes, and to increase the probability of hole-electron bonding, thereby improving the efficiency of the organic light emitting device. The hole blocking layer includes a hole blocking material, and as such a hole blocking material, a material having a stable structure that prevents holes from flowing out of the light emitting layer is suitable.

As the hole blocking material, a compound into which an electron-withdrawing group is introduced, such as azine derivatives including triazine; triazole derivatives; oxadiazole derivatives; phenanthroline derivatives; phosphine oxide derivatives can be used, but is not limited thereto.

### Electron Transport Layer

The organic light emitting device according to the present disclosure can include an electron transport layer interposed between the light emitting layer and the cathode.

The electron transport layer is a layer that receives the electrons from the cathode or the electron injection layer formed on the cathode and transports the electrons to the light emitting layer, and that suppress the transfer of holes from the light emitting layer, and an electron transport material is suitably a material which can receive well injection of electrons from a cathode and transfer the electrons to a light emitting layer, and has a large mobility for electrons.

Specific examples of the electron transport material include: an Al complex of 8-hydroxyquinoline; a complex including Alq₃; an organic radical compound; a hydroxyflavone-metal complex, and the like, but are not limited thereto. The electron transport layer can be used with any desired cathode material, as used according to a conventional technique. In particular, appropriate examples of the cathode material are a typical material which has a low work function, followed by an aluminum layer or a silver layer. Specific examples thereof include cesium, barium, calcium, ytterbium, and samarium, in each case followed by an aluminum layer or a silver layer.

### Electron Injection Layer

The organic light emitting device according to the present disclosure can further include an electron injection layer interposed between the electron transport layer and the cathode.

The electron injection layer is a layer which injects electrons from an electrode, and is preferably a compound which has a capability of transporting electrons, has an effect of injecting electrons from a cathode and an excellent effect of injecting electrons into a light emitting layer or a light emitting material, prevents excitons produced from the light emitting layer from moving to a hole injection layer, and is also excellent in the ability to form a thin film.

Specific examples of the electron injection layer include fluorenone, anthraquinodimethane, diphenoquinone, thiopyran dioxide, oxazole, oxadiazole, triazole, imidazole, perylenetetracarboxylic acid, fluorenylidene methane, anthrone, and the like, and derivatives thereof, a metal complex compound, a nitrogen-containing 5-membered ring derivative, and the like, but are not limited thereto.

Examples of the metal complex compound include 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato) aluminum, tris(8-hydroxyquinolinato)gallium, bis(10-hydroxy benzo[h] quinolinato)beryllium, bis(10-hydroxybenzo[h] quinolinato)zinc, bis(2-methyl-8-hydroxyquinolinato) chlorogallium, bis(2-methyl-8-hydroxyquinolinato)(o-cresolato)gallium, bis(2-methyl-8-hydroxyquinolinato)(1-naphtholato)aluminum, bis(2-methyl-8-hydroxyquinolinato)(2-naphtholato)gallium, and the like, but are not limited thereto.

### Organic Light Emitting Device

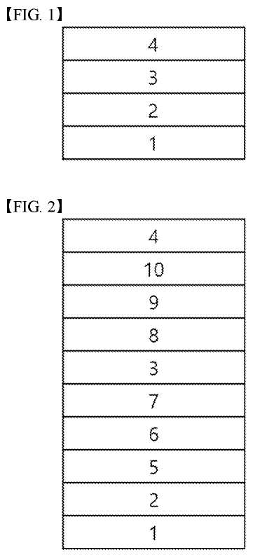

The structure of the organic light emitting device according to the present disclosure is illustrated in FIG. 1. FIG. 1 shows an example of an organic light emitting device comprising a substrate 1, an anode 2, a light emitting layer 3, and a cathode 4. FIG. 2 shows an example of an organic light emitting device comprising a substrate 1, an anode 2, a hole injection layer 5, a hole transport layer 6, an electron blocking layer 7, a light emitting layer 3, a hole blocking layer 8, an electron transport layer 9, an electron injection layer 10, and a cathode 4.

The organic light emitting device according to the present disclosure can be manufactured by sequentially stacking the above-described structures. In this case, the organic light emitting device can be manufactured by depositing a metal, metal oxides having conductivity, or an alloy thereof on the substrate by using a PVD (physical vapor deposition) method such as a sputtering method or an e-beam evaporation method to form the anode, forming the respective layers described above thereon, and then depositing a material that can be used as the cathode thereon. In addition to such a method, the organic light emitting device can be manufactured by sequentially depositing from the cathode material to the anode material on a substrate in the reverse order of the above-mentioned configuration (WO 2003/012890). Further, the light emitting layer can be formed by subjecting hosts and dopants to a vacuum deposition method and a solution coating method Herein, the solution coating method means a spin coating, a dip coating, a doctor blading, an inkjet printing, a screen printing, a spray method, a roll coating, or the like, but is not limited thereto.

In addition to such a method, the organic light emitting device can be manufactured by sequentially depositing from the cathode material to the organic material layer and the anode material on a substrate (WO 2003/012890).

Meanwhile, the organic light emitting device according to the present disclosure can be a bottom emission device, a top emission device, or a double-sided light emitting device, and particularly, can be a bottom emission device that requires relatively high luminous efficiency.

Below, preferable embodiments are presented to assist in the understanding of the present disclosure. The following examples are only provided for a better understanding of the present disclosure, and is not intended to limit the content of the present disclosure.

### Synthesis Example: Preparation of Intermediate Compounds P-1 to P-9

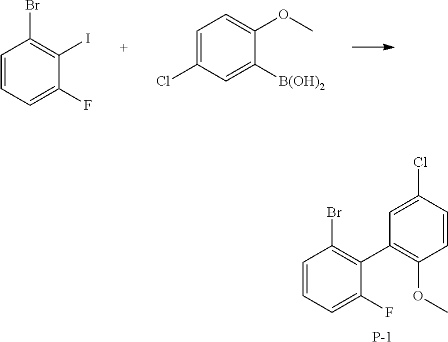

1-Bromo-3-fluoro-2-iodobenzene (100 g, 333.5 mmol) and (5-chloro-2-methoxyphenyl) boronic acid (62.2 g, 333.5 mmol) were dissolved in 800 ml of tetrahydrofuran(THF). Sodium carbonate (Na₂CO₃) 2M solution (500 mL) and tetrakis(triphenylphosphine)palladium(0) [Pd (PPh₃)_{4]} (7.7 g, 6.7 mmol) were added thereto, and the mixture was refluxed for 12 hours. After the reaction was completed, the mixture was cooled to room temperature, and the resulting mixture was extracted with water and toluene three times. The toluene layer was separated, dried over magnesium sulfate, filtered, and the filtrate was distilled under reduced pressure. The resulting mixture was recrystallized three times using chloroform and ethanol to give Compound P-1 (53.7 g, yield: 51%).

MS:[M+H]⁺=314

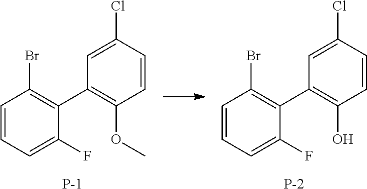

Compound P-1 (50.0 g, 158.5 mmol) was dissolved in dichloromethane (600 ml) and then cooled at 0° C. Boron tribromide (15.8 ml, 166.4 mmol) was slowly added dropwise and then stirred for 12 hours. After the reaction was completed, the mixture was washed with water three times, dried over magnesium sulfate, filtered, and the filtrate was distilled under reduced pressure and purified by column chromatography to give Compound P-2 (47.4 g, yield: 99%).

MS: [M+H]⁺=300

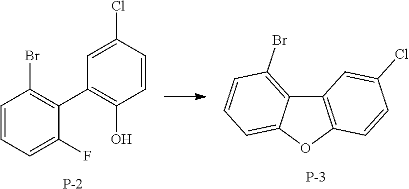

Compound P-2 (40.0 g, 132.7 mmol) was dissolved in distilled dimethylformamide (DMF) (400 ml). The solution was cooled to 0° C., and sodium hydride (3.5 g, 145.9 mmol) was slowly added dropwise thereto. The mixture was stirred for 20 minutes, and then stirred at 100° C. for 1 hour. After the reaction was completed, the mixture was cooled to room temperature, and 100 ml of ethanol was slowly added thereto. The above mixture was distilled under reduced pressure, and the resulting mixture was recrystallized from chloroform and ethyl acetate to give Compound P-3 (30.3 g, yield: 81%).

MS: [M+H]⁺=280

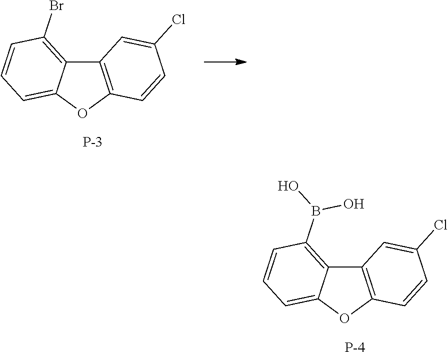

Compound P-3 (30.0 g, 106.6 mmol) was dissolved in tetrahydrofuran (300 ml), the temperature was lowered to −78° C., and 1.7 M tert-butyllithium (t-BuLi) (62.7 ml, 106.6 mmol) was slowly added thereto. After stirring for 1 hour at the same temperature, triisopropylborate (B(OiPr)₃) (28.3 ml, 213.1 mmol) was added thereto, and then stirred for 3 hours while gradually raising the temperature to room temperature. 2N aqueous hydrochloric acid solution (200 ml) was added to the reaction mixture, and stirred at room temperature for 1.5 hours. The produced precipitate was filtered, washed sequentially with water and ethyl ether, and then dried under vacuum. After drying, it was dispersed in ethyl ether, stirred for 2 hours, then filtered and dried to give Compound P-4 (24.4 g, yield: 93%).

MS: [M+H]⁺=247

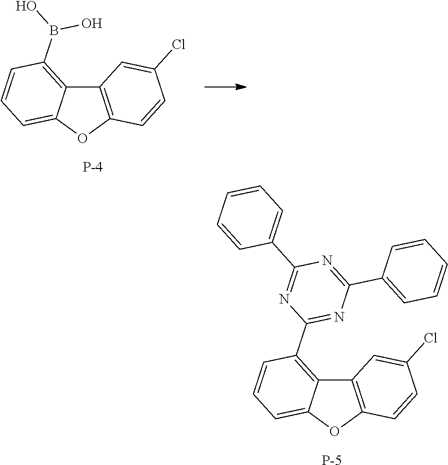

After Compound P-4 (20.0 g, 81.2 mmol) and 2-chloro-4,6-diphenyl-1,3,5-triazine (21.8 g, 81.2 mmol) were dispersed in tetrahydrofuran (250 ml), 2M potassium carbonate aqueous solution (aq. K₂CO₃) (33.6 ml, 243.5 mmol) and tetrakis (triphenylphosphine) palladium [Pd (PPh₃)₄] (1.9 g, 2 mol %) were added thereto, and the mixture was stirred and refluxed for 4 hours. The temperature was lowered to room temperature, and the produced solid was filtered. The filtered solid was recrystallized from tetrahydrofuran and ethyl acetate, filtered, and then dried to give Compound P-5 (32.4 g, yield: 92%).

MS: [M+H]⁺=434

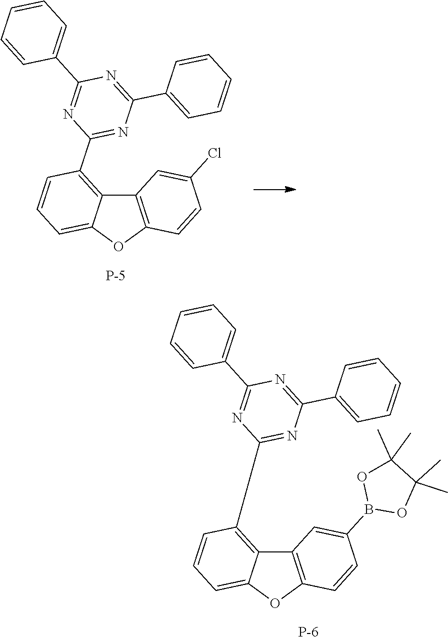

Compound P-5 (30 g, 69.2 mmol), bis (pinacolato) diborone) (19.3 g, 76.1 mmol), potassium acetate) (20.4 g, 207.5 mmol) and tetrakis (triphenylphosphine)-palladium (0) [Pd(PPh₃)₄] (1.6 g, 2 mol %) were added to tetrahydrofuran (300 ml), and the mixture was refluxed for 12 hours. After the reaction was completed, the mixture was cooled to room temperature, and distilled under reduced pressure to remove the solvent. This was dissolved in chloroform, washed with water three times, and then the organic layer was separated and dried with magnesium sulfate. This was distilled under reduced pressure to give Compound P-6 (34.5 g, yield: 95%).

MS: [M+H]⁺=526

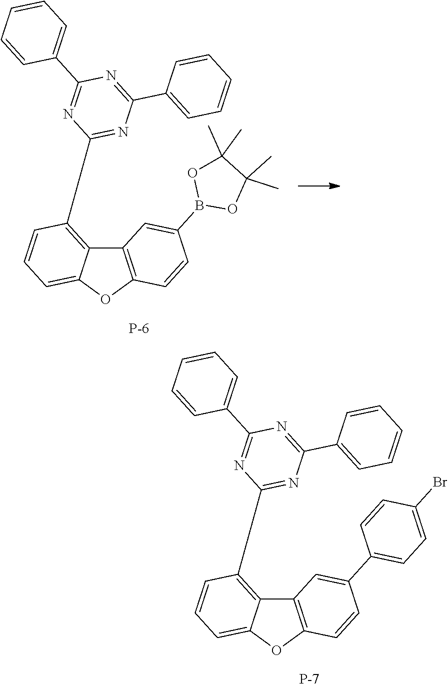

After Compound P-6 (30.0 g, 57.1 mmol) and 4-iodo-1-bromobenzene (16.2 g, 57.1 mmol) were dispersed in tetrahydrofuran (300 ml), 2M potassium carbonate aqueous solution (aq. K₂CO₃) (34 ml, 171 mmol) and tetrakis (triphenylphosphine)-palladium[Pd(PPh₃)₄] (0.7 g, 1 mol %) were added thereto, and the mixture was stirred and refluxed for 12 hours. The temperature was lowered to room temperature, and the produced solid was filtered. The filtered solid was recrystallized from tetrahydrofuran and ethyl acetate, filtered, and then dried to give Compound P-7 (22.8 g, yield: 72%).

MS: [M+H]⁺=555

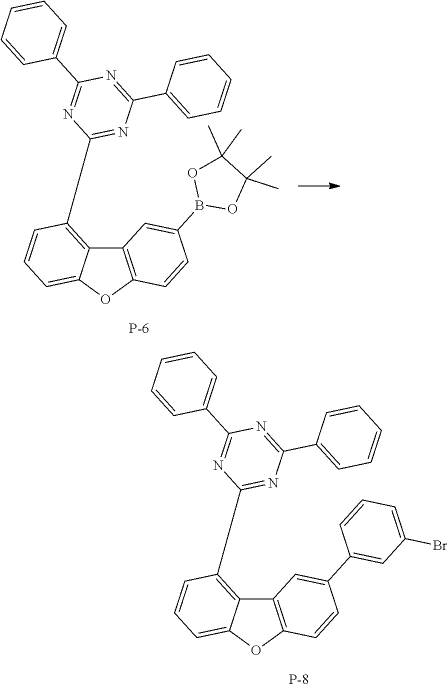

After Compound P-6 (30.0 g, 57.1 mmol) and 3-iodo-1-bromobenzene (16.2 g, 57.1 mmol) were dispersed in tetrahydrofuran (300 ml), 2M potassium carbonate aqueous solution (aq. K₂CO₃) (34 ml, 171 mmol) and tetrakis (triphenylphosphine)-palladium [Pd (PPh₃)₄] (0.7 g, 1 mol %) were added thereto, and the mixture was stirred and refluxed for 12 hours. The temperature was lowered to room temperature, and the produced solid was filtered. The filtered solid was recrystallized from tetrahydrofuran and ethyl acetate, filtered, and then dried to give Compound P-8 (21.5 g, yield: 68%).

MS: [M+H]⁺=555

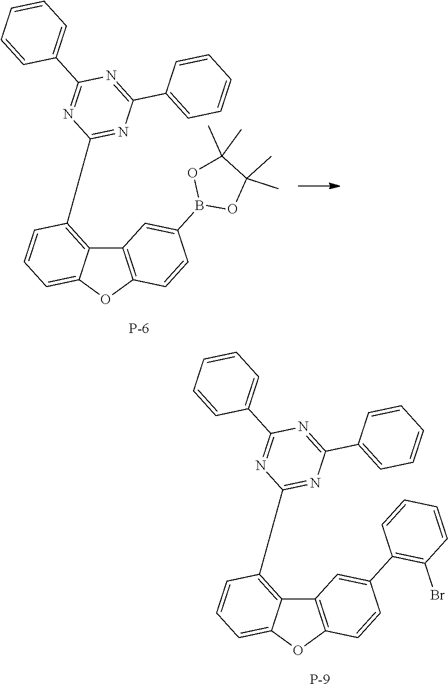

After Compound P-6 (30.0 g, 57.1 mmol) and 2-iodo-1-bromobenzene (16.2 g, 57.1 mmol) were dispersed in tetrahydrofuran (300 ml), 2M potassium carbonate aqueous solution (aq. K₂CO₃) (34 ml, 171 mmol) and tetrakis (triphenylphosphine)-palladium [Pd(PPh₃)₄] (0.7 g, 1 mol %) were added thereto, and the mixture was stirred and refluxed for 12 hours. The temperature was lowered to room temperature, and the produced solid was filtered. The filtered solid was recrystallized from tetrahydrofuran and ethyl acetate, filtered, and then dried to give Compound P-9 (13.3 g, yield: 42%).

MS: [M+H]⁺=555

### PREPARATION EXAMPLE 1: PREPARATION OF COMPOUNDS 1-1 TO 1-8

### Preparation Example 1-1: Preparation of Compound 1-1

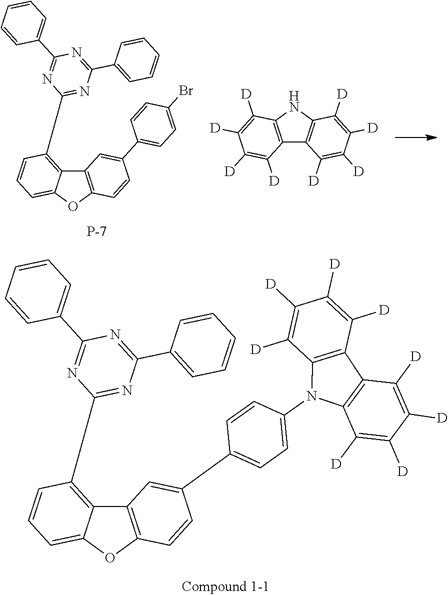

P-7 (20 g, 36.1 mmol) and 9H-carbazole-1,2,3,4,5,6,7,8-d8 (6.3 g, 36.1mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 3 hours, the reaction mixture was cooled to room temperature, and then the produced solid was filtered. The solid was added to 1170 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-1 as a yellowish white solid (14 g, yield: 60%).

MS: [M+H]⁺=649.8

### Preparation Example 1-2: Preparation of Compound 1-2

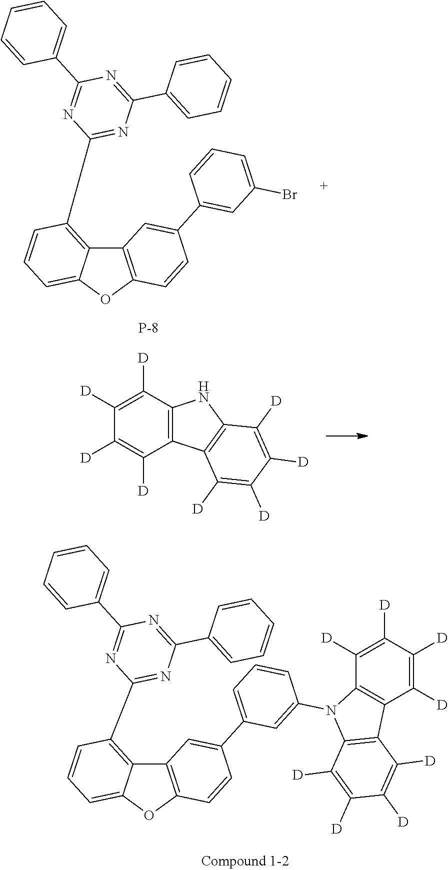

P-8 (20 g, 36.1 mmol) and 9H-carbazole-1,2,3,4,5,6,7,8-d8 (6.3 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 3 hours, the reaction mixture was cooled to room temperature, and then the produced solid was filtered. The solid was added to 1172 mL of chloroform, dissolved, washed twice with water, and then the organic layer was separated, to which anhydrous magnesium sulfate was added, stirred, then filtered, and the filtrate was distilled under reduced pressure. The concentrated compound was recrystallized from chloroform and ethyl acetate to give Compound 1-2 as a yellowish white solid (17.3 g, yield: 74%).

MS: [M+H]⁺=650.8

### Preparation Example 1-3: Preparation of Compound 1-3

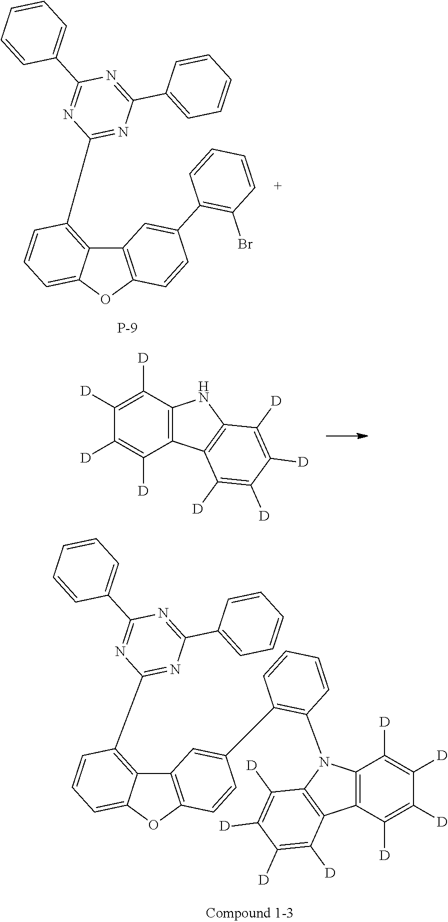

P-9 (20 g, 36.1 mmol) and 9H-carbazole-1,2,3,4,5,6,7,8-d8 (6.3 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 1 hours, the reaction mixture was cooled to room temperature, and then the produced solid was filtered. The solid was added to 1172 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-3 as a yellowish white solid (15.2 g, yield: 65%).

MS: [M+H]⁺=650.8

### Preparation Example 1-4: Preparation of Compound 1-4

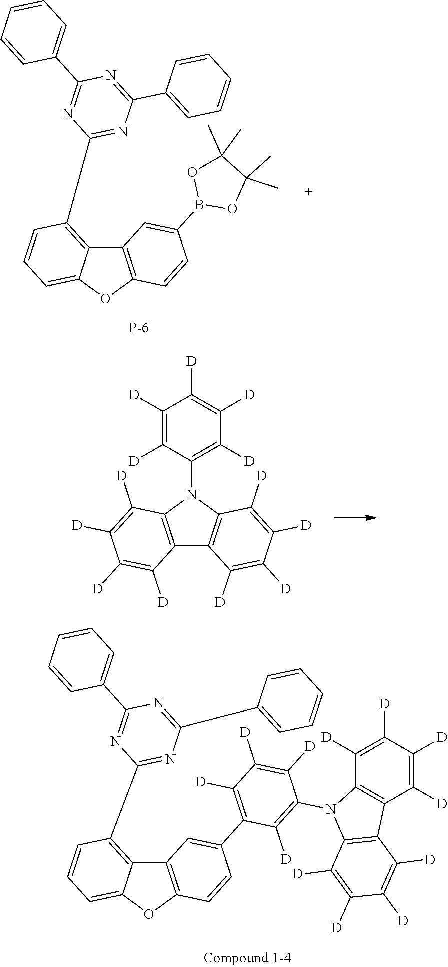

P-6 (20 g, 36.1 mmol) and 9-(3-bromo-phenyl-d4)-carbazole-1,2,3,4,5,6,7,8-d8 (6.2 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added. After reacting for 3 hours, the reaction mixture was cooled to room temperature, and then the produced solid was filtered. The solid was added to 1168 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-4 as a white solid (16.8g, yield: 72%).

MS: [M+H]⁺=648.8

### Preparation Example 1-5: Preparation of Compound 1-5

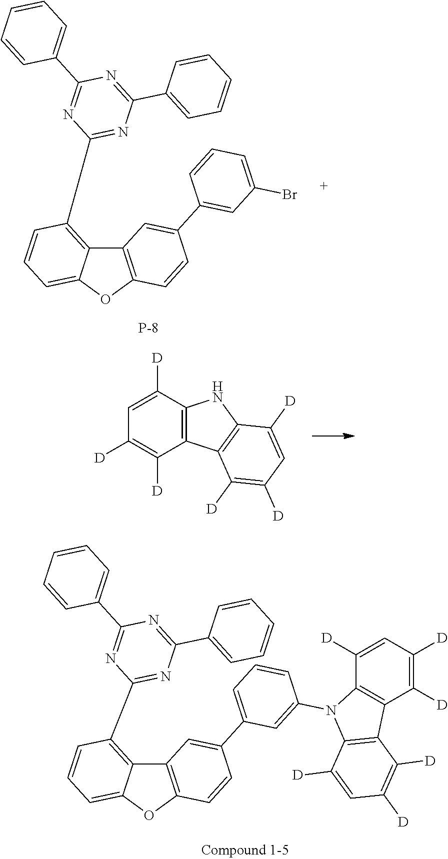

P-8 (20 g, 36.1 mmol) and 9H-carbazole-1,3,4,5,6,8-d6 (6.2 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 2 hours, the reaction mixture was cooled to room temperature, and then the produced solid was filtered. The solid was added to 1168 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-5 as a white solid (18 g, yield: 77%).

MS: [M+H]⁺=648.8

### Preparation Example 1-6: Preparation of Compound 1-6

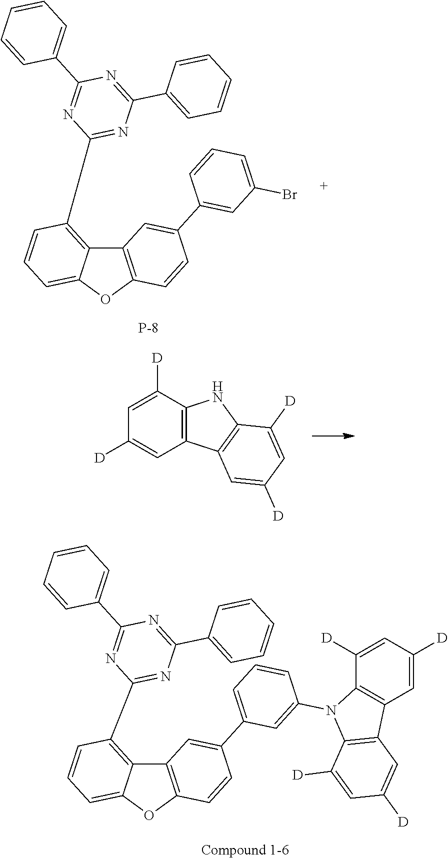

P-8 (20 g, 36.1 mmol) and 9H-carbazole-1,3,6,8-d4 (6.1 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 1 hours, the reaction mixture was cooled to room temperature, and then the produced solid was filtered. The solid was added to 1165 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-6 as a white solid (16.5 g, yield: 71%).

MS: [M+H]⁺=646.8

### Preparation Example 1-7: Preparation of Compound 1-7

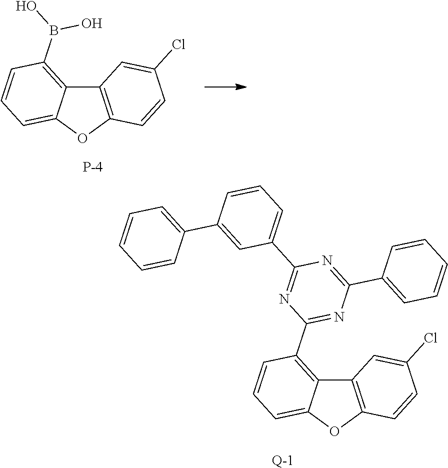

After Compound P-4 (20.0 g, 81.3 mmol) and 2- ([1,1′-biphenyl]-3-yl)-4-chloro-6-phenyl-1,3,5-triazine (27.9 g, 81.2 mmol) were dispersed in tetrahydrofuran (250 ml), 2M potassium carbonate aqueous solution (aq. K₂CO₃) (33.6 ml, 243.5mmol) and tetrakis (triphenylphosphine) palladium [Pd(PPh₃)₄] (1.9 g, 2 mol %) were added thereto, and the mixture was stirred and refluxed for 4 hours. The temperature was lowered to room temperature, and the produced solid was filtered. The filtered solid was recrystallized from tetrahydrofuran and ethyl acetate, filtered, and then dried to give Compound Q-1 (36.8 g, yield: 89%).

MS: [M+H]⁺=510

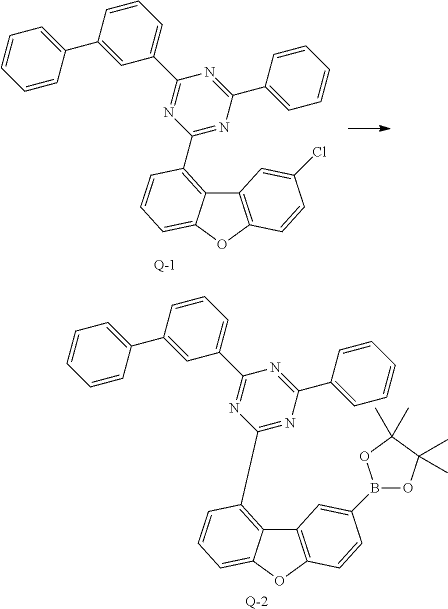

Compound Q-1 (30 g, 59 mmol), bis (pinacolato) diborone) (16.5 g, 65 mmol), potassium acetate (17 g, 177 mmol), dibenzylideneacetone palladium (1 g, 1.8 mmol) and tricyclohexylphosphine (1 g, 3.5 mmol) were added to dioxane (300 ml), and the mixture was refluxed for 12 hours. After the reaction was completed, the mixture was cooled to room temperature, and distilled under reduced pressure to remove the solvent. This was dissolved in chloroform, washed with water three times, and then the organic layer was separated and dried with magnesium sulfate. This was distilled under reduced pressure to give Compound Q-2 (32 g, yield: 90%).

MS: [M+H]⁺=602

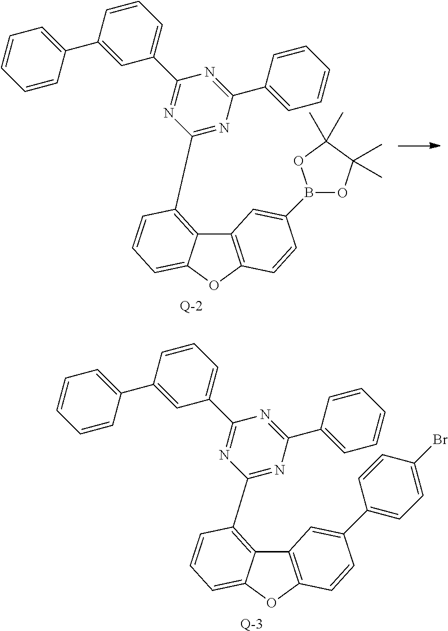

After Compound Q-2 (30.0 g, 49.8 mmol) and 4-iodo-1-bromobenzene (14.1g, 57.1 mmol) were dispersed in tetrahydrofuran (300 ml), 2M potassium carbonate aqueous solution (aq. mmol) K₂CO₃) (30 ml, 150 and tetrakis (triphenylphosphine) palladium [Pd(PPh₃)₄] (0.6 g, 1 mol %) were added thereto, and the mixture was stirred and refluxed for 12 hours. The temperature was lowered to room temperature, and the produced solid was filtered. The filtered solid was recrystallized from tetrahydrofuran and ethyl acetate, filtered, and then dried to give Compound Q-3 (25.1 g, yield: 80%).

MS: [M+H]⁺=630

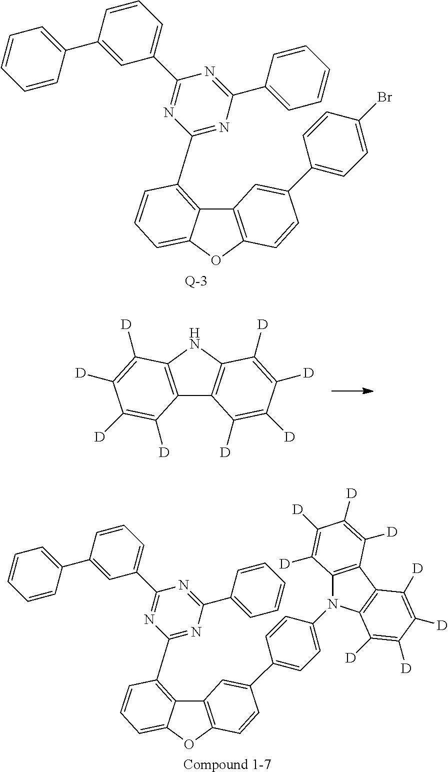

Q-3 (20 g, 31.7 mmol) and 9H-carbazole-1,2,3,4,5,6,7,8-d8 (8.1 g, 31.7 mmol) were added to 400 ml of tetrahydrofuran under a nitrogen atmosphere, and the mixture was stirred and refluxed. Then, potassium carbonate (13.2 g, 95.2 mmol) was dissolved in 13 ml of water and added thereto, and the mixture was sufficiently stirred, and then tetrakis (triphenylphosphine) palladium (1.1 g, 1 mmol) was added thereto. After reacting for 3 hours, the reaction mixture was cooled to room temperature, and then the produced solid was filtered. The solid was added to 1150 mL of chloroform, dissolved, washed twice with water, and the organic layer was separated, to which anhydrous magnesium sulfate was added, stirred, then filtered, and the filtrate was distilled under reduced pressure. The concentrated compound was recrystallized from chloroform and ethyl acetate to give Compound 1-7 as a yellowish white solid (17.7g, yield: 77%).

MS: [M+H]⁺=725.9

### Preparation Example 1-8: Preparation of Compound 1-8

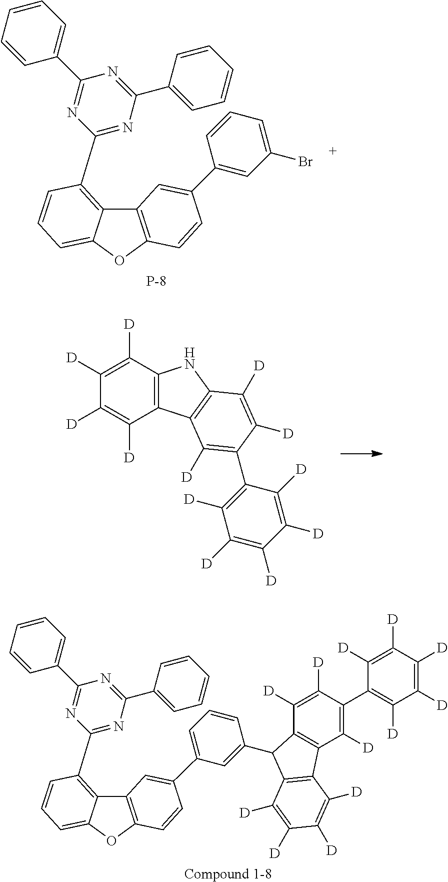

P-8 (20 g, 36.1 mmol) and 3-(phenyl-d5)-9H-carbazole-1,2,4,5,6,7,8-d7 (9.2 g, 36.1 mmol) were added to 400 ml of tetrahydrofuran under a nitrogen atmosphere, and the mixture was stirred and refluxed. Then, potassium carbonate (15 g, 108.2 mmol) was dissolved in 15 ml of water and added thereto, and the mixture was sufficiently stirred, and then tetrakis (triphenylphosphine) palladium (1.2 g, 1.1 mmol) was added thereto. After reacting for 1 hours, the reaction mixture was cooled to room temperature, and then the produced solid was filtered. The solid was added to 1315 mL of chloroform, dissolved, washed twice with water, and then the organic layer was separated, to which anhydrous magnesium sulfate was added, stirred, then filtered, and the filtrate was distilled under reduced pressure. The concentrated compound was recrystallized from chloroform and ethyl acetate to give Compound 1-8 as a yellowish white solid (16.3g, 62%).

MS: [M+H]⁺=729.9

### PREPARATION EXAMPLE 2: PREPARATION OF COMPOUNDS 2-1 TO 2-4

### Preparation Example 2-1: Preparation of Compound 2-1

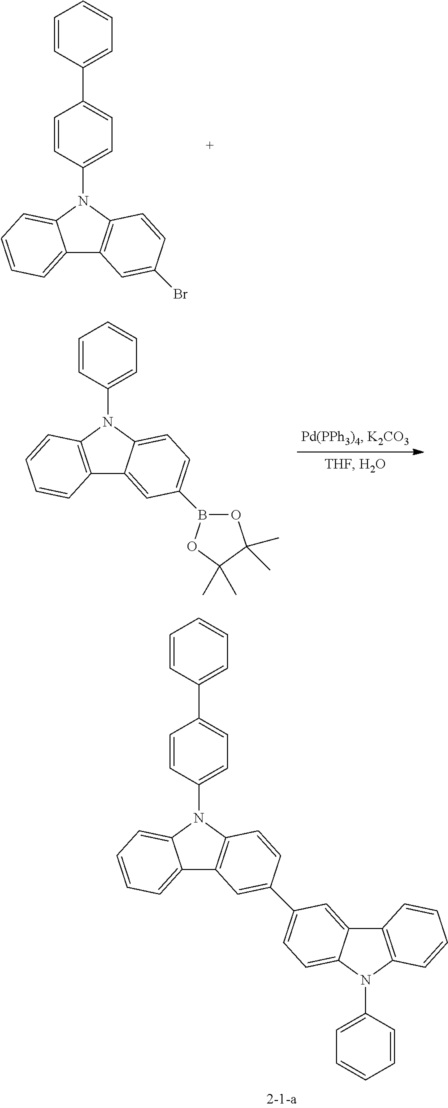

9- ([1,1′-Biphenyl]-4-yl)-3-bromo-9H-carbazole (15.0 g, 37.7 mmol) and 9-phenyl-3-(4,4,5,5-tetramethyl-1,3,2-dioxaborolan-2-yl)-9H-carbazole (15.3 g, 41.4 mmol) were added to 300 ml of THF under a nitrogen atmosphere, and the mixture was stirred and refluxed. Then, potassium carbonate (20.8 g, 150.6 mmol) was dissolved in 62 ml of water and added thereto, and the mixture was sufficiently stirred, and then tetrakis(triphenylphosphine)palladium(0) (1.3 g, 1.1 mmol) was added thereto. After reacting for 9 hours, the reaction mixture was cooled to room temperature, and then the organic layer and the aqueous layer were separated, and the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography to give 13.5 g of Compound 2-1-a (yield: 64%).

MS: [M+H]⁺=562

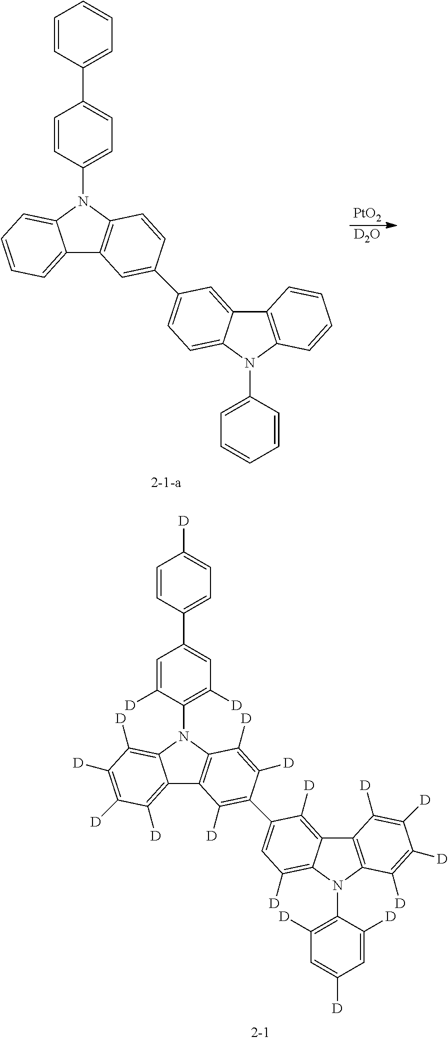 [SMILES: c1ccc(-c2ccc(-n3c4ccccc4c4cc(-c5ccc6c(c5)c5ccccc5n6-c5ccccc5)ccc43)cc2)cc1 ; "PtO2" ; "D2O" ; [2H]c1ccc(-c2cc([2H])c(-n3c4c([2H])c([2H])c([2H])c([2H])c4c4c([2H])c(-c5cc([2H])c6c(c5[2H])c5c([2H])c([2H])c([2H])c([2H])c5n6-c5c([2H])cc([2H])cc5[2H])c([2H])c([2H])c43)c([2H])c2)cc1]

Compound 2-1-a (10.0 g, 17.8 mmol), PtO2 (1.2 g, 5.4 mmol) and D20 (89 ml) were added to a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and then the sample was purified by silica gel column chromatography and then subjected to sublimation purification to give 3.9 g of Compound 2-1 (yield: 38%).

MS: [M+H]⁺=580

### Preparation Example 2-2: Preparation of Compound 2-2

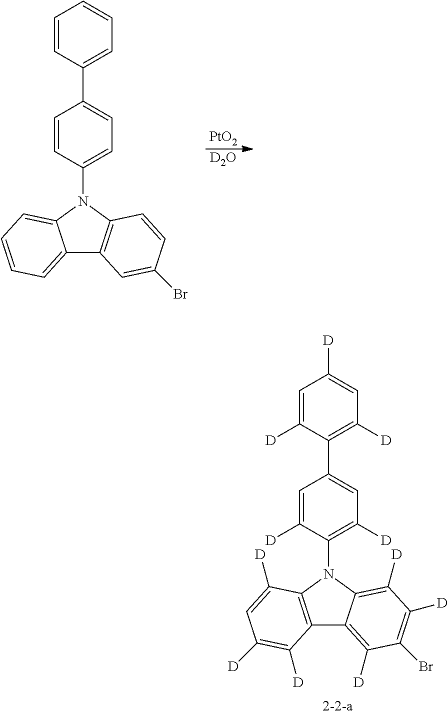 [SMILES: Brc1ccc2c(c1)c1ccccc1n2-c1ccc(-c2ccccc2)cc1 ; "PtO2" ; "D2O" ; [2H]c1cc([2H])c(-c2cc([2H])c(-n3c4c([2H])cc([2H])c([2H])c4c4c([2H])c(Br)c([2H])c([2H])c43)c([2H])c2)c([2H])c1]

9- ([1,1′-biphenyl]-4-yl)-3-bromo-9H-carbazole (10 g, 25.1 mmol), PtO₂ (1.7 g, 7.5 mmol) and D20 (126 ml) were added to a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and the sample was purified by silica gel column chromatography to give 7.9 g of Compound 2-2-a (yield: 77%).

MS: [M+H]⁺=409

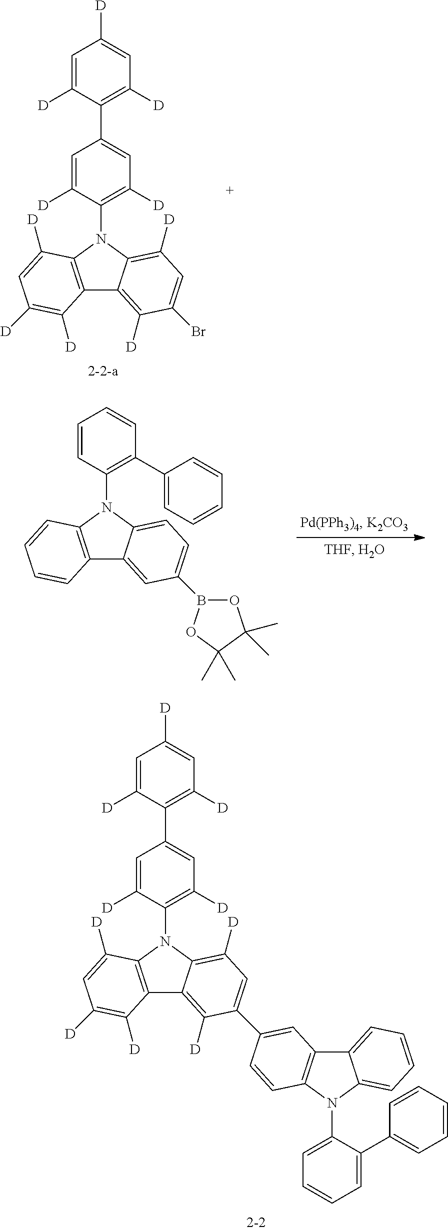

Compound 2-2-a (15.0 g, 36.7 mmol) and 9- ([1,1′-biphenyl]-2-yl)-3-(4,4,5,5-tetramethyl-1,3,2-dioxaborolan-2-yl)-9H-carbazole (18.0 g, 40.4 mmol) were added to 300 ml of THE under a nitrogen atmosphere, and the mixture was stirred and refluxed. Then, potassium carbonate (20.3 g, 146.9 mmol) was dissolved in 61 ml of water and added thereto, and the mixture was sufficiently stirred, and then tetrakis(triphenylphosphine)palladium(0) (1.3 g, 1.1 mmol) was added thereto. After reacting for 12 hours, the reaction mixture was cooled to room temperature, and then the organic layer and the aqueous layer were separated, and the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography and then subjected to sublimation purification to give 11.6 g of Compound 2-2 (vield: 49%).

MS: [M+H]⁺=648

### Preparation Example 2-3: Preparation of Compound 2-3

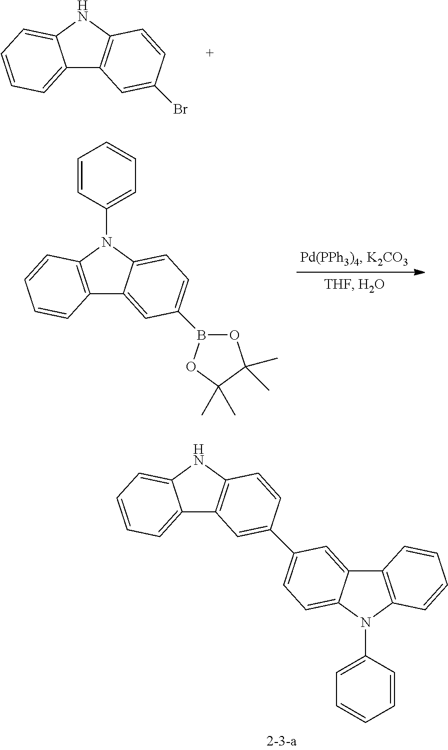

3-Bromo-9H-carbazole (15.0 g, 60.9 mmol) and 9-phenyl-3-(4,4,5,5-tetramethyl-1,3,2-dioxaborolan-2-yl)-9H-carbazole (24.8 g, 67 mmol) were added to 300 ml of THF under a nitrogen atmosphere, and the mixture was stirred and refluxed. Then, potassium carbonate (33.7 g, 243.8 mmol) was dissolved in 101 ml of water and added thereto, and the mixture was sufficiently stirred, and then tetrakis(triphenylphosphine)palladium(0) (2.1 g, 1.8 mmol) was added thereto. After reacting for 11 hours, the reaction mixture was cooled to room temperature, and then the organic layer and the aqueous layer were separated, and the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography to give 16.7 g of Compound 2-3-a (yield: 67%).

MS: [M+H]⁺=410

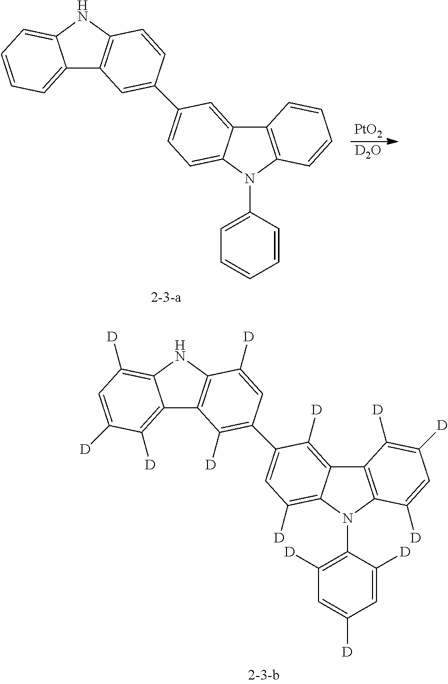

Compound 2-3-a (10.0 g, 24.5 mmol), PtO₂ (1.7 g, 7.3 mmol) and D₂O (122 ml) were added to a shaker tube, and then the tube was sealed and heated at 250° C. and 600 psi for 12 hours. When the reaction was completed, chloroform was added thereto, and the reaction solution was transferred to a separatory funnel, and extracted. The extract was dried over anhydrous magnesium sulfate and concentrated, and then the sample was purified by silica gel column chromatography to give 9.1 g of Compound 2-3-b (yield: 88%).

MS: [M+H]⁺=423

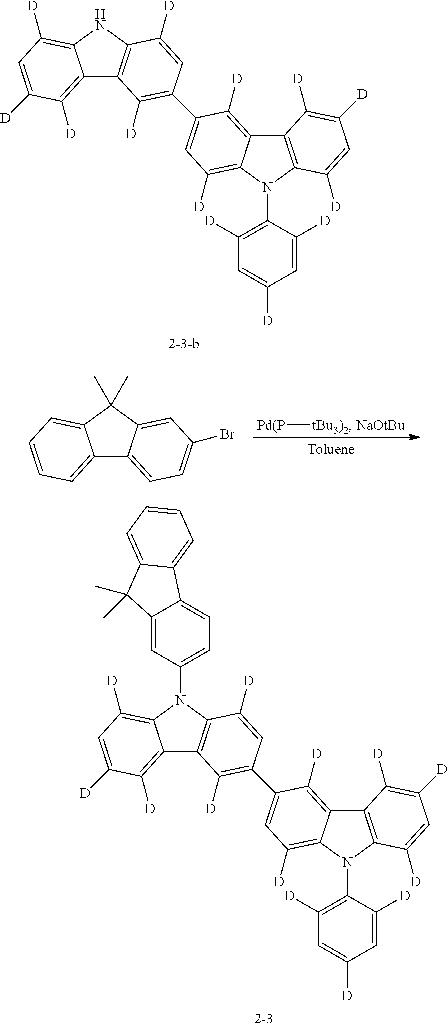

Compound 2-3-b (15.0 g, 36.7 mmol) and 2-bromo-9,9-dimethyl-9H-fluorene (11.0 g, 40.4 mmol) were added to 300 ml of toluene under a nitrogen atmosphere, and the mixture was stirred and refluxed. Then, sodium tert-butoxide (5.3 g, 55.1 mmol) and bis(tri-tert-butylphosphine)palladium(0) (0.6 g, 1.1 mmol) were added thereto. After reacting for 6 hours, the reaction mixture was cooled to room temperature, and then the organic layer was separated using chloroform and water, and then the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography and then subjected to sublimation purification to give 9.5 g of Compound 2-3 (yield: 42%).

MS: [M+H]⁺=615

### Preparation Example 2-4: Preparation of Compound 2-4

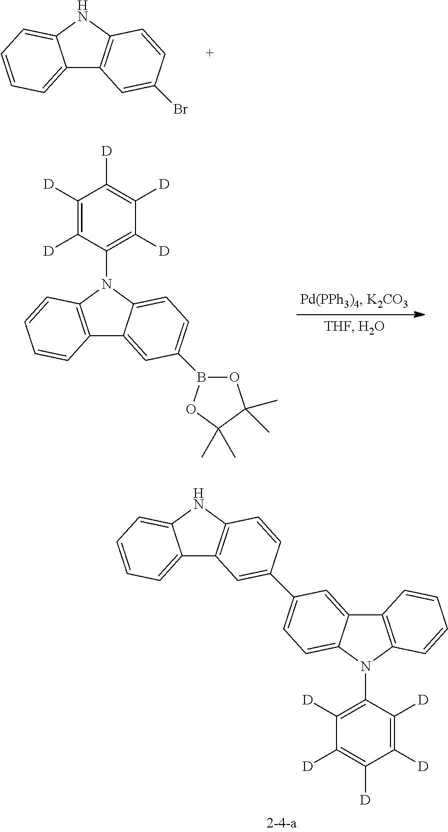 [SMILES: Brc1ccc2[nH]c3ccccc3c2c1 ; [2H]c1c([2H])c([2H])c(-n2c3ccccc3c3cc(B4OC(C)(C)C(C)(C)O4)ccc32)c([2H])c1[2H] ; [2H]c1c([2H])c([2H])c(-n2c3ccccc3c3cc(-c4ccc5[nH]c6ccccc6c5c4)ccc32)c([2H])c1[2H]]

3-Bromo-9H-carbazole (15.0 g, 60.9 mmol) and 9-(phenyl-d5)-3-(4,4,5,5-tetramethyl-1,3,2-dioxaborolan-2-yl)-9H-carbazole (25.1 g, 67 mmol) were added to 300 ml of THF under a nitrogen atmosphere, and the mixture was stirred and refluxed. Then, potassium carbonate (33.7 g, 243.8 mmol) was dissolved in 101 ml of water and added thereto, and the mixture was sufficiently stirred, and then tetrakis(triphenylphosphine)palladium(0) (2.1 g, 1.8 mmol) was added thereto. After reacting for 9 hours, the reaction mixture was cooled to room temperature, and then the organic layer and the aqueous layer were separated, and the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography to give 16.1 g of Compound 2-4-a (yield: 64%).

MS: [M+H]⁺=415

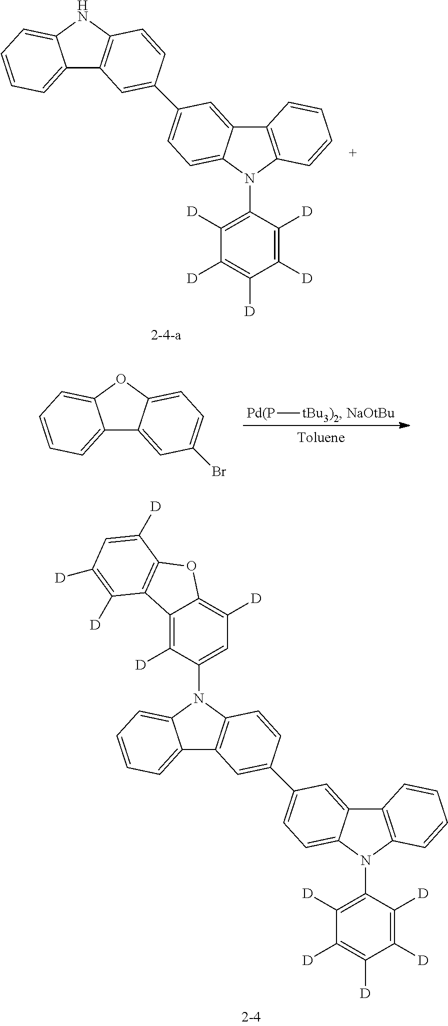

Compound 2-4-a (15.0 g, 36.3 mmol) and 2-bromodibenzo[b,d]furan (9.9 g, 39.9 mmol) were added to 300 ml of toluene under a nitrogen atmosphere, and the mixture was stirred and refluxed. Then, sodium tert-butoxide (5.2 g, 54.4 mmol), and bis(tri-tert-butylphosphine)palladium(0) (0.6 g, 1.1 mmol) were added thereto. After reacting for 11 hours, the reaction mixture was cooled to room temperature, and then the organic layer was separated using chloroform and water, and then the organic layer was distilled. This was again dissolved in chloroform, washed twice with water, and then the organic layer was separated, to which anhydrous magnesium sulfate was added, stirred, then filtered, and the filtrate was distilled under reduced pressure. The concentrated compound was purified by a silica gel column chromatography and then subjected to sublimation purification to give 8.1 g of Compound 2-4 (yield: 38%).

MS: [M+H]⁺=586

### Examples

### Example 1: Manufacture of Organic Light Emitting Device

A glass substrate on which a thin film of ITO (indium tin oxide) was coated in a thickness of 1400 Å was put into distilled water containing a detergent dissolved therein and ultrasonically washed. At this time, the detergent used was a product commercially available from Fischer Co. and the distilled water was one which had been twice filtered by using a filter commercially available from Millipore Co. The ITO was cleaned for 30 minutes, and ultrasonic cleaning was then repeated twice for 10 minutes by using distilled water. After the cleaning with distilled water was completed, the substrate was ultrasonically washed with the solvents of isopropyl alcohol, acetone, and methanol, and dried, after which it was transported to a plasma cleaner. Then, the substrate was cleaned with oxygen plasma for 5 minutes, and then transferred to a vacuum evaporator.

On the ITO transparent electrode thus prepared, 95 wt. % of the following Compound HT-A and 5 wt. % of the following Compound PD were thermally vacuum-deposited to a thickness of 100 Å to form a hole injection layer, and then only Compound HT-A was deposited to a thickness of 1150 Å to form a hole transport layer. The following Compound HT-B was thermally vacuum-deposited thereon to a thickness of 450 Å as an electron blocking layer.

Then, Compound 1-1 prepared in Preparation Example 1-1 and Compound 2-1 prepared in Preparation Example 2-1 were used in a weight ratio of 4:6 as a host material, and the following Compound GD was used as a dopant material, wherein the host material and the dopant material were vacuum-deposited at a weight ratio of 92:8 to a thickness of 350 Å on the electron blocking layer to form a light emitting layer.

Then, the following Compound ET-A was vacuum-deposited to a thickness of 50 Å as a hole blocking layer. Then, the following Compound ET-B and Compound Liq were thermally vacuum-deposited at a weight ratio of 1:1 to a thickness of 300 Å as an electron transport layer, and then, Yb (ytterbium) was vacuum-deposited to a thickness of 10 Å as an electron injection layer.

Magnesium and silver were deposited in a weight ratio of 1:4 to a thickness of 150 Å on the electron injection layer to form a cathode, thereby completing the manufacture of an organic light emitting device.

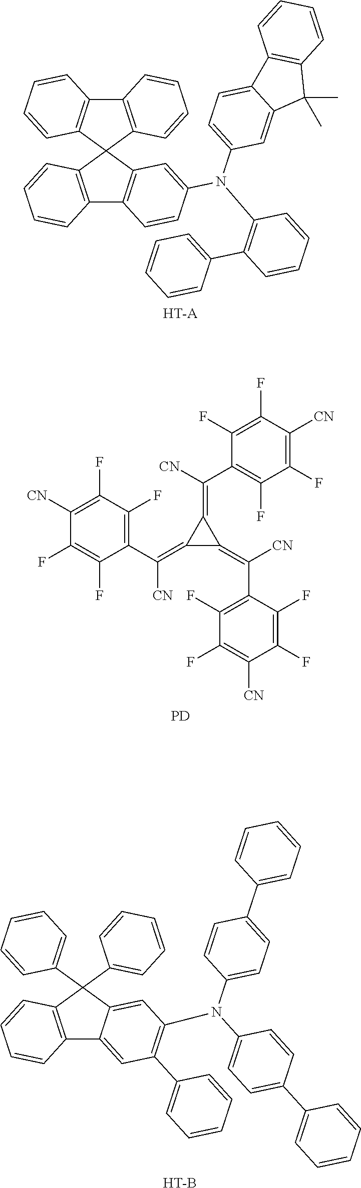

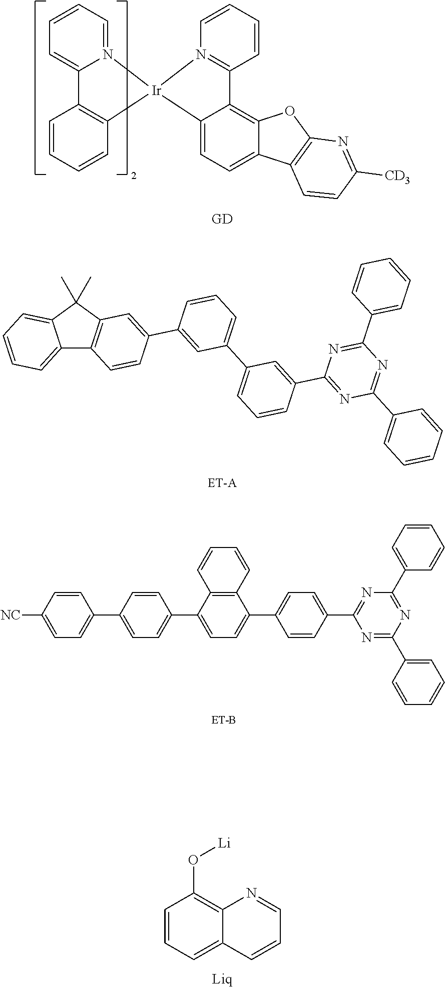

In the above-mentioned processes, the vapor deposition rate of the organic material was maintained at 0.4˜0.7 Å/sec, the deposition rate of magnesium and silver was maintained at 2 Å/sec, and the degree of vacuum during the deposition was maintained at 2*10⁻⁷˜5*10⁻⁶ torr, thereby manufacturing an organic light emitting device.

### Examples 2 to 11, and Comparative Examples 1 to 3

The organic light emitting devices of Examples 2 to 11 and Comparative Examples 1 to 3 were manufactured in the same manner as in Example 1, except that the host material was changed as shown in Table 1 below. Compound A-1 and Compound B-1 in Table 1 below are as follows.

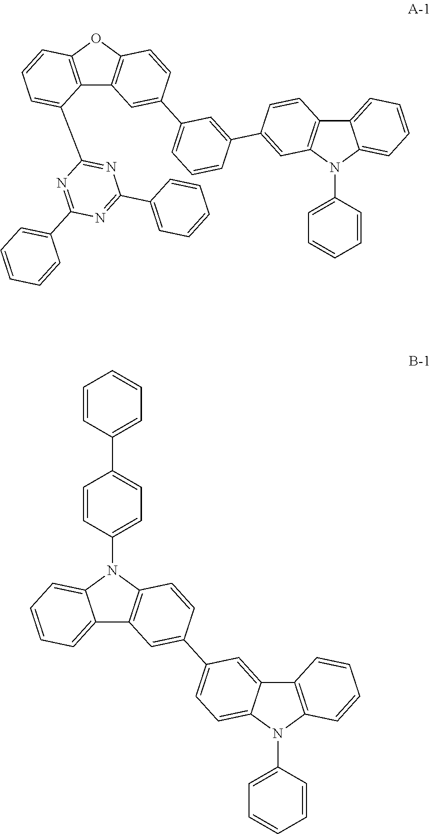 [SMILES: c1ccc(-c2nc(-c3ccccc3)nc(-c3cccc4oc5ccc(-c6cccc(-c7ccc8c9ccccc9n(-c9ccccc9)c8c7)c6)cc5c34)n2)cc1 ; c1ccc(-c2ccc(-n3c4ccccc4c4cc(-c5ccc6c(c5)c5ccccc5n6-c5ccccc5)ccc43)cc2)cc1]

### Experimental Example

The organic light emitting devices manufactured in Examples 1 to 11 and Comparative Examples 1 to 3 were heat-treated in an oven at 120° C. for 30 minutes, then taken out, and the voltage, efficiency, and lifetime (T95) were measured by applying a current, and the results are shown in Table 1 below. At this time, the driving voltage and efficiency were measured by applying a current density of 10mA/cm², and T95 means the time (hr) required for the luminance to be reduced to 95% of the initial luminance at a current density of 20 mA/cm².

TABLE 1

| | | | @ 10 mA/cm² | | Color | @ 20 mA/cm² |
|---|---|---|---|---|---|---|
| | Host material | | Voltage | Efficiency | coordinate | Lifetime |
| | First host | Second host | (V) | (cd/A) | (x, y) | (T95, hr) |
| Example 1 | Compound 1-1 | Compound 2-1 | 3.9 | 81 | 0.34, 0.62 | 200 |
| Example 2 | Compound 1-2 | Compound 2-1 | 4 | 82 | 0.34, 0.62 | 250 |
| Example 3 | Compound 1-3 | Compound 2-1 | 4 | 82 | 0.34, 0.62 | 210 |
| Example 4 | Compound 1-4 | Compound 2-1 | 4.1 | 81 | 0.34, 0.62 | 250 |
| Example 5 | Compound 1-5 | Compound 2-1 | 4 | 81 | 0.34, 0.62 | 270 |
| Example 6 | Compound 1-6 | Compound 2-1 | 4 | 82 | 0.34, 0.62 | 240 |
| Example 7 | Compound 1-7 | Compound 2-1 | 4 | 82 | 0.34, 0.62 | 230 |
| Example 8 | Compound 1-8 | Compound 2-1 | 3.9 | 83 | 0.34, 0.62 | 260 |
| Example 9 | Compound 1-2 | Compound 2-2 | 4.1 | 81 | 0.34, 0.62 | 220 |
| Example 10 | Compound 1-2 | Compound 2-3 | 4 | 80 | 0.34, 0.62 | 210 |
| Example 11 | Compound 1-2 | Compound 2-4 | 3.9 | 83 | 0.34, 0.62 | 200 |
| Comparative | Compound A-1 | Compound 2-1 | 4.3 | 77 | 0.34, 0.62 | 150 |
| Example 1 | | | | | | |
| Comparative | Compound A-1 | Compound B-1 | 4.4 | 70 | 0.34, 0.62 | 115 |
| Example 2 | | | | | | |
| Comparative | Compound 1-1 | Compound B-1 | 4 | 82 | 0.34, 0.62 | 150 |
| Example 3 | | | | | | |

It can be confirmed that when the compound of Chemical Formula 1 and the compound of Chemical Formula 2 were used as a light emitting layer host of an organic light emitting device, it exhibited low voltage, high efficiency, and long-life characteristics compared to materials having structures different from Chemical Formula 1 or Chemical Formula 2 in terms of structure and deuterium substitution rate.

### DESCRIPTION OF SYMBOLS

| | |
|---|---|
| 1: substrate | 2: anode |
| 3: light emitting layer | 4: cathode |
| 5: hole injection layer | 6: hole transport layer |
| 7: electron blocking layer | 8: hole blocking layer |
| 9: electron transport layer | 10: electron injection layer |

1. An organic light emitting device, comprising:
an anode;
a cathode; and
a light emitting layer interposed between the anode and the cathode,
wherein the light emitting layer includes a compound of the following Chemical Formula 1, and a compound of the following Chemical Formula 2: 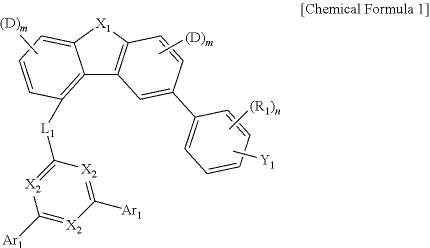
wherein, in Chemical Formula 1:
X₁ is O or S;
L₁ is a single bond, a substituted or unsubstituted C₆₋₆₀ arylene, or a substituted or unsubstituted C₂₋₆₀ heteroarylene containing any one or more heteroatoms selected from the group consisting of N, O, and S;
each X₂ is independently N or CH, provided that at least one of X₂is N, N:
each Ar₁ is independently a substituted or unsubstituted C₆₋₆₀ aryl, or a substituted or unsubstituted C₂₋₆₀ heteroaryl containing any one or more heteroatoms selected from the group consisting of N, O, and S;
each R₁ is independently hydrogen, deuterium, or a substituted or unsubstituted C₆₋₆₀ aryl;
each m is independently an integer of 0 to 3;
n is an integer of 0 to 4; and
Y₁ is any one selected from the group consisting of: 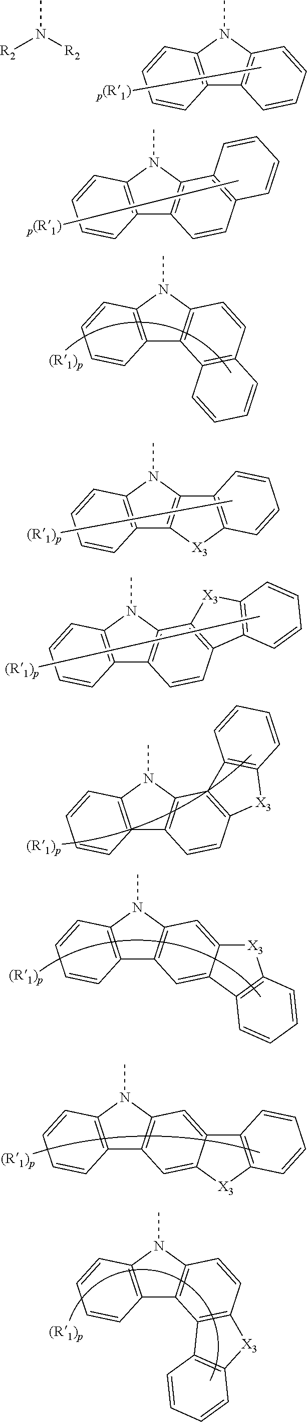 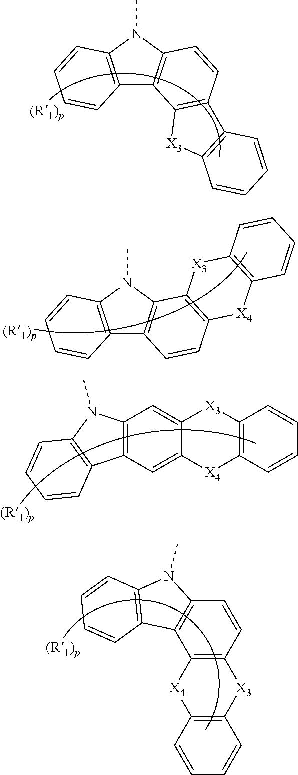
wherein, in the above group;
each R₂ is independently hydrogen, deuterium, or phenyl;
X₃ and X₄ are each independently O, N-(phenyl), S, or C(CH₃)₂;
each R′₁ is independently hydrogen, deuterium, or phenyl which is unsubstituted or substituted with at least one deuterium; and
p is an integer of 0 to 10; 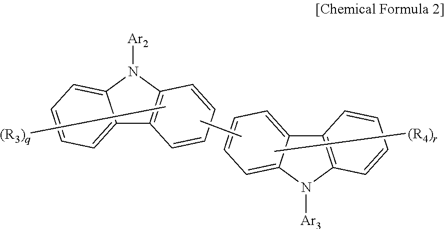
wherein, in Chemical Formula 2;
Ar₂and Ar₃ are each independently a substituted or unsubstituted C₆₋₆₀ aryl, or a substituted or unsubstituted C₂₋₆₀ heteroaryl containing any one or more heteroatoms selected from the group consisting of N, O and S;
R₃ and R₄ are each independently hydrogen, deuterium, a substituted or unsubstituted C₆₋₆₀ aryl, or a substituted or unsubstituted C₂₋₆₀ heteroaryl containing any one or more heteroatoms selected from the group consisting of N, O and S;
at least one of the Ar₂ and Ar₃ is substituted with at least one deuterium, or at least one of the R₃ and R₄ is deuterium;
q is an integer of 1 to 7; and
r is an integer of 1 to 7.

2. The organic light emitting device of claim 1, wherein:
L₁ is a single bond.

3. The organic light emitting device of claim 1, wherein:
each X₂ is N.

4. The organic light emitting device of claim 1, wherein:
each Ar₁ is independently phenyl which is unsubstituted or substituted with at least one deuterium, or biphenylyl which is unsubstituted or substituted with at least one deuterium.

5. The organic light emitting device of claim 1, wherein:
each R₁ is independently hydrogen, deuterium, or phenyl which is unsubstituted or substituted with at least one deuterium.

6. The organic light emitting device of claim 1, wherein:
the compound of Chemical Formula 1 is any one compound selected from the group consisting of:

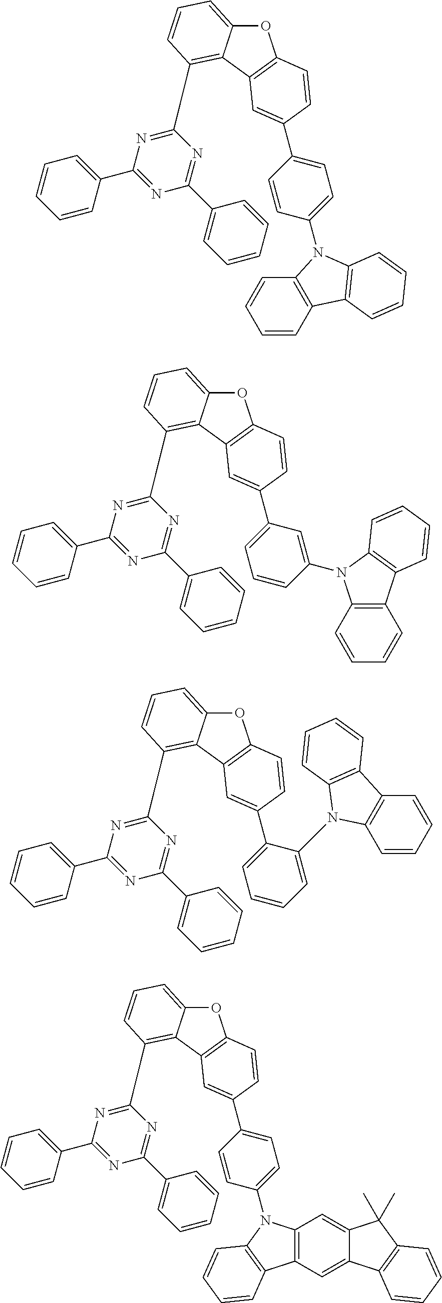 [SMILES: c1ccc(-c2nc(-c3ccccc3)nc(-c3cccc4oc5ccc(-c6ccc(-n7c8ccccc8c8ccccc87)cc6)cc5c34)n2)cc1 ; c1ccc(-c2nc(-c3ccccc3)nc(-c3cccc4oc5ccc(-c6cccc(-n7c8ccccc8c8ccccc87)c6)cc5c34)n2)cc1 ; c1ccc(-c2nc(-c3ccccc3)nc(-c3cccc4oc5ccc(-c6ccccc6-n6c7ccccc7c7ccccc76)cc5c34)n2)cc1 ; CC1(C)c2ccccc2-c2cc3c4ccccc4n(-c4ccc(-c5ccc6oc7cccc(-c8nc(-c9ccccc9)nc(-c9ccccc9)n8)c7c6c5)cc4)c3cc21]

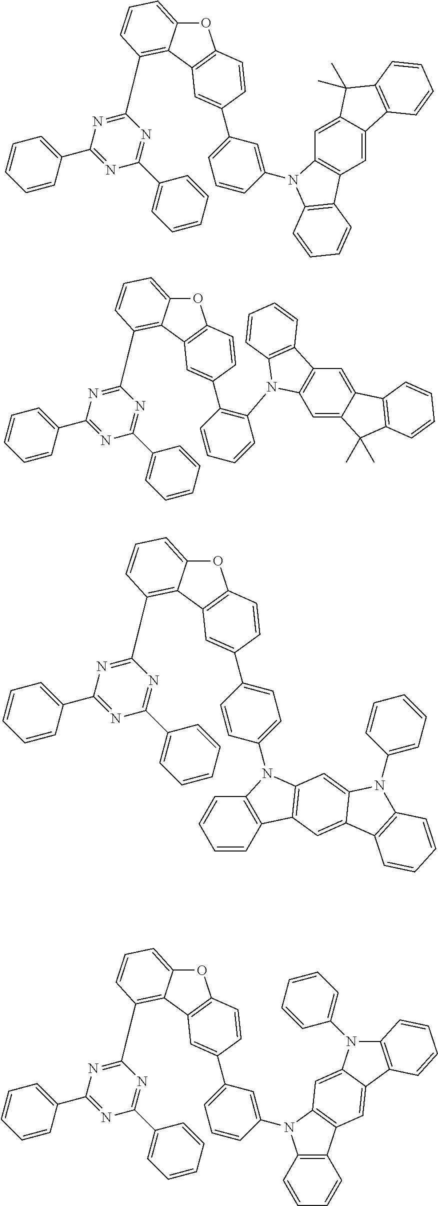

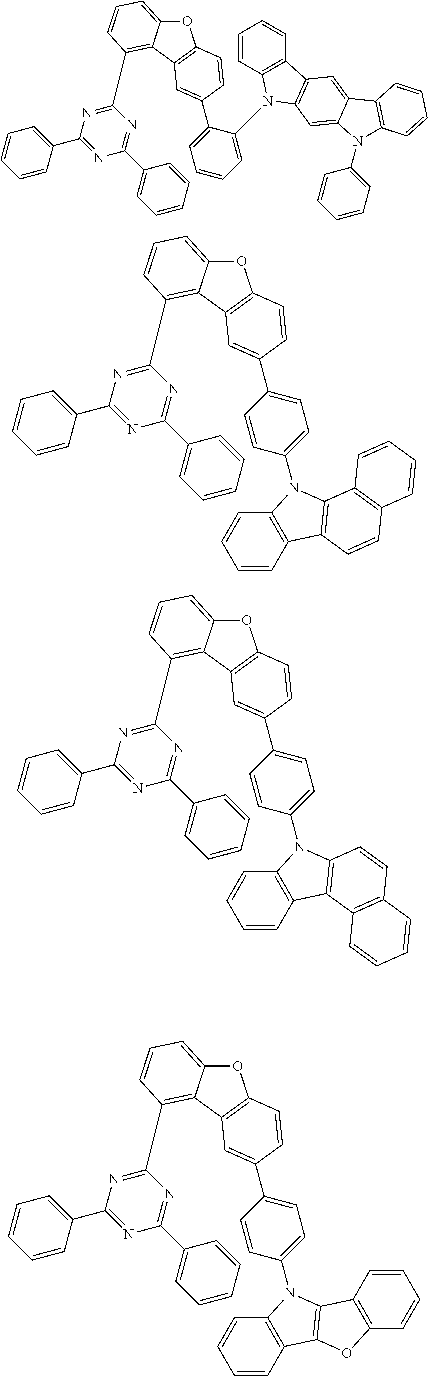

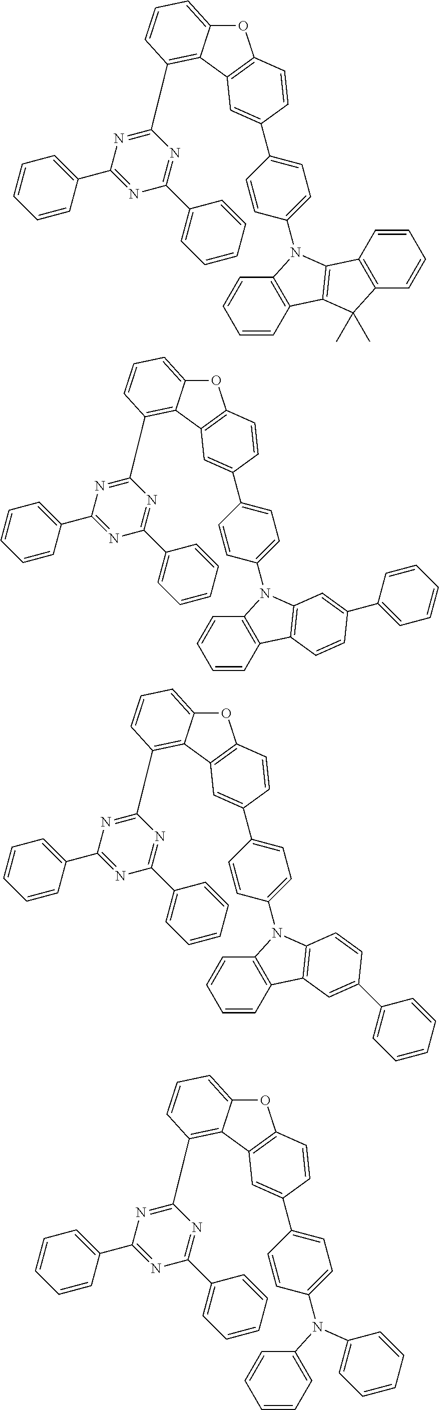

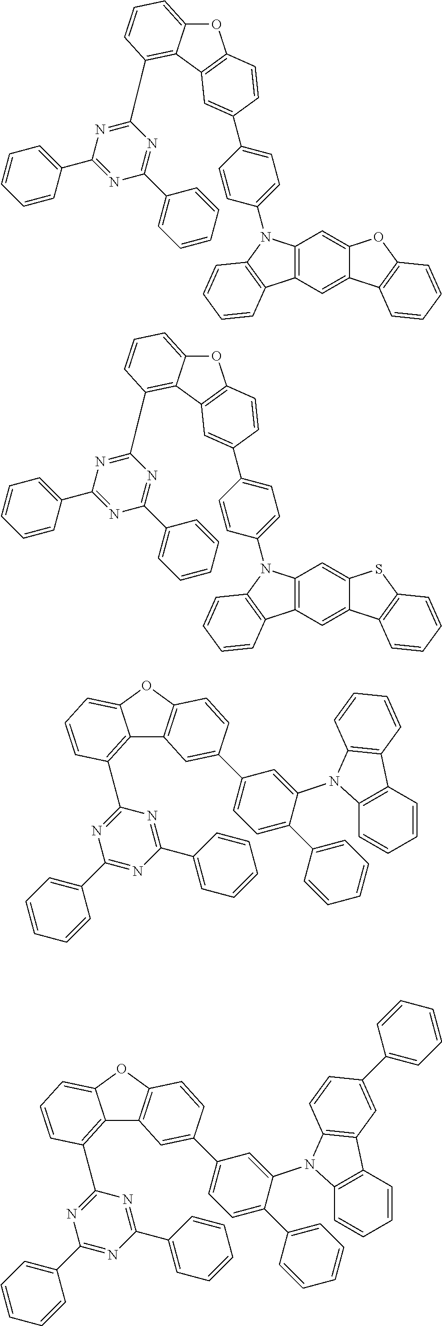

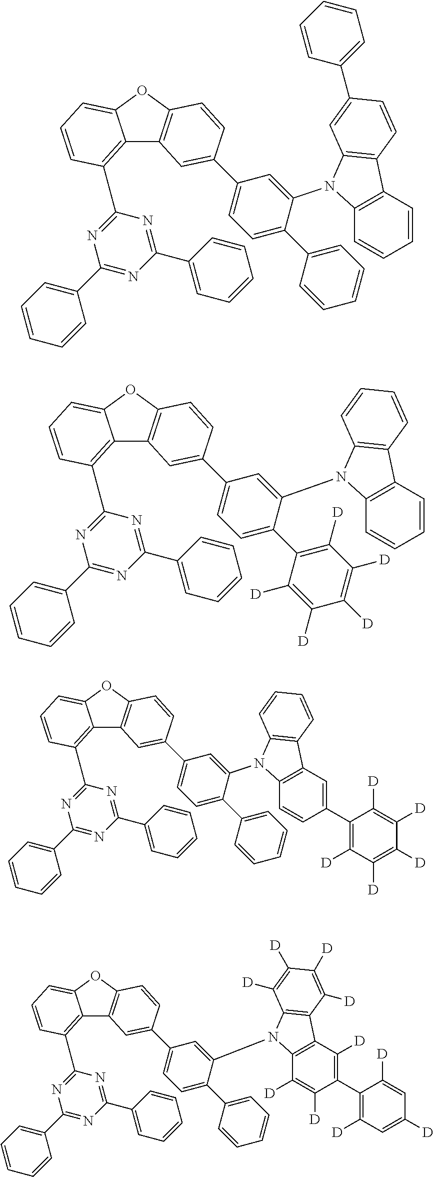

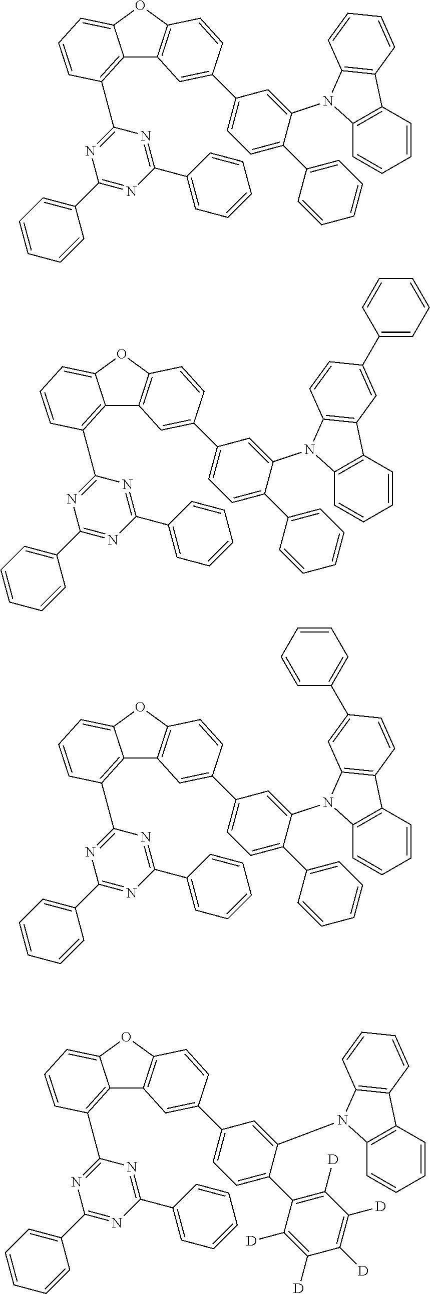 [SMILES: c1ccc(-c2nc(-c3ccccc3)nc(-c3cccc4oc5ccc(-c6ccc(-c7ccccc7)c(-n7c8ccccc8c8ccccc87)c6)cc5c34)n2)cc1 ; c1ccc(-c2ccc3c(c2)c2ccccc2n3-c2cc(-c3ccc4oc5cccc(-c6nc(-c7ccccc7)nc(-c7ccccc7)n6)c5c4c3)ccc2-c2ccccc2)cc1 ; c1ccc(-c2ccc3c4ccccc4n(-c4cc(-c5ccc6oc7cccc(-c8nc(-c9ccccc9)nc(-c9ccccc9)n8)c7c6c5)ccc4-c4ccccc4)c3c2)cc1 ; [2H]c1c([2H])c([2H])c(-c2ccc(-c3ccc4oc5cccc(-c6nc(-c7ccccc7)nc(-c7ccccc7)n6)c5c4c3)cc2-n2c3ccccc3c3ccccc32)c([2H])c1[2H]]

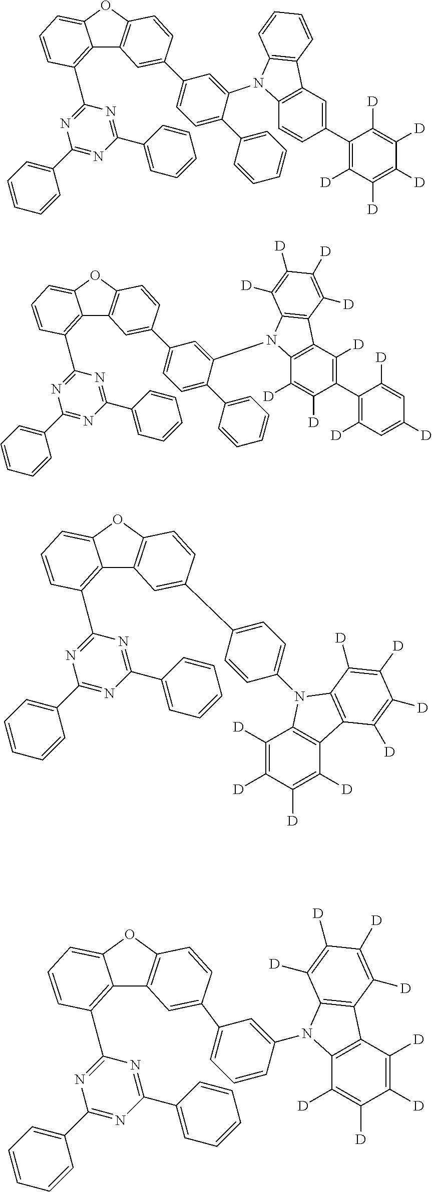

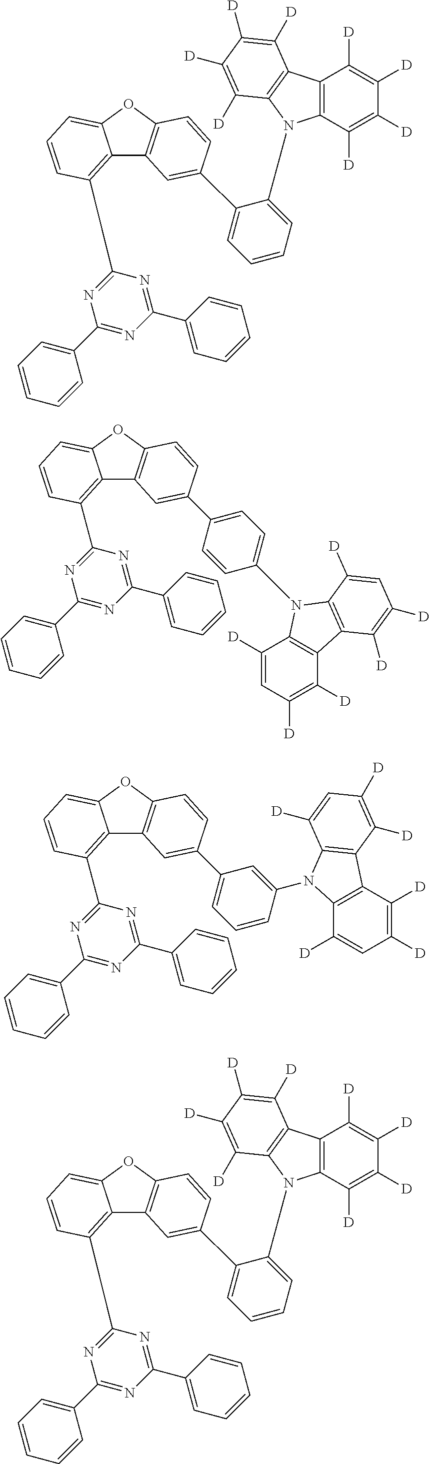

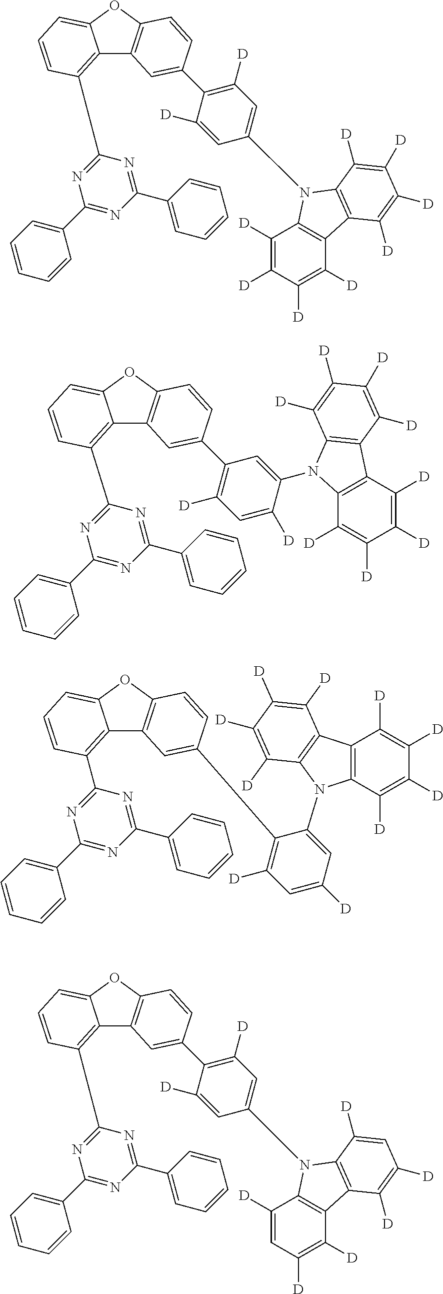

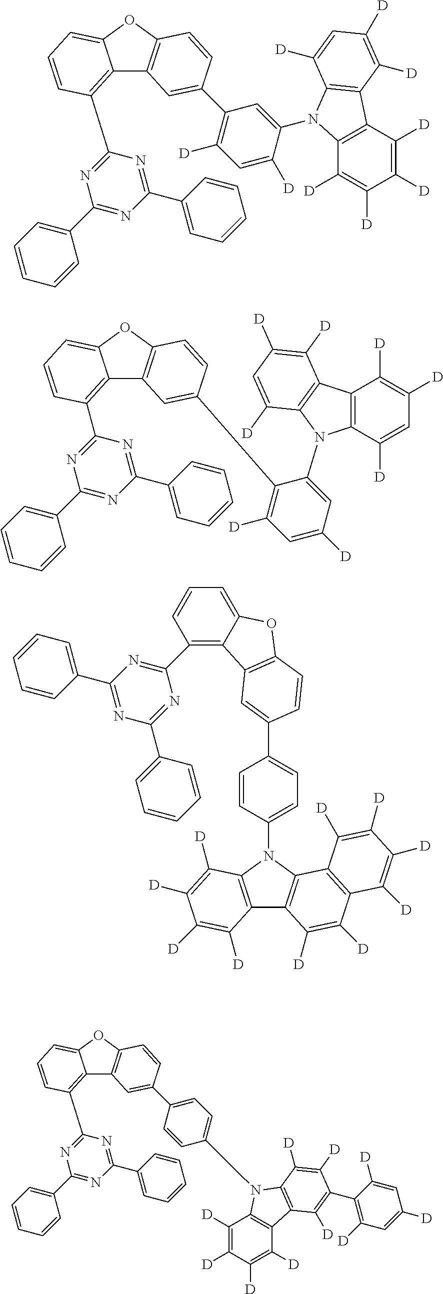

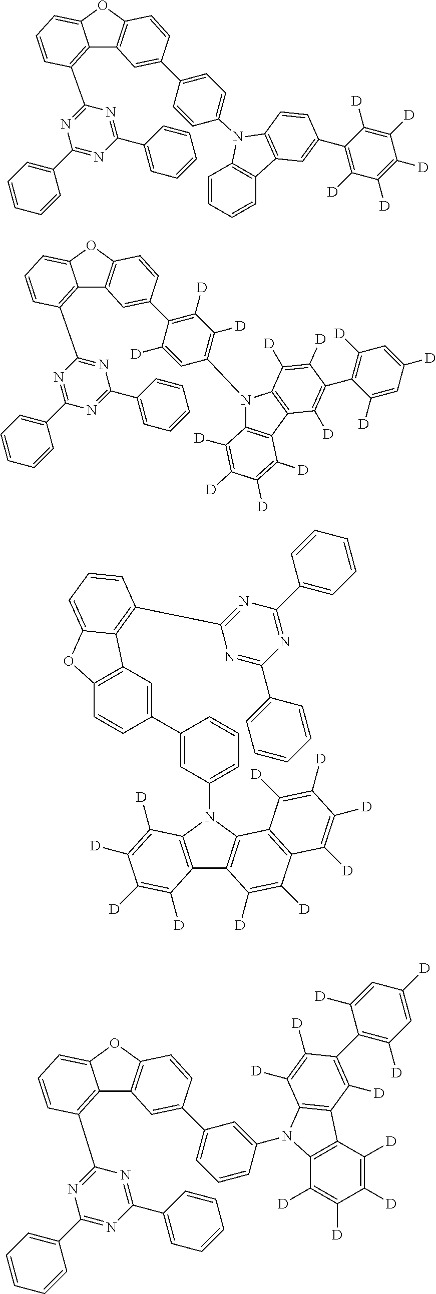

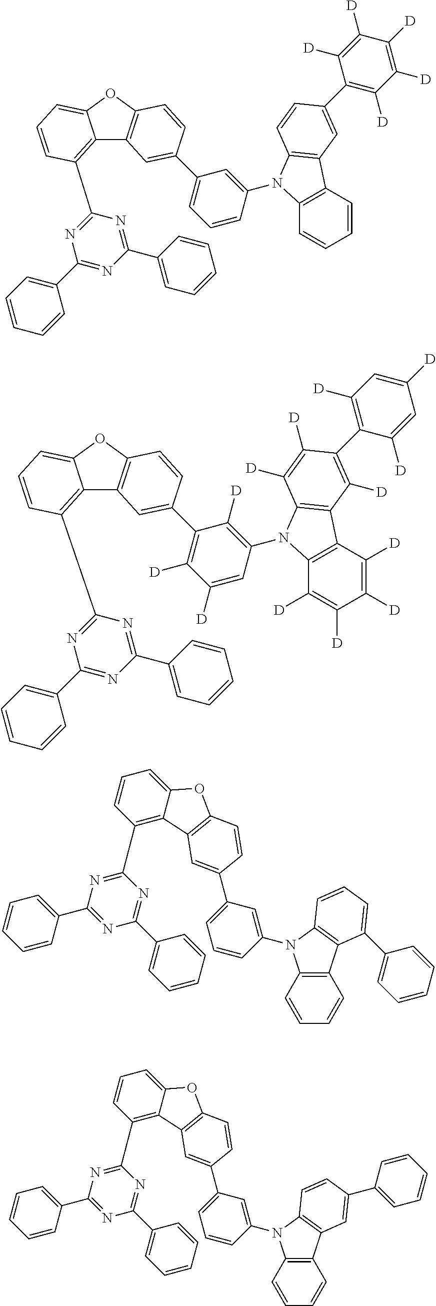 [SMILES: [2H]c1c([2H])c([2H])c(-c2ccc3c(c2)c2ccccc2n3-c2cccc(-c3ccc4oc5cccc(-c6nc(-c7ccccc7)nc(-c7ccccc7)n6)c5c4c3)c2)c([2H])c1[2H] ; [2H]c1cc([2H])c(-c2c([2H])c([2H])c3c(c2[2H])c2c([2H])c([2H])c([2H])c([2H])c2n3-c2cc([2H])c([2H])c(-c3ccc4oc5cccc(-c6nc(-c7ccccc7)nc(-c7ccccc7)n6)c5c4c3)c2[2H])c([2H])c1 ; c1ccc(-c2nc(-c3ccccc3)nc(-c3cccc4oc5ccc(-c6cccc(-n7c8ccccc8c8c(-c9ccccc9)cccc87)c6)cc5c34)n2)cc1 ; c1ccc(-c2ccc3c(c2)c2ccccc2n3-c2cccc(-c3ccc4oc5cccc(-c6nc(-c7ccccc7)nc(-c7ccccc7)n6)c5c4c3)c2)cc1]

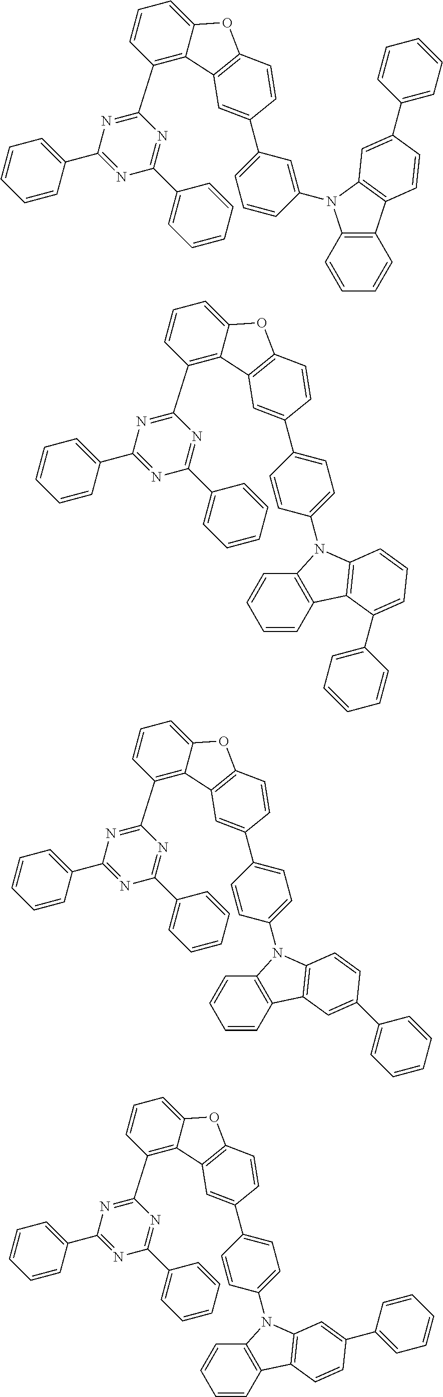 [SMILES: c1ccc(-c2ccc3c4ccccc4n(-c4cccc(-c5ccc6oc7cccc(-c8nc(-c9ccccc9)nc(-c9ccccc9)n8)c7c6c5)c4)c3c2)cc1 ; c1ccc(-c2nc(-c3ccccc3)nc(-c3cccc4oc5ccc(-c6ccc(-n7c8ccccc8c8c(-c9ccccc9)cccc87)cc6)cc5c34)n2)cc1 ; c1ccc(-c2ccc3c(c2)c2ccccc2n3-c2ccc(-c3ccc4oc5cccc(-c6nc(-c7ccccc7)nc(-c7ccccc7)n6)c5c4c3)cc2)cc1 ; c1ccc(-c2ccc3c4ccccc4n(-c4ccc(-c5ccc6oc7cccc(-c8nc(-c9ccccc9)nc(-c9ccccc9)n8)c7c6c5)cc4)c3c2)cc1]

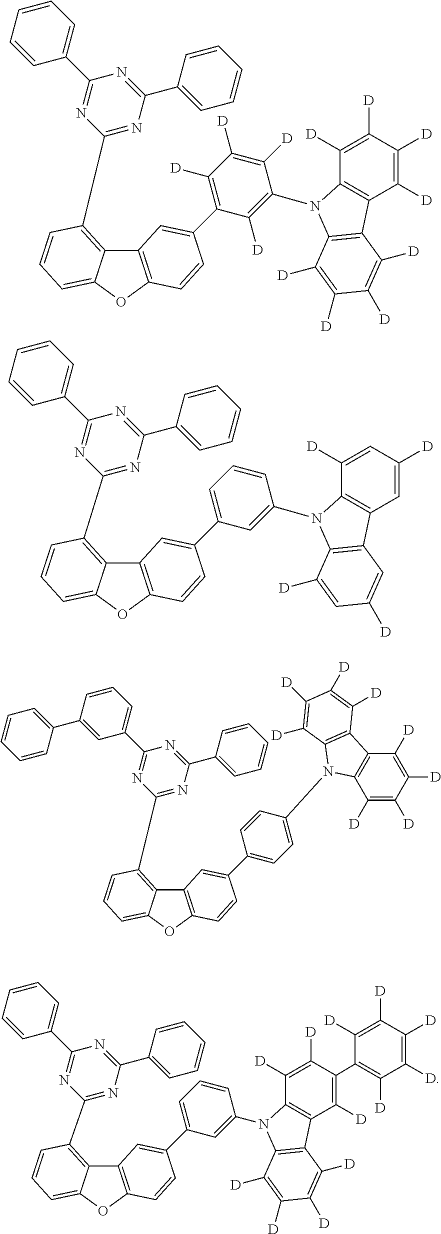

7. The organic light emitting device of claim 1, wherein:
Ar₂ and Ar₃ are each independently phenyl, biphenylyl, terphenylyl, naphthyl, dimethylfluorenyl, dibenzofuranyl, or dibenzothiophenyl,
wherein Ar₂ and Ar₃ are unsubstituted or substituted with at least one deuterium.

8. The organic light emitting device of claim 1, wherein:
Ar₂ is phenyl, biphenylyl, terphenylyl, dimethylfluorenyl, dibenzofuranyl, or dibenzothiophenyl; and
Ar₃ is phenyl, biphenylyl, or naphthyl,
wherein Ar₂ and Ar₃ are unsubstituted or substituted with at least one deuterium.

9. The organic light emitting device of claim 1, wherein:
R₃ and R₄ are each independently hydrogen, deuterium, or phenyl which is unsubstituted or substituted with at least one deuterium.

10. The organic light emitting device of claim 1, wherein:
the compound of Chemical Formula 2 is any one compound selected from the group consisting of: 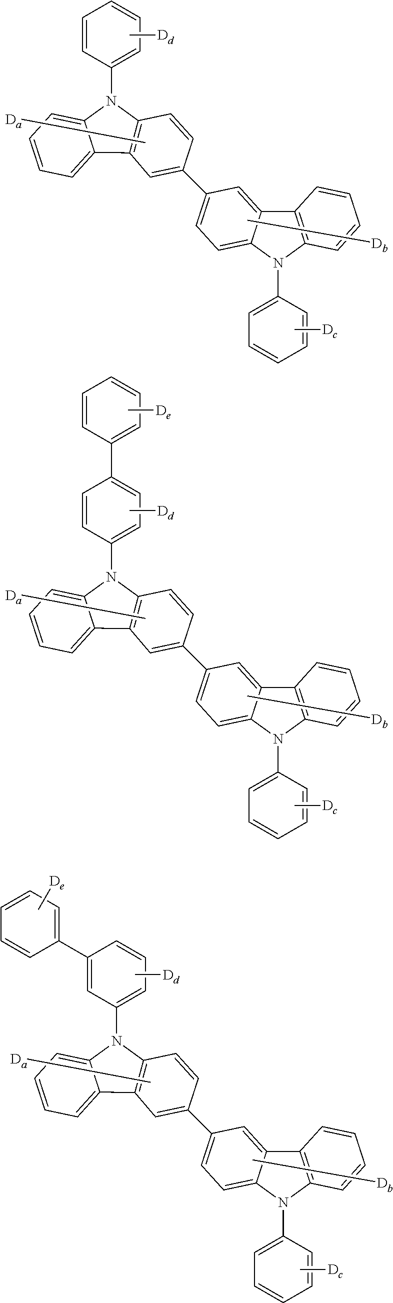 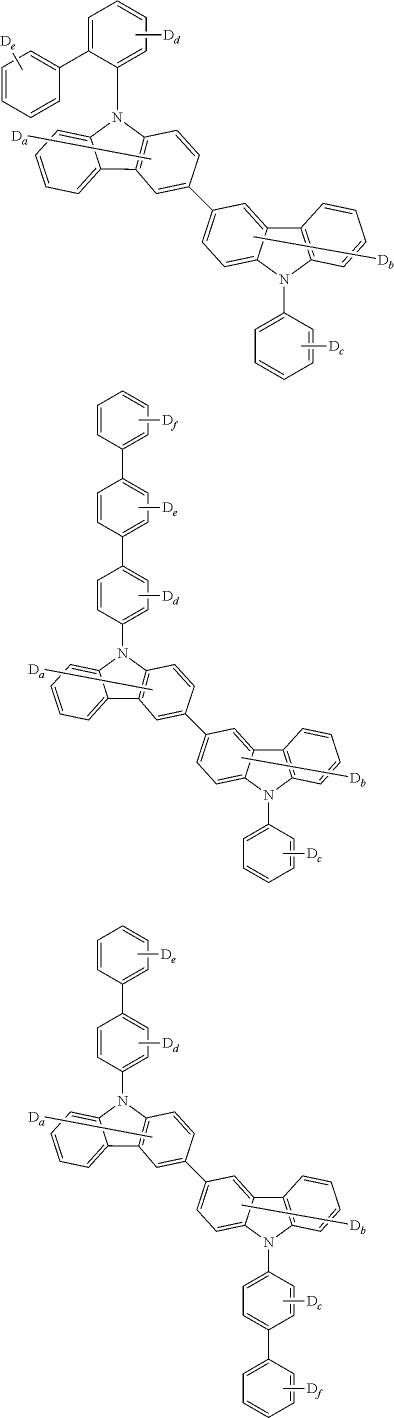 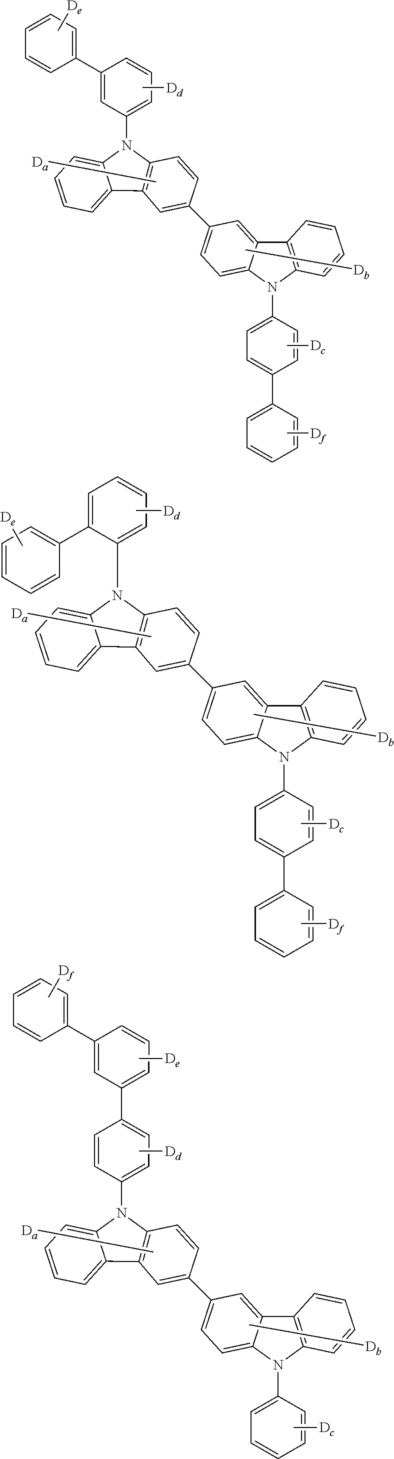 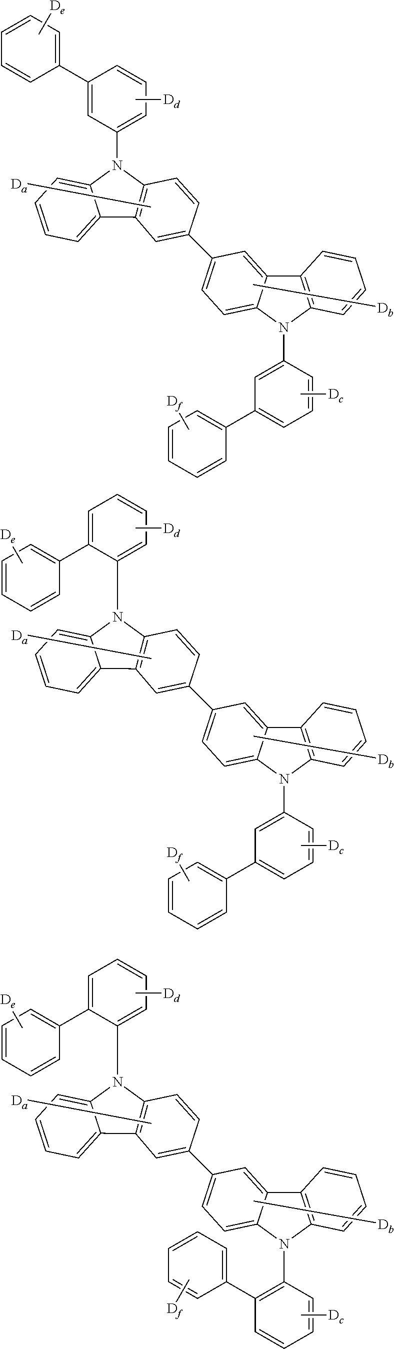 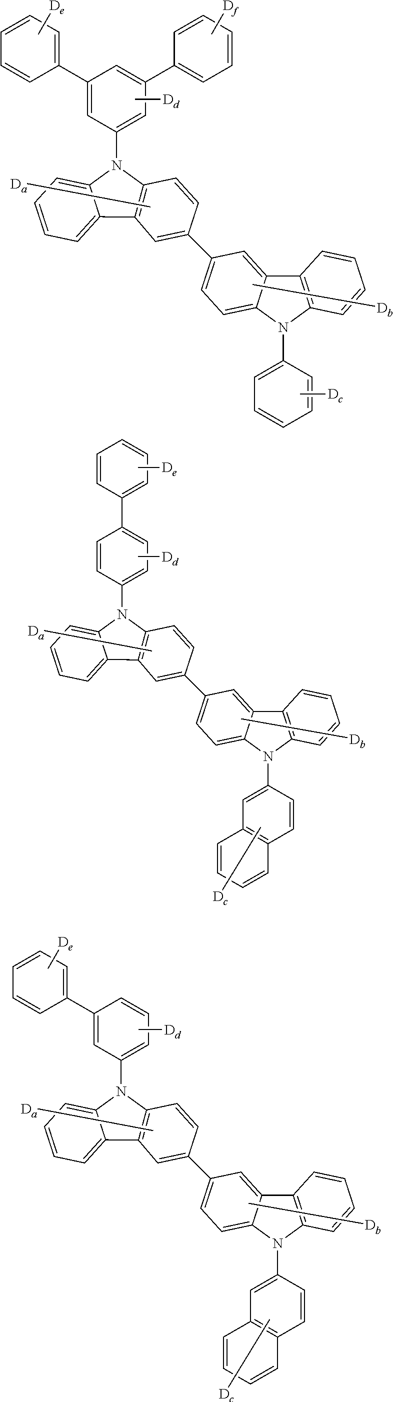 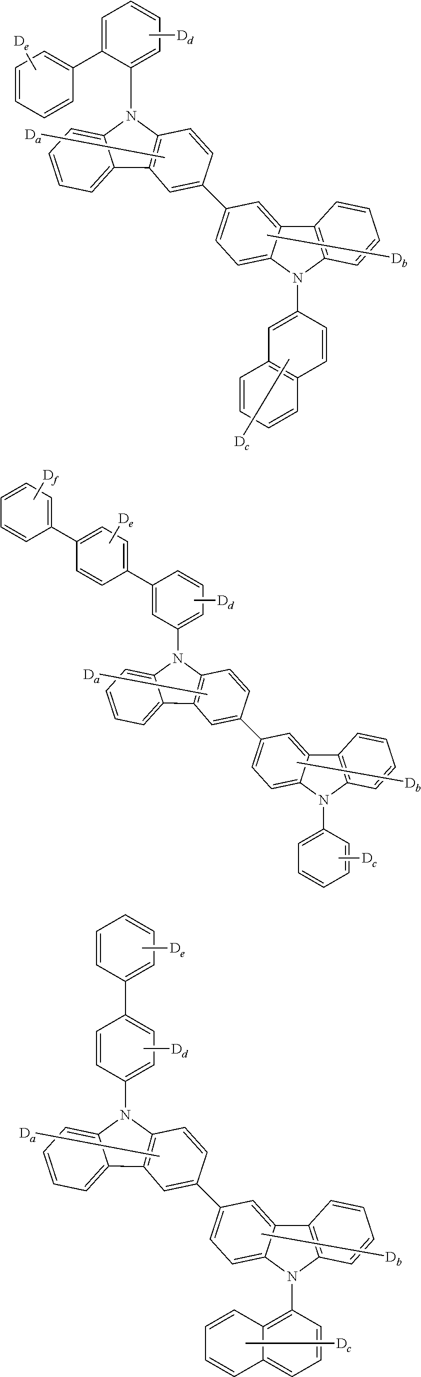 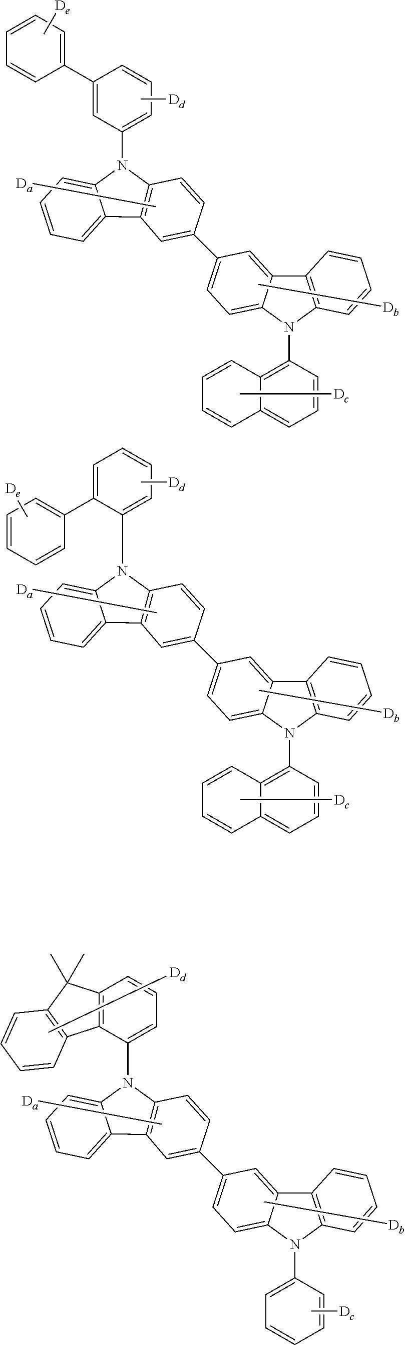 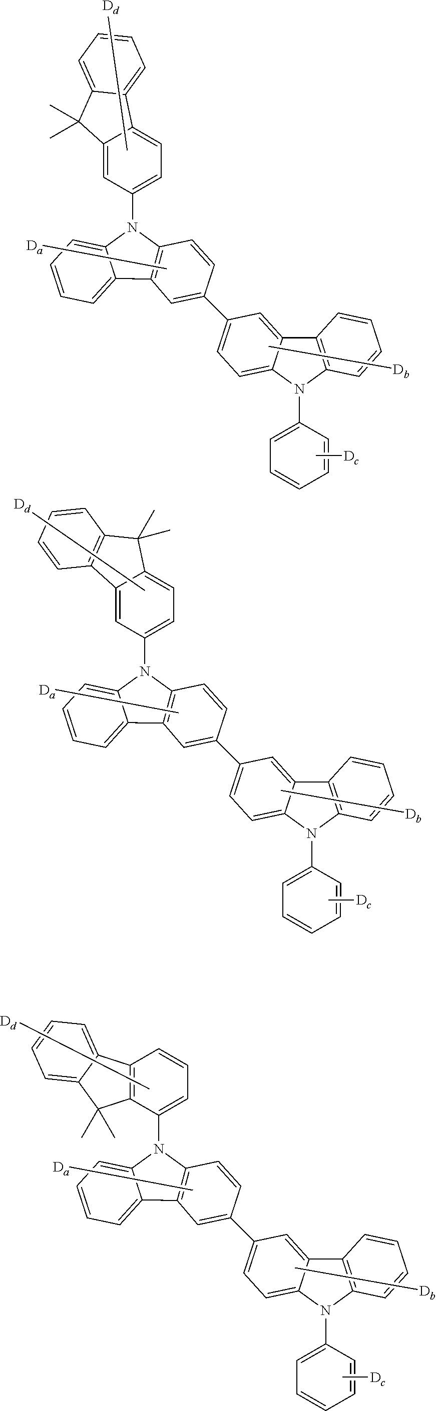 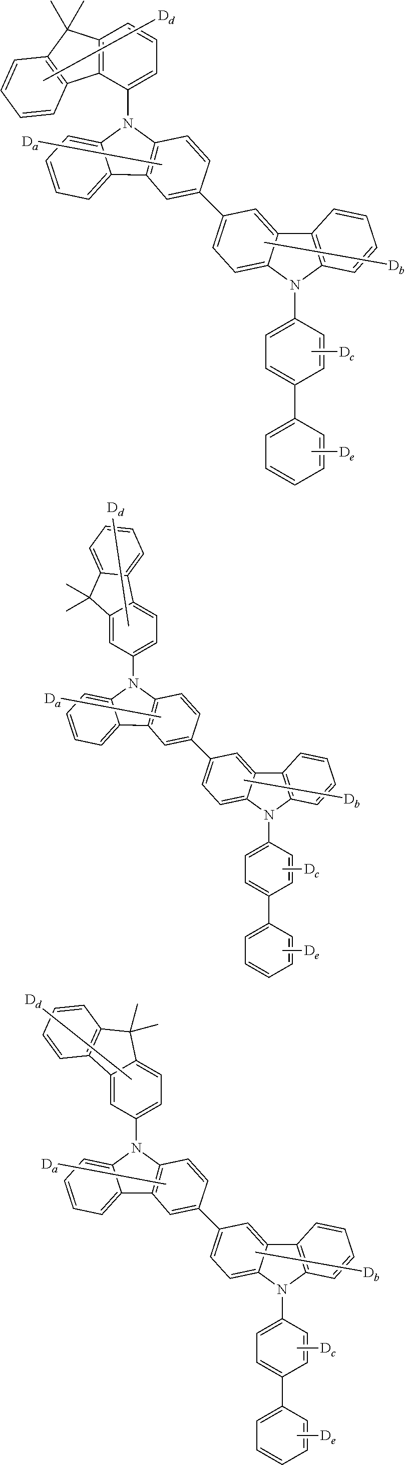 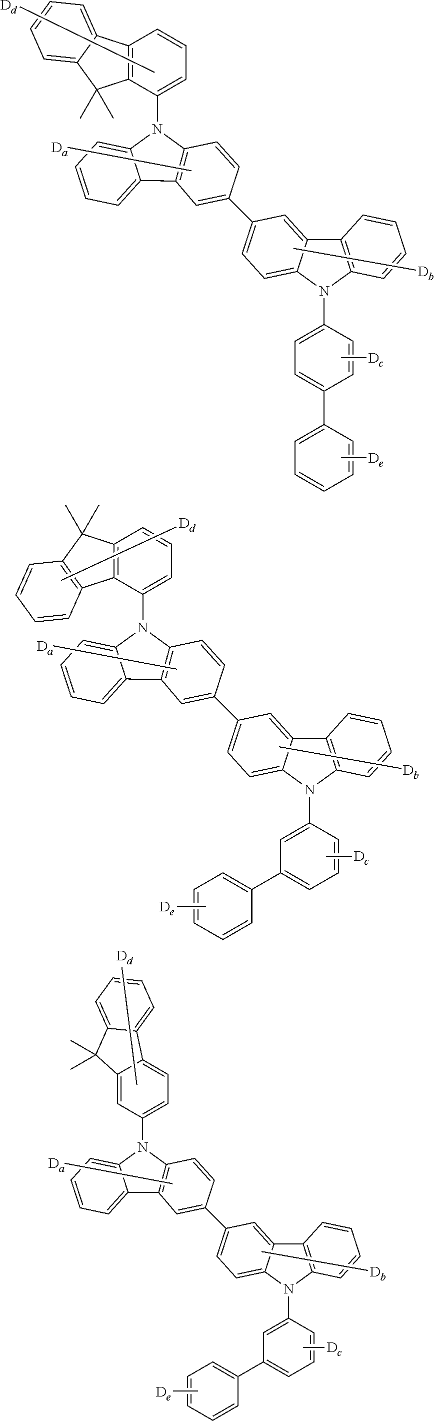 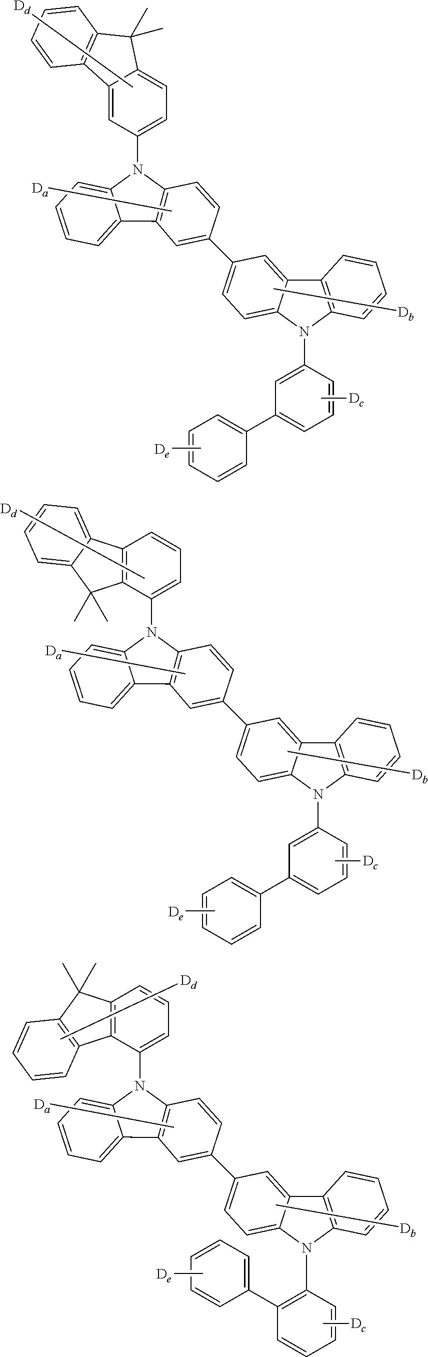 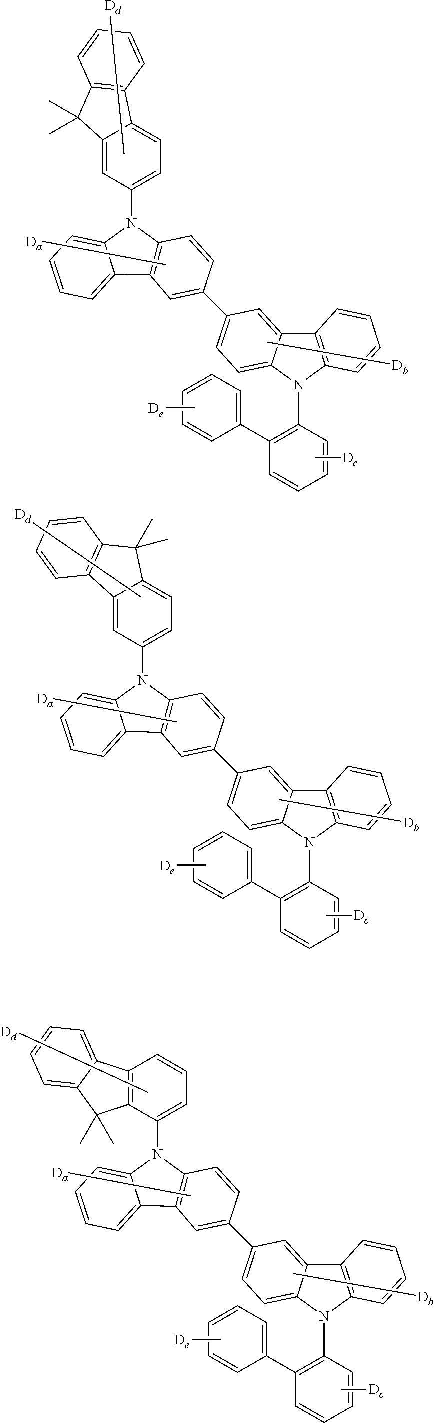 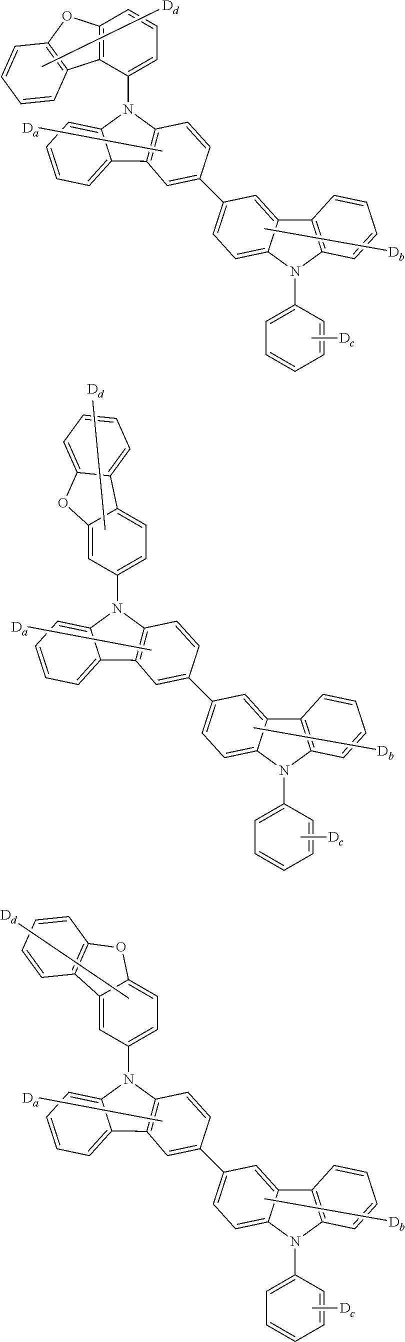 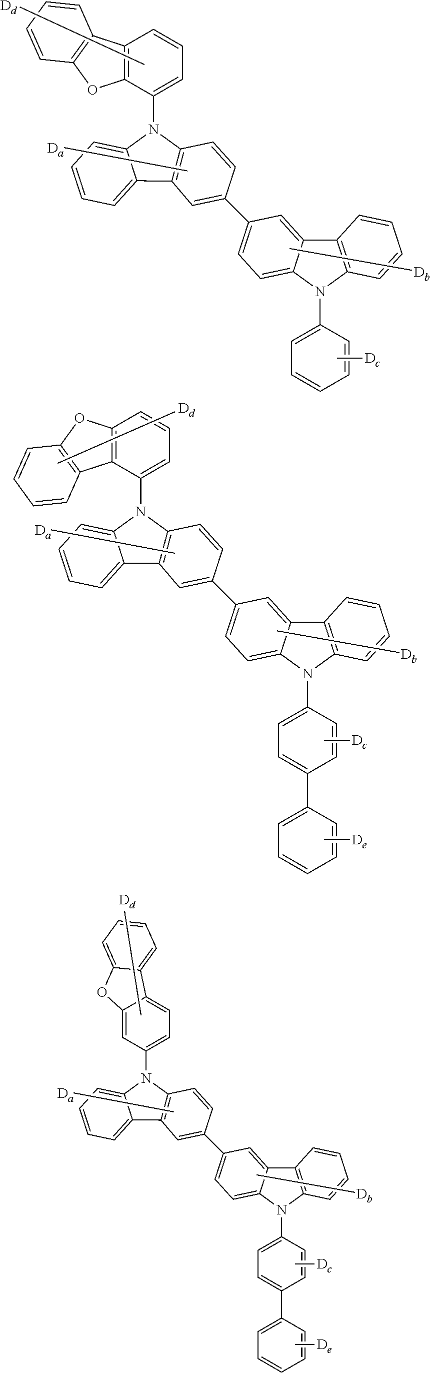 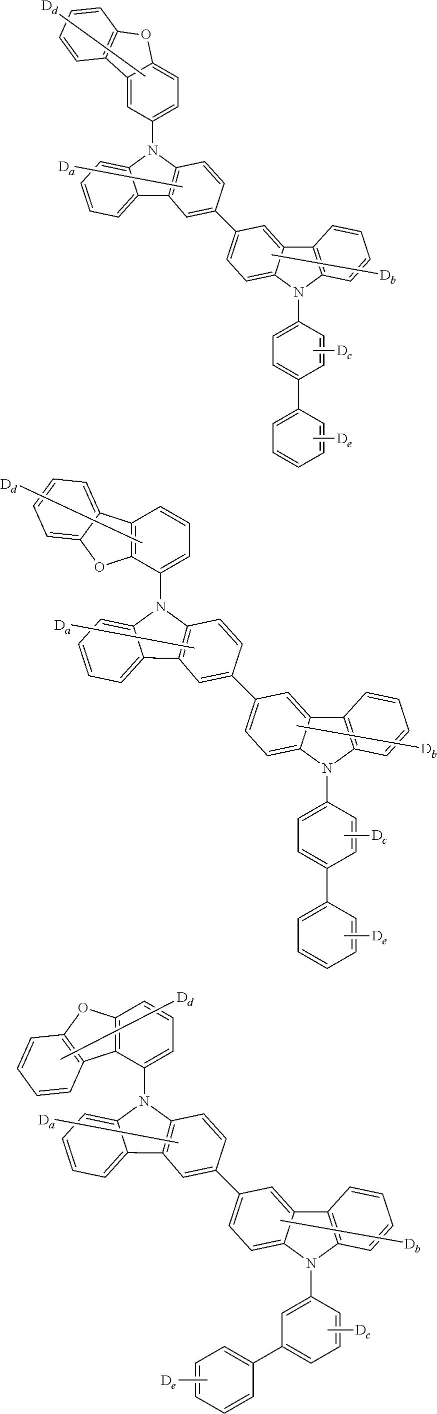 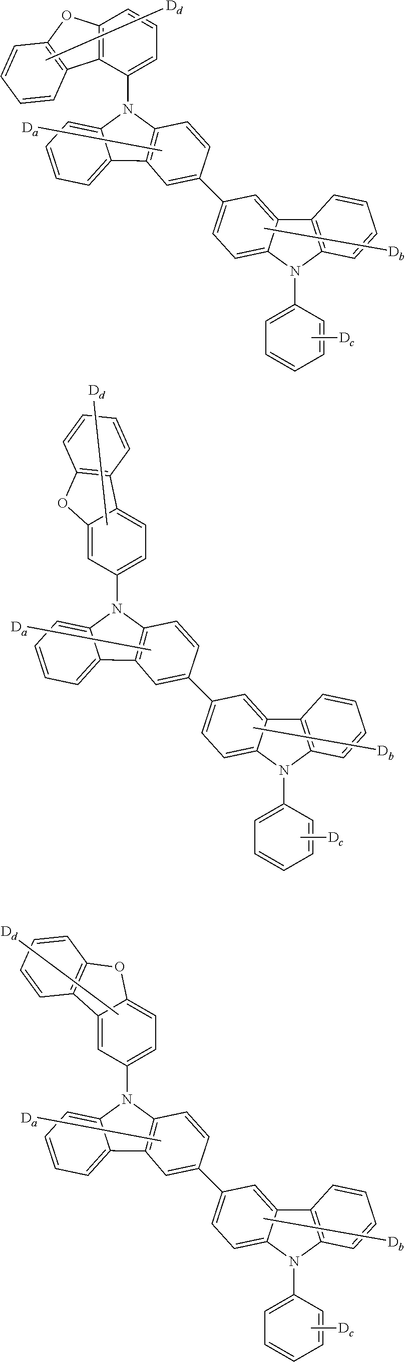 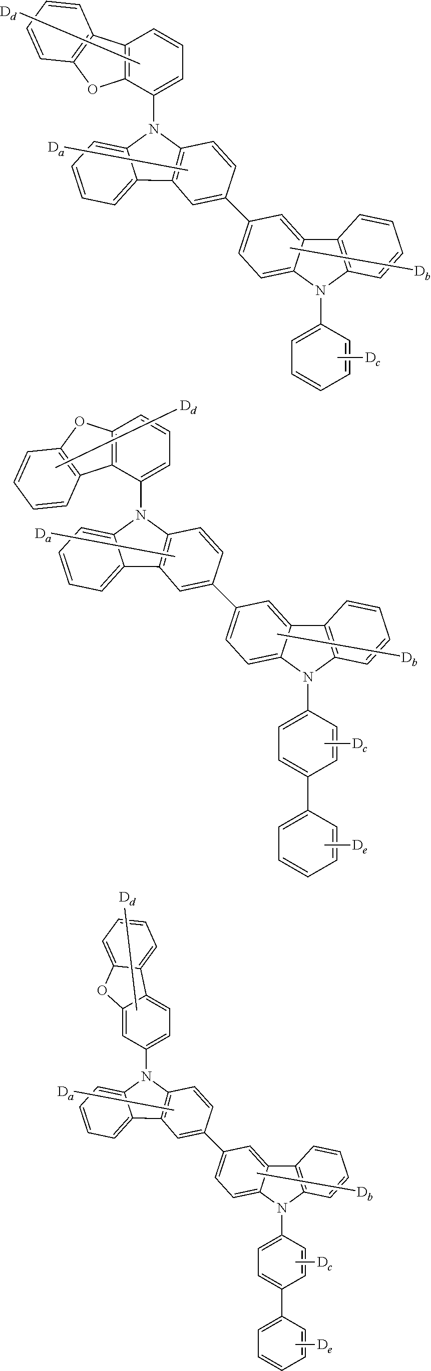 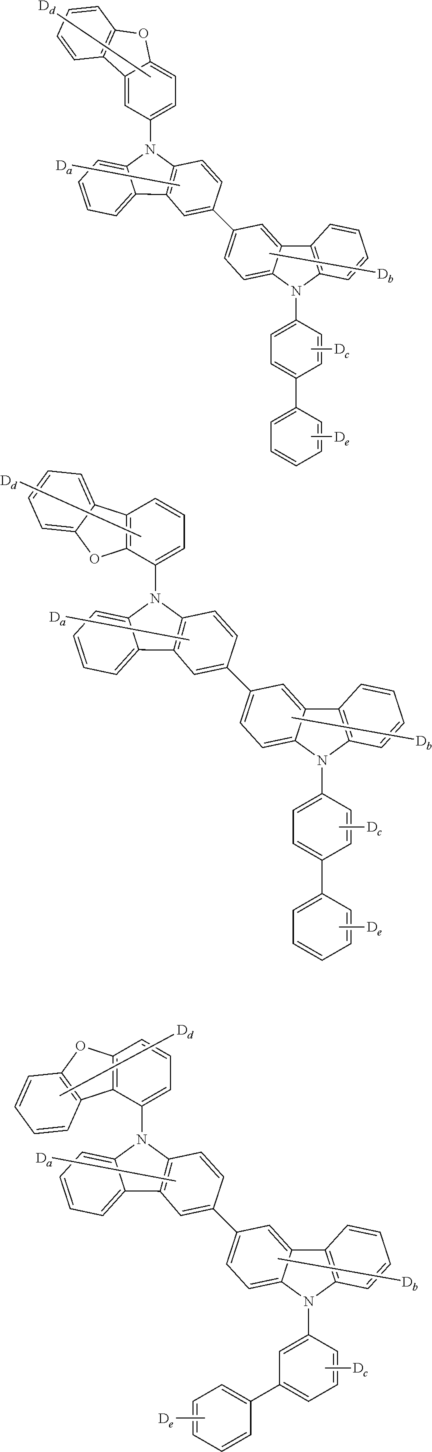 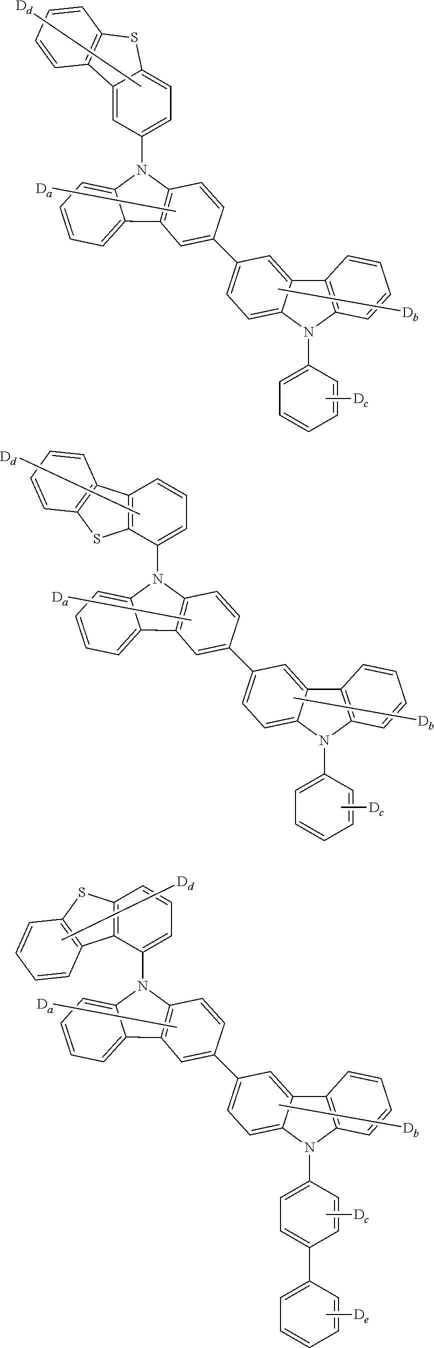 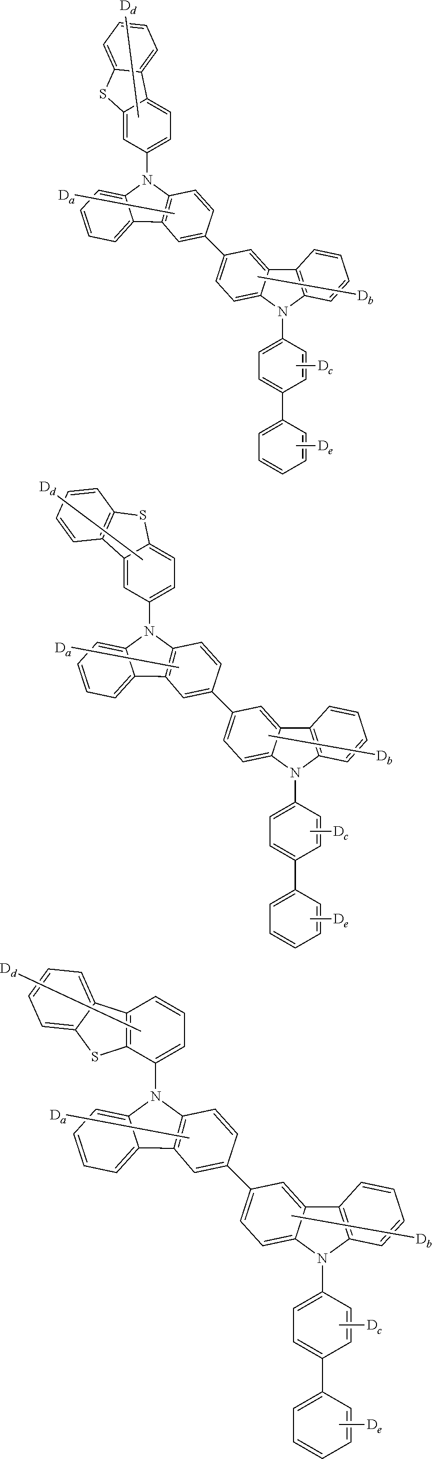 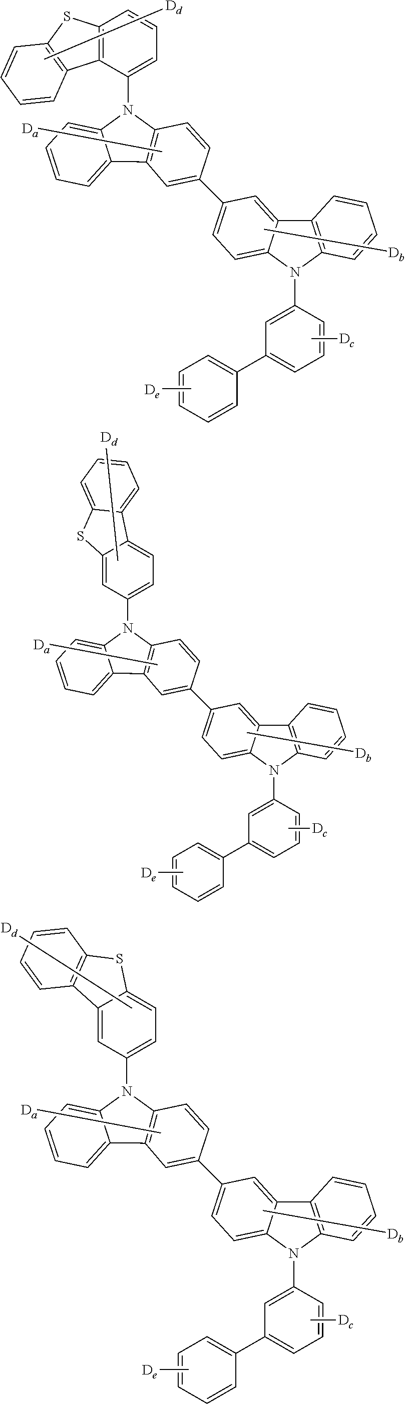 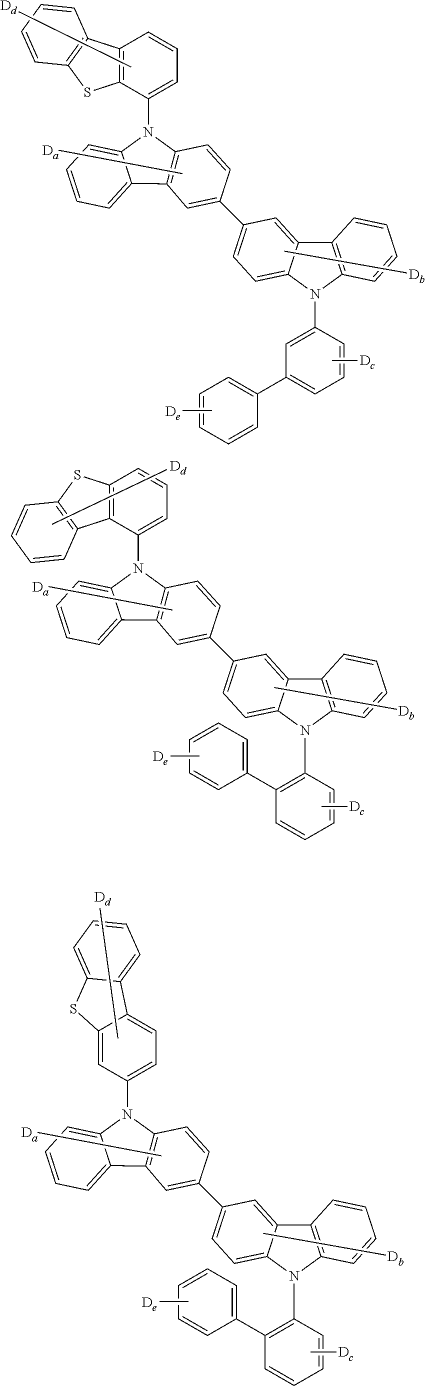 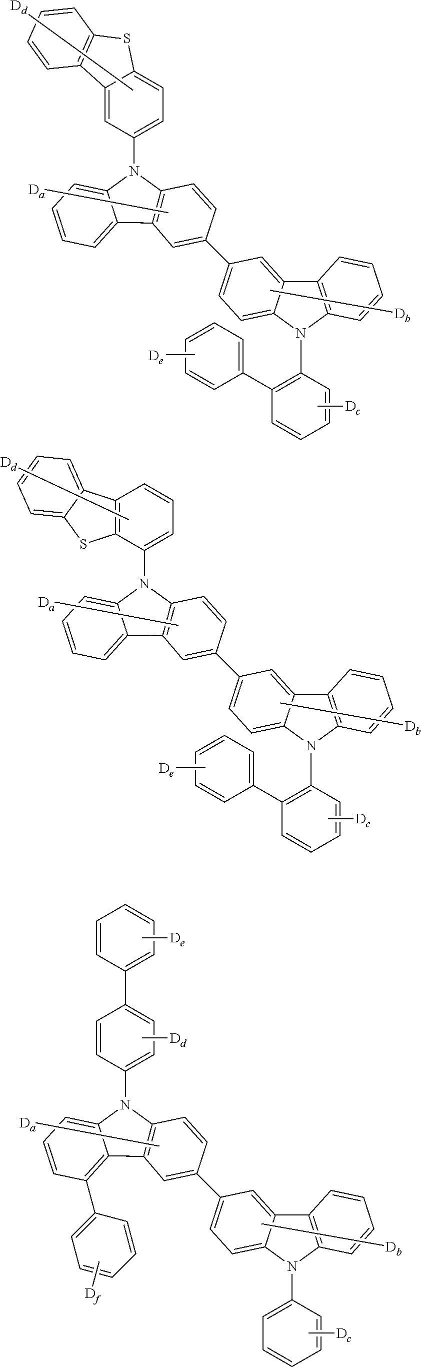 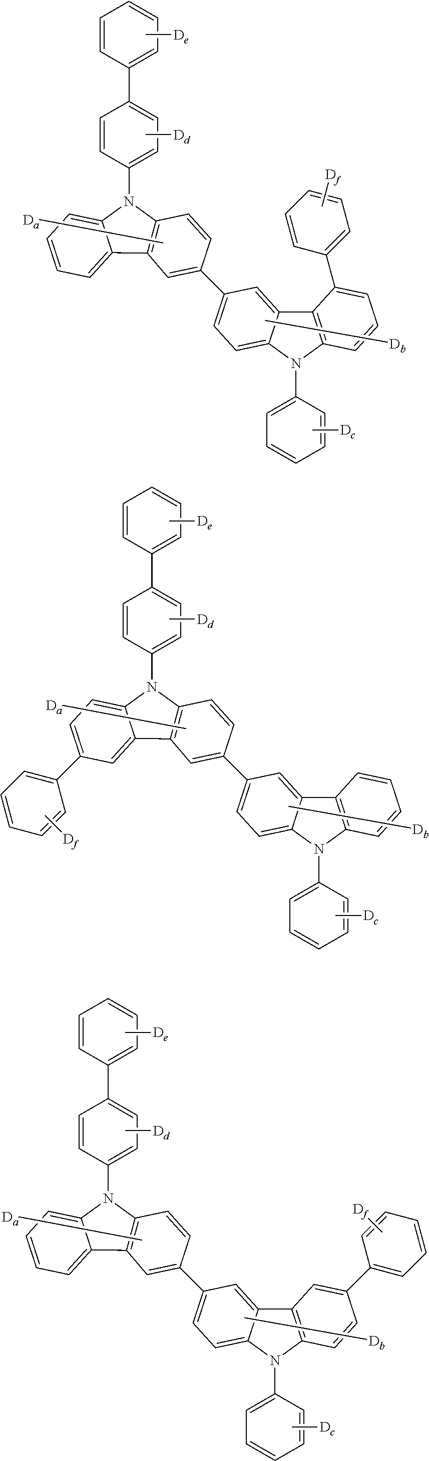
wherein, in the above group:
a is an integer of 0 to 7;
b is an integer of 0 to 7;
c is an integer of 0 to 7;
d is an integer of 0 to 7;
e is an integer of 0 to 5; and
f is an integer of 0 to 5,
provided that the sum of a to f is 1 or more.
